(19) United States
(12) Patent Application Publication
(10) Pub. No.: US 2025/0248071 A1
(43) Pub. Date: Jul. 31, 2025

(54) SEMICONDUCTOR DEVICE AND MEMORY DEVICE

(71) Applicant: SEMICONDUCTOR ENERGY LABORATORY CO., LTD., Atsugi-shi (JP)

(72) Inventors: Shunpei YAMAZAKI, Tokyo (JP); Tsutomu MURAKAWA, Isehara (JP); Hidekazu MIYAIRI, Hadano (JP); Yasuhiro JINBO, Isehara (JP); Fumito ISAKA, Zama (JP); Motomu KURATA, Isehara (JP)

(21) Appl. No.: 19/038,772

(22) Filed: Jan. 28, 2025

(30) Foreign Application Priority Data
Jan. 31, 2024 (JP) 2024-013335
Jan. 31, 2024 (JP) 2024-013338
Feb. 16, 2024 (JP) 2024-022002

(51) Int. Cl. H10D 30/67; H10B 12/00

(52) U.S. Cl. CPC H10D 30/6755; H10B 12/33

(57) ABSTRACT

A semiconductor device that can be miniaturized or highly integrated includes an oxide semiconductor layer, first to third insulating layers, and first to third conductive layers. The first and second conductive layers are over the first insulating layer to be apart from each other. The first insulating layer includes a groove portion between the first and second conductive layers. The oxide semiconductor layer includes regions in contact with top and side surfaces of the first conductive layer, in contact with top and side surfaces of the second conductive layer, and in contact with a side surface of the groove portion. The second insulating layer is over the oxide semiconductor layer. The third conductive layer is over the second insulating layer. The third insulating layer includes a region in contact with the side surfaces of the oxide semiconductor layer, the second insulating layer, and the third conductive layer.

### BACKGROUND OF THE INVENTION

### 1. Field of the Invention

One embodiment of the present invention relates to a semiconductor device, a memory device, and an electronic device. One embodiment of the present invention also relates to a method for manufacturing a semiconductor device or a memory device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and include a semiconductor device in some cases.

### 2. Description of the Related Art

In recent years, semiconductor devices have been developed, and large-scale integrations (LSIs), central processing units (CPUs), memories (memory devices), and the like are mainly used in semiconductor devices. A CPU is an aggregation of semiconductor elements; the CPU includes an integrated circuit (including a transistor and a memory) formed into a chip by processing a semiconductor wafer, and is provided with an electrode that is a connection terminal.

An integrated circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely known, but oxide semiconductors have been attracting attention as alternative materials.

A transistor including an oxide semiconductor is known to have an extremely low leakage current in an off state. For example, Patent Document 1 discloses a low-power-consumption CPU utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

An object of one embodiment of the present invention is to provide a transistor with favorable electrical characteristics. An object of one embodiment of the present invention is to provide a transistor having a high on-state current. An object of one embodiment of the present invention is to provide a transistor with small parasitic capacitance. An object of one embodiment of the present invention is to provide a highly reliable transistor, semiconductor device, or memory device. An object of one embodiment of the present invention is to provide a transistor, a semiconductor device, or a memory device that can be miniaturized or highly integrated. An object of one embodiment of the present invention is to provide a semiconductor device or a memory device with low power consumption. An object of one embodiment of the present invention is to provide a memory device with high operation speed. An object of one embodiment of the present invention is to provide a method for manufacturing the above-described transistor, semiconductor device, or memory device.

Note that the description of these objects does not preclude the existence of other objects. One embodiment of the present invention does not necessarily achieve all of these objects. Other objects can be derived from the description of the specification, the drawings, and the claims.

One embodiment of the present invention is a semiconductor device including an oxide semiconductor layer, first to third insulating layers, and first to third conductive layers. The first conductive layer and the second conductive layer are provided over the first insulating layer to be apart from each other. The first insulating layer includes a groove portion between the first conductive layer and the second conductive layer. The oxide semiconductor layer includes a region in contact with part of a top surface of the first conductive layer and a side surface of the first conductive layer on a side of the groove portion, a region in contact with part of a top surface of the second conductive layer and a side surface of the second conductive layer on a side of the groove portion, and a region in contact with a side surface of the groove portion. The second insulating layer is provided over the oxide semiconductor layer. The third conductive layer is provided over the second insulating layer. Side surfaces of the third conductive layer, the second insulating layer, and the oxide semiconductor layer are aligned or substantially aligned with each other. The third insulating layer includes, outside the groove portion, a region in contact with another part of the top surface of the first conductive layer, another part of the top surface of the second conductive layer, the side surface of the oxide semiconductor layer, the side surface of the second insulating layer, and the side surface of the third conductive layer. The third insulating layer includes, inside the groove portion, a region in contact with a side surface of the oxide semiconductor layer, a side surface of the second insulating layer, and a side surface of the third conductive layer.

The above semiconductor device preferably includes a fourth conductive layer. The fourth conductive layer is preferably in contact with a top surface of the third conductive layer. An extending direction of the fourth conductive layer preferably intersects with an extending direction of the groove portion.

The above semiconductor device preferably includes a fifth conductive layer. The fifth conductive layer preferably includes regions overlapping with the first conductive layer and the second conductive layer with the first insulating layer therebetween. The fifth conductive layer preferably includes a depressed portion in a region overlapping with the groove portion. The oxide semiconductor layer preferably includes a region in contact with a side surface and a bottom portion of the depressed portion.

In the above semiconductor device, the depressed portion preferably has a curved portion.

One embodiment of the present invention is a memory device including a capacitor, a transistor over the capacitor, a first insulating layer, and a second insulating layer. The transistor includes an oxide semiconductor layer, a third insulating layer, and first to fourth conductive layers. The first insulating layer is provided to cover the first conductive layer. The second conductive layer and the third conductive layer are provided over the first insulating layer to be apart from each other. The first insulating layer includes a groove portion between the second conductive layer and the third conductive layer. The first conductive layer includes a depressed portion in a region overlapping with the groove portion. The oxide semiconductor layer includes a region in contact with part of a top surface of the second conductive layer and a side surface of the second conductive layer on a side of the groove portion, a region in contact with part of a top surface of the third conductive layer and a side surface of the third conductive layer on a side of the groove portion, a region in contact with a side surface of the groove portion, and a region in contact with a side surface and a bottom portion of the depressed portion. The third insulating layer is provided over the oxide semiconductor layer. The fourth conductive layer is provided over the third insulating layer. Side surfaces of the fourth conductive layer, the third insulating layer, and the oxide semiconductor layer are aligned or substantially aligned with each other. The second insulating layer includes, outside the groove portion, a region in contact with another part of the top surface of the second conductive layer, another part of the top surface of the third conductive layer, the side surface of the oxide semiconductor layer, the side surface of the third insulating layer, and the side surface of the fourth conductive layer. The second insulating layer includes, inside the groove portion, a region in contact with a side surface of the oxide semiconductor layer, a side surface of the third insulating layer, and a side surface of the fourth conductive layer.

The above memory device preferably includes a fifth conductive layer. The fifth conductive layer is preferably in contact with a top surface of the fourth conductive layer. An extending direction of the fifth conductive layer preferably intersects with an extending direction of the groove portion.

In the above memory device, the depressed portion preferably has a curved portion.

In the above memory device, the capacitor preferably includes a sixth conductive layer, a fourth insulating layer over the sixth conductive layer, and the first conductive layer over the fourth insulating layer.

In the above memory device, the third insulating layer preferably includes a first layer, and the first layer preferably includes an oxide containing hafnium.

In the above memory device, the first layer preferably includes a hafnium zirconium oxide.

In the above memory device, the third insulating layer preferably includes a second layer over the first layer, and the second layer preferably contains silicon nitride.

One embodiment of the present invention is a semiconductor device including a first insulating layer, a second insulating layer, a first transistor, and a second transistor. The first insulating layer includes a groove portion. The first transistor includes a first oxide semiconductor layer including a channel formation region. The second transistor includes a second oxide semiconductor layer including a channel formation region. At least part of the first oxide semiconductor layer and at least part of the second oxide semiconductor layer are positioned in the groove portion. In a plan view, the first oxide semiconductor layer and the second oxide semiconductor layer face each other with the second insulating layer therebetween, in a direction perpendicular to an extending direction of the groove portion.

In the above semiconductor device, the first transistor preferably includes first to third conductive layers, the second conductive layer is preferably provided over the first insulating layer, the first conductive layer preferably includes a region overlapping with the second conductive layer with the first insulating layer therebetween, the first conductive layer preferably includes a depressed portion in a region overlapping with the groove portion, the first oxide semiconductor layer preferably includes a region in contact with a side surface and a bottom portion of the depressed portion in the first conductive layer and a region in contact with a top surface and a side surface of the second conductive layer, and the third conductive layer is preferably provided above the first oxide semiconductor layer.

In the above semiconductor device, inside the groove portion, the second insulating layer preferably includes regions in contact with a side surface of the first oxide semiconductor layer and a side surface of the second oxide semiconductor layer.

The semiconductor device preferably includes a fourth conductive layer. The fourth conductive layer is preferably connected to a gate of the first transistor and a gate of the second transistor. An extending direction of the fourth conductive layer preferably intersects with an extending direction of the groove portion.

One embodiment of the present invention is a memory device including the above semiconductor device and a capacitor. The capacitor is positioned below the first transistor. The first conductive layer includes a region functioning as one of a pair of electrodes of the capacitor.

One embodiment of the present invention can provide a transistor with favorable electrical characteristics. One embodiment of the present invention can provide a transistor having a high on-state current. One embodiment of the present invention can provide a transistor with small parasitic capacitance. One embodiment of the present invention can provide a highly reliable transistor, semiconductor device, or memory device. One embodiment of the present invention can provide a transistor, a semiconductor device, or a memory device which can be miniaturized or highly integrated. One embodiment of the present invention can provide a semiconductor device or a memory device with low power consumption. One embodiment of the present invention can provide a memory device with high operating speed. One embodiment of the present invention can provide a method for manufacturing the above transistor, semiconductor device, or memory device.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIGS. 1A1 and 1A2 are plan views illustrating examples of a semiconductor device, and

FIGS. 1B to 1E are cross-sectional views illustrating the example of the semiconductor device;

FIG. 2 is a schematic perspective view illustrating an example of a semiconductor device;

FIGS. 3A to 3C are cross-sectional views illustrating an example of a semiconductor device;

FIGS. 4A and 4B are cross-sectional views illustrating examples of a semiconductor device;

FIGS. 5A and 5B are cross-sectional views illustrating examples of a semiconductor device;

FIGS. 6A and 6B are cross-sectional views illustrating examples of a semiconductor device;

FIGS. 7A to 7F are cross-sectional views illustrating examples of a semiconductor device;

FIG. 8A is a plan view illustrating an example of a method for manufacturing a semiconductor device, and FIGS. 8B to 8E are cross-sectional views illustrating the example of the method for manufacturing the semiconductor device;

FIG. 9A is a plan view illustrating the example of the method for manufacturing the semiconductor device, and FIGS. 9B to 9E are cross-sectional views illustrating the example of the method for manufacturing the semiconductor device;

FIG. 10A is a plan view illustrating the example of the method for manufacturing the semiconductor device, and FIGS. 10B to 10E are cross-sectional views illustrating the example of the method for manufacturing the semiconductor device;

FIG. 11A is a plan view illustrating the example of the method for manufacturing the semiconductor device, and FIGS. 11B to 11E are cross-sectional views illustrating the example of the method for manufacturing the semiconductor device;

FIG. 12A is a plan view illustrating the example of the method for manufacturing the semiconductor device, and FIGS. 12B to 12E are cross-sectional views illustrating the example of the method for manufacturing the semiconductor device;

FIG. 13A is a plan view illustrating the example of the method for manufacturing the semiconductor device, and FIGS. 13B to 13E are cross-sectional views illustrating the example of the method for manufacturing the semiconductor device;

FIG. 14A is a plan view illustrating the example of the method for manufacturing the semiconductor device, and FIGS. 14B to 14E are cross-sectional views illustrating the example of the method for manufacturing the semiconductor device;

FIG. 15A is a plan view illustrating the example of the method for manufacturing the semiconductor device, and FIGS. 15B to 15E are cross-sectional views illustrating the example of the method for manufacturing the semiconductor device;

FIGS. 16A and 16B are cross-sectional views illustrating examples of a semiconductor device;

FIG. 17A is a plan view illustrating an example of a semiconductor device, and FIGS. 17B to 17D are cross-sectional views illustrating the example of the semiconductor device;

FIG. 18A is a plan view illustrating an example of a semiconductor device, and FIGS. 18B to 18E are cross-sectional views illustrating the example of the semiconductor device;

FIG. 19 is a cross-sectional view illustrating an example of a semiconductor device;

FIG. 20A is a plan view illustrating an example of a semiconductor device, and FIGS. 20B and 20C are cross-sectional views illustrating the example of the semiconductor device;

FIGS. 21A1 and 21A2 are plan views illustrating an example of a semiconductor device, and FIGS. 21B to 21E are cross-sectional views illustrating the example of the semiconductor device;

FIGS. 22A and 22B are cross-sectional views illustrating examples of a semiconductor device;

FIG. 23A is a plan view illustrating an example of a semiconductor device, and FIGS. 23B and 23C are cross-sectional views illustrating the example of the semiconductor device;

FIG. 24 is a schematic perspective view illustrating an example of a semiconductor device;

FIGS. 25A to 25C are cross-sectional views illustrating examples of a semiconductor device;

FIGS. 26A to 26C are cross-sectional views illustrating examples of a semiconductor device;

FIG. 27 is a band diagram of an oxide semiconductor layer;

FIG. 28A is a plan view illustrating an example of a memory device, and FIGS. 28B and 28C are cross-sectional views illustrating the example of the memory device;

FIGS. 29A to 29C are plan views illustrating examples of a memory device, and FIG. 29D illustrates a circuit structure example of a memory cell;

FIG. 30 is a schematic perspective view illustrating an example of a semiconductor device;

FIGS. 31A and 31B are cross-sectional views illustrating examples of a memory device;

FIG. 32A is a plan view illustrating an example of a memory device, FIG. 32B is a cross-sectional view illustrating the example of the memory device, and FIG. 32C illustrates a circuit structure example of a memory cell;

FIG. 33 is a schematic perspective view illustrating an example of a semiconductor device;

FIG. 34A is a plan view illustrating an example of a memory device, and FIG. 34B illustrates a circuit structure example of a memory cell;

FIG. 35 is a cross-sectional view illustrating an example of a memory device;

FIG. 36 is a cross-sectional view illustrating an example of a memory device;

FIG. 37 is a cross-sectional view illustrating an example of a memory device;

FIG. 38 is a cross-sectional view illustrating an example of a memory device;

FIG. 39 is a graph showing an example of hysteresis characteristics;

FIGS. 40A to 40C are equivalent circuit diagrams of a semiconductor device, and FIG. 40D shows I_{d}-V_{g} characteristics of a transistor;

FIG. 41A is a timing chart for explaining an operation of a semiconductor device, and FIG. 41B is a circuit diagram for explaining the operation of the semiconductor device;

FIG. 42A is a timing chart for explaining an operation of a semiconductor device, and FIG. 42B is a circuit diagram for explaining the operation of the semiconductor device;

FIG. 43A is a timing chart for explaining an operation of a semiconductor device, and

FIG. 43B is a circuit diagram for explaining the operation of the semiconductor device;

FIG. 44 is a block diagram illustrating a structure example of a semiconductor device;

FIGS. 45A to 45G illustrate circuit structure examples of memory cells;

FIGS. 46A and 46B are perspective views illustrating structure examples of a semiconductor device;

FIG. 47 is a block diagram illustrating a CPU;

FIGS. 48A and 48B are perspective views of a semiconductor device;

FIGS. 49A and 49B are perspective views of semiconductor devices;

FIG. 50 is a conceptual diagram showing a hierarchy of memory devices;

FIGS. 51A and 51B are circuit diagrams of a semiconductor device of one embodiment of the present invention, and FIG. 51C illustrates an example of an electronic component including the semiconductor device of one embodiment of the present invention;

FIG. 52 illustrates an example of an electronic component;

FIGS. 53A to 53C illustrate an example of a large computer, FIG. 53D illustrates an example of a device for space, and FIG. 53E illustrates an example of a storage system that can be used in a data center;

FIGS. 54A to 54F illustrate examples of electronic devices;

FIGS. 55A to 55G illustrate examples of electronic devices; and

FIGS. 56A to 56F illustrate examples of electronic devices.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In this specification and the like, a transistor containing silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The content of an element such as hydrogen, oxygen, carbon, or nitrogen in a film can be analyzed by secondary ion mass spectrometry (SIMS), X-ray photoelectron spectroscopy (XPS), or electron spectroscopy for chemical analysis (ESCA), for example. XPS is suitable when the content of a target element is high (e.g., 0.5 atomic % or more, or 1 atomic % or more). In contrast, SIMS is suitable when the content of a target element is low (e.g., 0.5 atomic % or less, or 1 atomic % or less). To compare the contents of elements, analysis with a combination of SIMS and XPS is preferably used.

Note that in this specification and the like, a content percentage refers to a proportion of a component contained in a film. In the case where an oxide semiconductor layer contains a metal element X, a metal element Y, and a metal element Z whose atomic numbers are respectively represented by A_{X}, A_{Y}, and A_{Z}, the content percentage of the metal element X can be represented by A_{X}/(A_{X}+A_{Y}+A_{Z}). Moreover, in the case where the atomic ratio of the metal element X, the metal element Y, and the metal element Z contained in the oxide semiconductor layer is represented by B_{X}:B_{Y}:B_{Z}, the content percentage of the metal element X can be represented by B_{X}/(B_{X}+B_{Y}+B_{Z}).

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

Note that “normally-on characteristics” in this specification and the like means a state where a channel exists and a current flows through a transistor even when no voltage is applied to a gate. Furthermore, “normally-off characteristics” means a state where a current does not flow through a transistor when no potential or a ground potential is applied to a gate.

Note that in this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. In other words, A includes a region in contact with B or A includes a region overlapping with B, for example. Similarly, in this specification and the like, when the expression “A covers B” is used, at least part of A covers B. In other words, A includes a region covering B, for example.

In this specification and the like, disconnection refers to a phenomenon in which a layer, a film, or an electrode is divided because of the shape of the formation surface (e.g., a level difference).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

Examples of a groove include an opening, a trench, and a slit. A region where a groove is formed is referred to as a groove portion in some cases.

### Embodiment 1

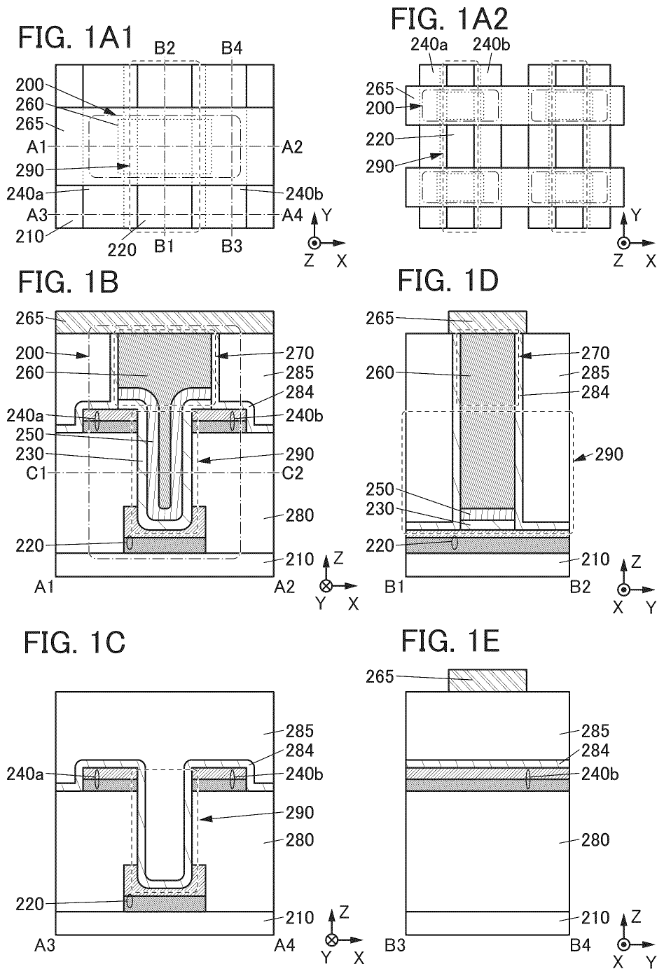

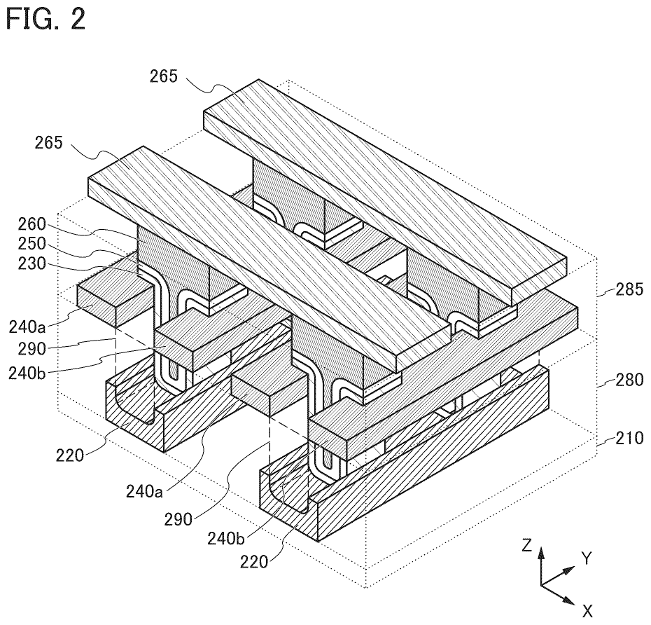

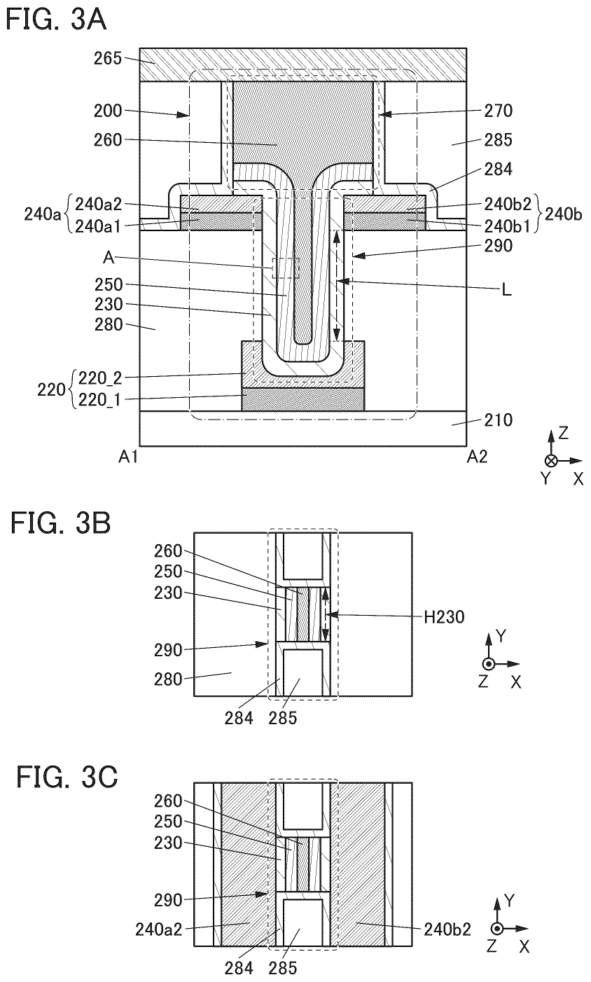

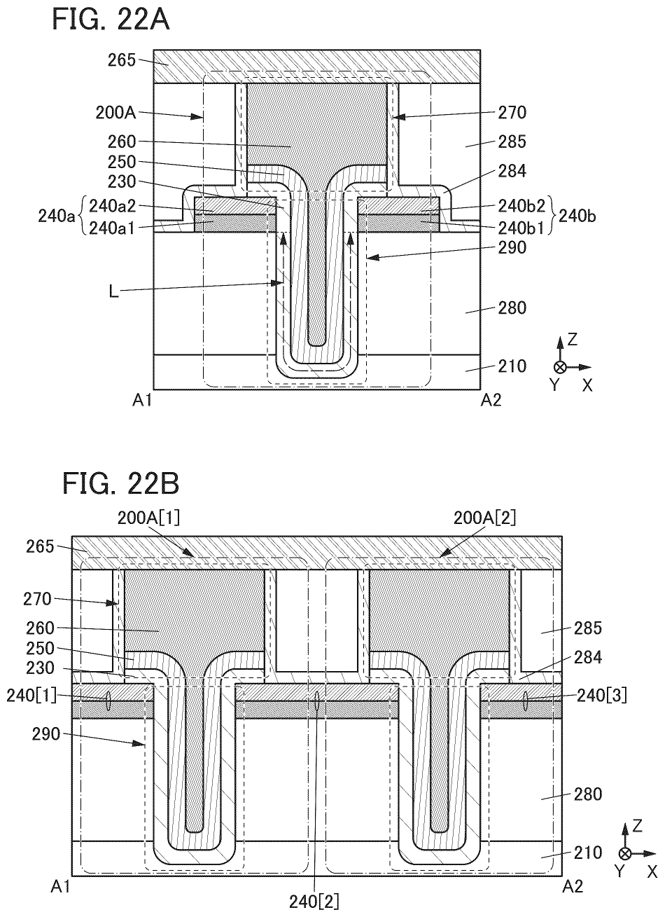

In this embodiment, semiconductor devices of one embodiment of the present invention and a manufacturing method thereof are described with reference to FIGS. 1A1 to 1E, FIG. 2, FIGS. 3A to 3C, FIGS. 4A and 4B, FIGS. 5A and 5B, FIGS. 6A and 6B, FIGS. 7A to 7F, FIGS. 8A to 8E, FIGS. 9A to 9E, FIGS. 10A to 10E, FIGS. 11A to 11E, FIGS. 12A to 12E, FIGS. 13A to 13E, FIGS. 14A to 14E, FIGS. 15A to 15E, FIGS. 16A and 16B, FIGS. 17A to 17D, FIGS. 18A to 18E, FIG. 19, FIGS. 20A to 20C, FIGS. 21A1 to 21E, FIGS. 22A and 22B, FIGS. 23A to 23C, FIG. 24, FIGS. 25A to 25C, and FIGS. 26A to 26C.

### Structure Example 1 of Semiconductor Device

Structures of the semiconductor device of one embodiment of the present invention are described with reference to FIGS. 1A1 to 1E, FIG. 2, FIGS. 3A to 3C, FIGS. 4A and 4B, FIGS. 5A and 5B, FIGS. 6A and 6B.

FIG. 1A1 is a plan view of a semiconductor device including a transistor. FIG. 1A2 is a plan view illustrating an example where a plurality of transistors are arranged. FIG. 1B is a cross-sectional view taken along dashed-dotted line A1-A2 in FIG. 1A1. FIG. 1C is a cross-sectional view taken along dashed-dotted line A3-A4 in FIG. 1A1. FIG. 1D is a cross-sectional view taken along dashed-dotted line B1-B2 in FIG. 1A1. FIG. 1E is a cross-sectional view taken along dashed-dotted line B3-B4 in FIG. 1A1. Note that for simplification, some components are not illustrated in the plan views in FIGS. 1A1 and 1A2. Some components may be omitted also in the following plan views.

FIG. 2 is a schematic perspective view of the semiconductor device illustrated in FIGS. 1A1 to 1E. Specifically, FIG. 2 is a schematic perspective view of a semiconductor device including four transistors. For some components (e.g., interlayer insulating layers), FIG. 2 shows only outlines indicated by dotted lines.

In FIGS. 1A1 to 2, the X direction, the Y direction, and the Z direction are indicated by arrows. Although the same reference signs X, Y, and Z are used in FIGS. 1A1 to 1E and FIG. 2, the directions in FIGS. 1A1 to 1E are not necessarily the same as those in FIG. 2.

FIG. 3A is a cross-sectional view taken along dashed-dotted line A1-A2 in FIG. 1B. FIG. 3A corresponds to an example of an enlarged view of FIG. 1B.

The semiconductor device illustrated in FIGS. 1A1 to 1E includes an insulating layer 210 over a substrate (not illustrated); a transistor 200 over the insulating layer 210; an insulating layer 280 over the insulating layer 210; an insulating layer 284 over the insulating layer 280; an insulating layer 285 over the insulating layer 284; and a conductive layer 265 over the transistor 200, the insulating layer 284, and the insulating layer 285. The insulating layer 210, the insulating layer 280, the insulating layer 284, and the insulating layer 285 function as interlayer films.

### [Transistor 200]

The transistor 200 includes a conductive layer 220 over the insulating layer 210; a conductive layer 240a and a conductive layer 240b over the insulating layer 280; an oxide semiconductor layer 230 over the conductive layer 220, the conductive layer 240a, and the conductive layer 240b; an insulating layer 250 over the oxide semiconductor layer 230; and a conductive layer 260 over the insulating layer 250.

FIG. 3A illustrates an example where the conductive layer 220 has a two-layer structure of a conductive layer 220_1 and a conductive layer 220_2 over the conductive layer 220_1, the conductive layer 240a has a two-layer structure of a conductive layer 240al and a conductive layer 240a2 over the conductive layer 240a1, and the conductive layer 240b has a two-layer structure of a conductive layer 240b1 and a conductive layer 240b2 over the conductive layer 240b1.

FIG. 3B is a cross-sectional view taken along dashed-dotted line C1-C2 in FIG. 1B. FIG. 3C is a cross-sectional view taken along the XY plane including the conductive layer 240a2.

In the transistor 200, the oxide semiconductor layer 230 functions as a semiconductor layer, the conductive layer 260 functions as a gate electrode, the insulating layer 250 functions as a gate insulating layer, the conductive layer 220 functions as one of a source electrode and a drain electrode, and at least one of the conductive layer 240a and the conductive layer 240b functions as the other of the source electrode and the drain electrode. For example, in the case where the conductive layer 240a and the conductive layer 240b are connected to each other, the conductive layer 240a and the conductive layer 240b function as the other of the source electrode and the drain electrode. In the case where the conductive layer 240a and the conductive layer 240b are not connected to each other, one of the conductive layer 240a and the conductive layer 240b functions as the other of the source electrode and the drain electrode.

The conductive layer 265 includes a region in contact with the top surface of the conductive layer 260. Note that the conductive layer 265 may be regarded as a component of the transistor 200. The conductive layer 265 is provided to extend in the X direction. The conductive layer 265 functions as a gate wiring.

In the semiconductor device illustrated in FIGS. 1A1 to 1E, the conductive layer 220 is provided to extend in the Y direction. Note that the conductive layer 220 may be provided in an island shape.

The insulating layer 280 is positioned over the conductive layer 220.

As illustrated in FIGS. 1A1 to 1C, a groove portion 290 reaching the conductive layer 220 is provided in the insulating layer 280. The groove portion 290 extends in the Y direction. In that case, the direction in which the conductive layer 265 extends intersects with the direction in which the groove portion 290 extends.

In FIG. 1B, the conductive layer 220 includes a depressed portion in a region overlapping with the groove portion 290. Note that in the case where the conductive layer 220 has the two-layer structure of the conductive layer 220_1 and the conductive layer 220_2 as illustrated in FIG. 3A, the bottom surface of the depressed portion corresponds to the bottom surface of the depressed portion of the conductive layer 220_2, and the side surface of the depressed portion corresponds to the side surface of the depressed portion of the conductive layer 220_2. Here, the bottom portion of the groove portion 290 can be regarded as including the bottom surface of the depressed portion of the conductive layer 220_2, and the side surface of the groove portion 290 can be regarded as including the side surface of the depressed portion of the conductive layer 220_2 and the side surface of the insulating layer 280.

The conductive layer 240a and the conductive layer 240b are provided over the insulating layer 280 to be apart from each other. The conductive layer 240a and the conductive layer 240b are provided to extend in the Y direction. Note that the conductive layer 240a and the conductive layer 240b may each be provided in an island shape.

In FIG. 1B and the like, the side surface of the conductive layer 240a on the groove portion 290 side is aligned or substantially aligned with the side surface of the groove portion 290. The side surface of the conductive layer 240b on the groove portion 290 side is aligned or substantially aligned with the side surface of the groove portion 290. With such a structure, the conductive layer 240a, the conductive layer 240b, and the groove portion 290 can be formed at a time. When the side surface of the conductive layer 240a and the side surface of the insulating layer 280 are aligned or substantially aligned with each other and the side surface of the conductive layer 240b and the side surface of the insulating layer 280 are aligned or substantially aligned with each other in the groove portion 290, the thickness distribution of the oxide semiconductor layer 230 and the like provided in the groove portion 290 can be uniform. Furthermore, the oxide semiconductor layer 230 and the like can be inhibited from being divided by a step between the conductive layer 240a and the insulating layer 280, a step between the conductive layer 240b and the insulating layer 280, and the like. Here, the side surfaces of the groove portion 290 can be regarded as including the side surface of the conductive layer 240a on the groove portion 290 side and the side surface of the conductive layer 240b on the groove portion 290 side.

The components of the transistor 200 are placed in the groove portion 290 at least partly. Specifically, the oxide semiconductor layer 230, the insulating layer 250, and the conductive layer 260 are placed in the groove portion 290 at least partly.

The oxide semiconductor layer 230 is provided to cover at least part of the side surface and at least part of the bottom surface of the groove portion 290. In the groove portion 290, the oxide semiconductor layer 230 includes a region in contact with the side surface of the insulating layer 280, a region in contact with the side surface of the conductive layer 240a on the groove portion 290 side, a region in contact with the side surface of the conductive layer 240b on the groove portion 290 side, and a region in contact with the side and bottom surfaces of the depressed portion of the conductive layer 220. Outside the groove portion 290, the oxide semiconductor layer 230 includes a region in contact with the top surface of the conductive layer 240a and a region in contact with the top surface of the conductive layer 240b.

Outside the groove portion 290, one end portion of the oxide semiconductor layer 230 is positioned inward from an end portion of the conductive layer 240a, and the other end portion of the oxide semiconductor layer 230 is positioned inward from an end portion of the conductive layer 240b.

The insulating layer 250 is provided to cover the oxide semiconductor layer 230. The insulating layer 250 is in contact with the top surface of the oxide semiconductor layer 230. The insulating layer 250 includes a depressed portion in a position overlapping with the groove portion 290.

The conductive layer 260 includes a portion positioned in the depressed portion of the insulating layer 250. In the groove portion 290, the conductive layer 260 includes a region facing the oxide semiconductor layer 230 with the insulating layer 250 therebetween.

As illustrated in FIG. 3A, outside the groove portion 290, the side surfaces of the conductive layer 260, the insulating layer 250, and the oxide semiconductor layer 230 are aligned or substantially aligned with each other. As illustrated in FIGS. 3B and 3C, inside the groove portion 290, the side surfaces of the conductive layer 260, the insulating layer 250, and the oxide semiconductor layer 230 on the side in contact with the insulating layer 284 are aligned or substantially aligned with each other.

As described above, the oxide semiconductor layer 230 includes a portion positioned in the groove portion 290. The transistor 200 has a structure where a current flows in the vertical direction since one of the source electrode and the drain electrode (here, the conductive layer 220) is positioned below and the other of the source electrode and the drain electrode (here, at least one of the conductive layer 240a and the conductive layer 240b) is positioned above. That is, a channel is formed along the side surface of the groove portion 290.

That is, in the transistor 200 illustrated in FIGS. 1A1 to 1E, the source electrode and the drain electrode are positioned at different heights and a current flows in the semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor 200 illustrated in FIGS. 1A1 to 1E, the source electrode, the semiconductor layer, and the drain electrode can be provided to overlap with each other; thus, the area occupied by the transistor 200 can be much smaller than that of what is called a planar transistor in which a semiconductor layer is provided in a planar shape.

In the groove portion 290, a region of the oxide semiconductor layer 230 facing the conductive layer 260 with the insulating layer 250 therebetween and the vicinity of the region function as the channel formation region of the transistor 200. A region of the oxide semiconductor layer 230 in the vicinity of the conductive layer 220 functions as one of the source region and the drain region, and at least one of a region of the oxide semiconductor layer 230 in the vicinity of the conductive layer 240a and a region of the oxide semiconductor layer 230 in the vicinity of the conductive layer 240b functions as the other of the source region and the drain region. That is, the channel formation region is interposed between the source region and the drain region.

With the above structure, the channel formation region, the source region, and the drain region can be formed in the groove portion 290. Thus, the area occupied by the transistor 200 can be reduced as compared with a planar transistor in which the channel formation region, the source region, and the drain region are provided separately on the XY plane. Thus, the semiconductor device can be highly integrated. In the case where the semiconductor device of one embodiment of the present invention is used for a memory device, the storage capacity per unit area can be increased.

As illustrated in FIG. 3B, the side surface of the conductive layer 260 at the center of the groove portion 290, which faces the side surface of the groove portion 290, faces the side surface of the oxide semiconductor layer 230 with the insulating layer 250 therebetween. That is, in the plan view, two side surfaces of the oxide semiconductor layer 230 on the insulating layer 250 side serve as the channel formation regions. In this case, for example, the channel width of the transistor 200 is determined by the length of the oxide semiconductor layer 230 in the Y direction. It can also be said that the channel width of the transistor 200 is determined by the width of the conductive layer 260 in the Y direction, the width of the insulating layer 250 in the Y direction, or the like. FIG. 3B illustrates a length H230, which is the length of the oxide semiconductor layer 230 in the Y direction. The channel width of the transistor 200 can be calculated to be “2×H230”.

By increasing the length H230 of the oxide semiconductor layer 230 in the Y direction, the channel width per unit area can be increased and the on-state current can be increased. Meanwhile, the area occupied by the transistor 200, e.g., the area of the transistor 200 in the plan view, is roughly determined depending on the length H230. By reducing the length H230, the area occupied by the transistor 200 can be reduced, and the semiconductor device can be highly integrated.

In the case where the groove portion 290 is formed by a photolithography method, the width of the groove portion 290 in the X direction is determined by the light exposure limit of photolithography. In addition, the width of the groove portion 290 in the X direction is determined by the thicknesses of the oxide semiconductor layer 230, the insulating layer 250, and the conductive layer 260 provided in the groove portion 290. The width of the groove portion 290 in the X direction is preferably, for example, greater than or equal to 5 nm, greater than or equal to 10 nm, or greater than or equal to 20 nm and less than or equal to 300 nm, less than or equal to 200 nm, less than or equal to 100 nm, less than or equal to 60 nm, less than or equal to 50 nm, less than or equal to 40 nm, or less than or equal to 30 nm.

The channel length of the transistor 200 illustrated in FIGS. 1A1 to 1E is the distance between the source region and the drain region. For example, the channel length of the transistor 200 can be regarded as the distance between an end portion of a region where the oxide semiconductor layer 230 is in contact with the conductive layer 220 and an end portion of a region where the oxide semiconductor layer 230 is in contact with the conductive layer 240a or the conductive layer 240b in the cross-sectional view. That is, it can be said that the channel length of the transistor 200 is determined by the thickness of the insulating layer 280 over the conductive layer 220. In FIG. 3A, a channel length L of the transistor 200 is indicated by a dashed double-headed arrow.

Although a planar transistor is difficult to further miniaturize since its channel length is limited by the light exposure limit of photolithography, the channel length of the transistor 200 can be set by the thickness of the insulating layer 280. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm and greater than or equal to 0.1 nm, greater than or equal to 1 nm, or greater than or equal to 5 nm). Accordingly, the transistor 200 can have a higher on-state current and higher frequency characteristics.

The channel length of the transistor 200 is determined by the thickness of the insulating layer 280, and thus does not affect the area occupied by the transistor 200, for example, the area of the transistor 200 in the plan view. When the channel length of the transistor 200 is, for example, less than or equal to 1 μm, less than or equal to 500 nm, or less than or equal to 300 nm, the productivity, yield, and the like can be improved in formation of the groove portion 290, for example.

Thus, the channel length of the transistor included in the semiconductor device of one embodiment of the present invention is preferably greater than or equal to 0.1 nm, greater than or equal to 1 nm, or greater than or equal to 5 nm and less than or equal to 1 μm, less than or equal to 500 nm, or less than or equal to 300 nm.

The channel length of the transistor illustrated in FIGS. 1A1 to 1E can be controlled by the thickness of the insulating layer 280. Thus, a transistor with an extremely small channel length, which is difficult to achieve in a planar transistor, can be achieved. Accordingly, a transistor with a small occupation area and a high on-state current can be provided.

The channel length L of the transistor 200 is preferably smaller than at least a channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables a transistor with favorable electrical characteristics and high reliability. Note that the channel width W of the transistor 200 may be smaller than or equal to the channel length L of the transistor 200. This structure enables miniaturization or high integration of the semiconductor device.

As described above, the insulating layer 250 and the conductive layer 260 are provided along the shape of the oxide semiconductor layer 230. This makes the distance between the conductive layer 260 and the oxide semiconductor layer 230 substantially uniform, so that a gate electric field can be substantially uniformly applied to the oxide semiconductor layer 230.

The conductive layer 220_2 illustrated in FIG. 3A includes a depressed portion. When the conductive layer 220_2 includes the depressed portion in a position overlapping with the groove portion 290, unlike in the case where the depressed portion is not provided, the levels of the bottom surfaces of the insulating layer 250 and the conductive layer 260 in the groove portion 290 can be lower than the level of the top surface of the conductive layer 220_2 which is in contact with the insulating layer 280, with the top surface of the insulating layer 210 in a region overlapping with the conductive layer 220 used as a reference. Here, the levels of the surfaces can be determined using the formation surface of the transistor as a reference. Here, the top surface of the insulating layer 210 in a region overlapping with the conductive layer 220 is used as the reference. The surface used as the reference is not limited to the formation surface of the transistor. For example, the top surface of the substrate where the transistor or the semiconductor device is provided may be used as the reference.

When the conductive layer 220_2 includes a depressed portion, the side surface of the conductive layer 220_2 is in contact with the oxide semiconductor layer 230. Accordingly, the contact area between the conductive layer 220_2 and the oxide semiconductor layer 230 can be increased, so that the contact resistance therebetween can be reduced. This can inhibit a decrease in on-state current of the transistor 200 due to the contact resistance between the conductive layer 220_2 and the oxide semiconductor layer 230.

In addition, a gate electric field is easily applied to the channel formation region of the oxide semiconductor layer 230, so that the electrical characteristics of the transistor 200 can be improved. Furthermore, a gate electric field is easily applied to a region of the oxide semiconductor layer 230 in contact with the conductive layer 220_2, so that the on-state current of the transistor 200 can be increased. The electrical characteristics of the transistor 200 can be improved when either the conductive layer 220 or the conductive layer 240a or 240b is used as the drain electrode.

As illustrated in FIG. 3A, the depressed portion of the conductive layer 220_2 preferably includes a curved portion. The depressed portion including a curved portion can reduce electric field concentration and increase the withstand voltage of the transistor, so that the electrostatic breakdown of the transistor can be inhibited. Accordingly, the reliability of the semiconductor device can be improved.

In the case where a depressed portion is provided in the conductive layer 220_2, a depressed portion is sometimes provided in the insulating layer 210 in a position overlapping with the groove portion 290.

FIG. 1B illustrates an example where the conductive layer 220 includes a depressed portion. Note that the present invention is not limited thereto. For example, the top surface of the conductive layer 220 can be flat.

As illustrated in FIG. 3A, the insulating layer 284 is provided over the insulating layer 280, the conductive layer 240a, and the conductive layer 240b. Outside the groove portion 290, the insulating layer 284 includes a region in contact with the top and side surfaces of each of the conductive layer 240a and the conductive layer 240b, a region in contact with the side surface of the oxide semiconductor layer 230, a region in contact with the side surface of the insulating layer 250, and a region in contact with the side surface of the conductive layer 260. As illustrated in FIGS. 3B and 3C, in the groove portion 290, the insulating layer 284 includes a region in contact with the side surface of the oxide semiconductor layer 230, a region in contact with the side surface of the insulating layer 250, a region in contact with the side surface of the conductive layer 260, and a region in contact with the side surface of the insulating layer 280. The insulating layer 284 includes a region in contact with the side surface of the conductive layer 240a on the groove portion 290 side and a region in contact with the side surface of the conductive layer 240b on the groove portion 290 side.

An insulating layer having a function of capturing or fixing hydrogen is preferably used as the insulating layer 284. When the insulating layer 284 has a function of capturing or fixing hydrogen, hydrogen in the oxide semiconductor layer 230 can be diffused into the insulating layer 284 to be captured or fixed. In addition, diffusion of hydrogen from above the insulating layer 284 into the oxide semiconductor layer 230 can be inhibited. Thus, the hydrogen concentration in the oxide semiconductor layer 230 can be reduced. For the insulating layer 284, an aluminum oxide film, a hafnium oxide film, a hafnium silicate film, or the like can be used.

As the insulating layer 284, a barrier insulating layer against hydrogen can be used. In this case, diffusion of hydrogen from above the insulating layer 284 into the oxide semiconductor layer 230 can be inhibited. A silicon nitride film and a silicon nitride oxide film can be suitably used for the insulating layer 284 because they release few impurities (e.g., water and hydrogen) and are less likely to transmit oxygen and hydrogen.

In the case where a silicon nitride film is used for the insulating layer 284, the silicon nitride film is preferably formed by a sputtering method. A deposition gas in a sputtering method need not include molecules containing hydrogen; thus, the hydrogen concentration in the insulating layer 284 can be reduced. When the insulating layer 284 is formed by a sputtering method, a high-density silicon nitride film can be obtained.

The insulating layer 284 may have a stacked-layer structure of an insulating layer having a function of capturing or fixing hydrogen and a barrier insulating layer against hydrogen. For example, a stack of an aluminum oxide film and a silicon nitride film over the aluminum oxide film may be used as the insulating layer 284.

An opening portion 270 reaching the insulating layer 250 is provided in the insulating layer 284 to overlap with the groove portion 290. The conductive layer 260 is placed to be positioned in the opening portion 270 at least partly. The conductive layer 260 is in contact with the insulating layer 250 in the opening portion 270.

Note that the insulating layer 284 includes an opening portion also in the groove portion 290 in a region not overlapping with the insulating layer 250. The insulating layer 285 is provided to fill the opening portion.

The insulating layer 285 functions as an interlayer film and is thus preferably formed using the above-described material with a low dielectric constant. For example, the insulating layer 285 preferably includes a silicon oxide film.

The conductive layer 260 is provided to fill the groove portion 290 and the opening portion 270. The conductive layer 260 includes a portion facing the oxide semiconductor layer 230 with the insulating layer 250 therebetween in the groove portion 290 and a portion positioned in the opening portion 270.

A portion of the conductive layer 265 not overlapping with the groove portion 290 is mainly positioned over the insulating layer 285. Thus, the conductive layer 265 mainly overlaps with the conductive layer 240a with the insulating layers 284 and 285 therebetween. This can increase the physical distance between the conductive layers 265 and 240a, and reduce the parasitic capacitance generated therebetween. Note that the conductive layers 240a and 265 may include a portion where they overlap with each other without the insulating layer 285 therebetween. The same applies to the positions of the conductive layers 240b and 265.

That is, the transistor 200 has a structure where the parasitic capacitance generated between the other of the source electrode and the drain electrode and the gate wiring is reduced. Accordingly, the frequency characteristics of a circuit including the transistor can be improved.

FIG. 3A illustrates an example where the width of the opening portion 270 is larger than the width of the groove portion 290. Note that in the plan view, the area where the opening portion 270 and the groove portion 290 overlap with each other is preferably small. The smaller area where the opening portion 270 and the groove portion 290 overlap with each other can increase the physical distance between the conductive layer 240a and the conductive layer 260, so that the parasitic capacitance generated therebetween can be reduced. Similarly, the physical distance between the conductive layer 240b and the conductive layer 260 can be increased, so that the parasitic capacitance generated therebetween can be reduced.

Although this embodiment describes the example where the opening portion 270 has a quadrangular shape in the plan view, the present invention is not limited thereto. The opening portion 270 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than 180°) or a convex polygonal shape (a polygonal shape all the interior angles of which are less than or equal to 180°).

The width of the opening portion 270 changes in the depth direction in some cases. Here, the maximum width of the opening portion 270 provided in the insulating layer 284 in the cross-sectional view is particularly used as the width of the opening portion 270.

The top surface of the conductive layer 260 and the top surface of the insulating layer 285 or the insulating layer 284 are preferably level with or substantially level with each other. The conductive layer 265 is provided over the insulating layer 285, the insulating layer 284, and the conductive layer 260, and is in contact with the top surface of the conductive layer 260. It can be said that the conductive layer 260 and the conductive layer 265 are connected to each other.

### <Materials for Semiconductor Device>

Materials that can be used for the semiconductor device of this embodiment are described below. Note that the layers included in the semiconductor device of this embodiment may have a single-layer structure or a stacked-layer structure. Note that the conductive layer 240a and the conductive layer 240b are sometimes collectively referred to as a conductive layer 240 in the following description.

### [Oxide Semiconductor Layer]

As described above, the oxide semiconductor layer 230 includes the channel formation region. The oxide semiconductor layer 230 further includes the source region and the drain region. The source region and the drain region are n-type regions (low-resistance regions) having a higher carrier concentration than the channel formation region. The oxide semiconductor layer 230 may have a single-layer structure or a stacked-layer structure of two or more layers.

There is no particular limitation on the crystallinity of the semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case degradation of the transistor characteristics can be inhibited.

In the transistor 200, the oxide semiconductor layer 230 including the channel formation region preferably includes a metal oxide (also referred to as an oxide semiconductor) functioning as a semiconductor. In the case where a metal oxide functioning as a semiconductor is used for the oxide semiconductor layer 230, the transistor 200 can be regarded as an OS transistor.

When oxygen vacancies (Vo) and impurities are in a channel formation region of an oxide semiconductor in an OS transistor, electrical characteristics of the OS transistor easily vary and the reliability thereof might worsen. In some cases, a defect that is an oxygen vacancy into which hydrogen enters (hereinafter also referred to as V_{O}H in some cases) is formed and an electron serving as a carrier is generated. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

The band gap of the metal oxide functioning as a semiconductor is preferably greater than or equal to 2.0 eV, further preferably greater than or equal to 2.5 eV. The use of a metal oxide having a wide band gap for the oxide semiconductor layer 230 can reduce the off-state current of the transistor 200. The off-state current of the OS transistor is small, so that power consumption of the semiconductor device can be sufficiently reduced. The OS transistor has high frequency characteristics, which enables the semiconductor device to operate at high speed. For the oxide semiconductor layer that can be used as the semiconductor layer of the transistor of one embodiment of the present invention, description in Embodiment 2 can be referred to. Here, detailed description thereof is omitted.

Note that for the semiconductor device of this embodiment, a transistor including another semiconductor material in its channel formation region may be used. Examples of another semiconductor material include a single-element semiconductor and a compound semiconductor.

Examples of the single-element semiconductor that can be used as the semiconductor material include silicon and germanium. Examples of silicon that can be used as the semiconductor material include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used for the semiconductor layer preferably includes an amorphous structure. Boron arsenide that can be used for the semiconductor layer preferably includes a crystal with a cubic structure. Other examples of the compound semiconductor include an organic semiconductor and a nitride semiconductor. Note that the above-described oxide semiconductor is also one kind of the compound semiconductor. These semiconductor materials may contain an impurity as a dopant.

The semiconductor device of this embodiment may include a transistor containing a layered material functioning as a semiconductor in a channel formation region. Note that the details of the layered material will be described in Embodiment 7.

### [Insulating Layer]

An inorganic insulating film is preferably used for each of the insulating layers (the insulating layer 210, the insulating layer 280, the insulating layer 284, the insulating layer 285, the insulating layer 250, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With miniaturization and high integration of a transistor, for example, a problem such as generation of a leakage current may arise because of a thin gate insulating layer. When a material with a high dielectric constant (a high-k material) is used for the gate insulating layer, the voltage at the time of operation of the transistor can be reduced while the physical thickness is maintained. Furthermore, the equivalent oxide thickness (EOT) of the gate insulating layer can be reduced. By contrast, when a material with a low dielectric constant is used for the insulating layer functioning as an interlayer film, the parasitic capacitance generated between wirings can be reduced. Thus, a material is preferably selected depending on the function of an insulating layer. Note that a material with a low dielectric constant is a material with high dielectric strength. Examples of the material with a high dielectric constant include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low dielectric constant include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for the insulating layer included in the semiconductor device. Examples of the material that can have ferroelectricity include metal oxides such as hafnium oxide, zirconium oxide, and hafnium zirconium oxide. Examples of the material that can have ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. Note that in the above, lanthanum may be replaced with lanthanoid. As the material that can have ferroelectricity, a piezoelectric ceramic having a perovskite structure, such as lead titanate (PbTiOₓ), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can have ferroelectricity also include perovskite-type oxynitrides such as SrTaO₂N and BaTaO₂N, and GaFcO₃ with a κ-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, an insulating layer 130 to be described in Embodiment 3 can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer 130 needs to include a crystal. It is particularly preferable that the insulating layer include a crystal having an orthorhombic crystal structure, in which case ferroelectricity is exhibited. A crystal included in the insulating layer may have one or more of crystal structures selected from tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide, a nitride such as aluminum nitride or silicon nitride, a nitride oxide such as silicon nitride oxide can be used.

Specific examples of the material for the insulating layer having a function of inhibiting passage of oxygen and impurities such as water and hydrogen include a metal oxide such as aluminum oxide, magnesium oxide, gallium oxide, germanium oxide, yttrium oxide, zirconium oxide, lanthanum oxide, neodymium oxide, hafnium oxide, tantalum oxide, and an oxide containing aluminum and hafnium (hafnium aluminate). Furthermore, nitrides such as aluminum nitride, aluminum titanium nitride, and silicon nitride can be given, for example. Moreover, a nitride oxide such as silicon nitride oxide can be given.

An insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, oxygen vacancies in the oxide semiconductor layer can be reduced. Examples of a material for an insulating layer in which a region containing excess oxygen is easily formed include silicon oxide, silicon oxynitride, and porous silicon oxide.

As the insulating layer in contact with the oxide semiconductor layer or the insulating layer provided in the vicinity of the oxide semiconductor layer, a barrier insulating layer against hydrogen is preferably used. When the insulating layer has a barrier property against hydrogen, diffusion of hydrogen into the oxide semiconductor layer can be inhibited.

Examples of a material for an insulating layer having a function of capturing or fixing hydrogen include metal oxides such as an oxide containing hafnium, an oxide containing magnesium, an oxide containing aluminum, an oxide containing aluminum and hafnium (hafnium aluminate), an oxide containing hafnium and zirconium (hafnium zirconium oxide), and an oxide containing hafnium and silicon (hafnium silicate). Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced. For example, the amorphous structure of the metal oxide may be achieved by addition of silicon. For example, an oxide containing hafnium and silicon (hafnium silicate) is preferably used.

When the insulating layer has an amorphous structure, formation of a crystal grain boundary can be inhibited. Inhibiting formation of a crystal grain boundary can increase the planarity of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce a leakage current due to the defect states in the crystal grain boundary. Thus, the insulating layer can function as an insulating film with a low leakage current.

Note that the insulating layer may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability of a target substance, or a function of inhibiting diffusion of a target substance). Note that hydrogen described as a target substance refers to at least one of a hydrogen atom, a hydrogen molecule, a water molecule, a substance bonded to hydrogen, such as OH⁻, and the like. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of a material for a barrier insulating layer against hydrogen include aluminum oxide, magnesium oxide, hafnium oxide, gallium oxide, silicon nitride, and silicon nitride oxide.

Examples of a material for a barrier insulating layer against oxygen include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The insulating layer 210 functions as an interlayer film and is thus preferably formed using the above-described material with a low dielectric constant. In the case where a material with a low dielectric constant is used for an interlayer film, the parasitic capacitance generated between wirings can be reduced.

As the insulating layer 210, a barrier insulating layer against hydrogen is preferably used. When the insulating layer 210 provided below the oxide semiconductor layer 230 has a barrier property against hydrogen, diffusion of hydrogen into the oxide semiconductor layer 230 from below the transistor 200 can be inhibited. For example, a silicon nitride film is preferably used as the insulating layer 210.

An insulating layer having a function of capturing or fixing hydrogen is preferably used as the insulating layer 210. When the insulating layer 210 has a function of capturing or fixing hydrogen, hydrogen in the oxide semiconductor layer 230 can be diffused into the insulating layer 210 and the hydrogen can be captured or fixed. Thus, the hydrogen concentration in the oxide semiconductor layer 230 can be reduced.

The concentration of impurities such as hydrogen and water in the insulating layer 210 is preferably reduced. This can inhibit entry of impurities such as hydrogen and water into the channel formation region of the oxide semiconductor layer 230.

FIG. 3A illustrates an example where the insulating layer 210 has a single-layer structure. Note that the insulating layer 210 can have a stacked-layer structure of two or more layers. For example, the insulating layer 210 can have a two-layer structure of a first insulating layer and a second insulating layer over the first insulating layer. In that case, a barrier insulating layer against hydrogen is preferably used as the first insulating layer, and an insulating layer having a function of capturing or fixing hydrogen is preferably used as the second insulating layer, for example. Specifically, a silicon nitride film is preferably used as the first insulating layer, and a hafnium oxide film, a hafnium silicate film, or an aluminum oxide film is preferably used as the second insulating layer.

The insulating layer 280 functions as an interlayer film and is thus preferably formed using the above-described material with a low dielectric constant. In the case where a material with a low dielectric constant is used for an interlayer film, the parasitic capacitance generated between wirings can be reduced. For example, silicon oxide or silicon oxynitride can be suitably used for the insulating layer 280.

The concentration of impurities such as hydrogen and water in the insulating layer 280 is preferably reduced. This can inhibit entry of impurities such as hydrogen and water into the channel formation region of the oxide semiconductor layer 230.

For example, the insulating layer including a region containing excess oxygen can be formed by deposition by a sputtering method in an oxygen-containing atmosphere. Since a molecule containing hydrogen is not used as a film formation gas in the sputtering method, the concentration of hydrogen in the insulating layer 280 can be reduced. When at least part of the insulating layer 280 is formed by a sputtering method in this manner, oxygen can be supplied from the insulating layer 280 to the channel formation region of the oxide semiconductor layer 230, so that oxygen vacancies and V_{O}H therein can be reduced.

Note that since the thickness of the insulating layer 280 over the conductive layer 220 affects the channel length of the transistor 200, the thickness of the insulating layer 280 is set as appropriate depending on the design value of the channel length of the transistor 200.

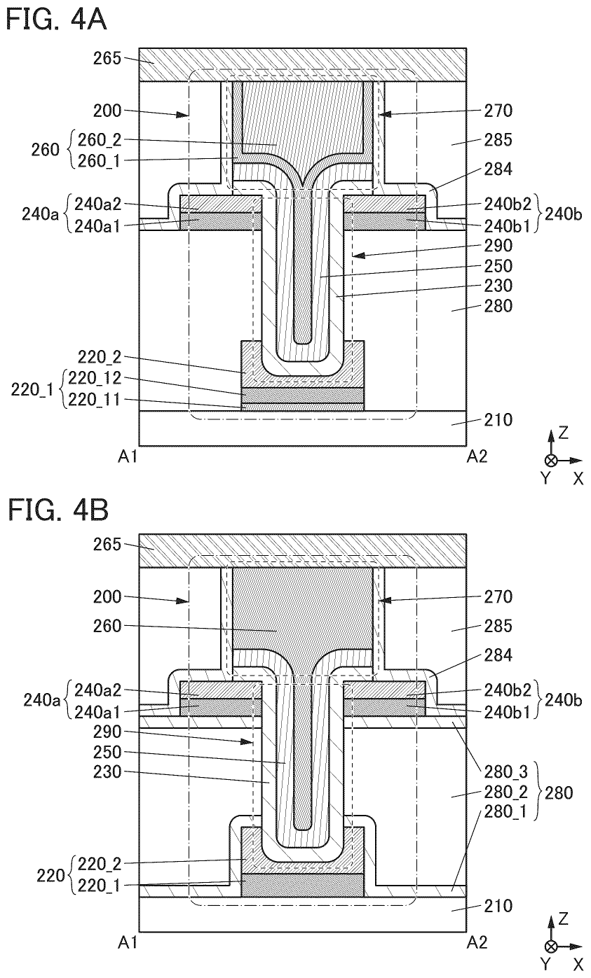

FIG. 3A illustrates an example where the insulating layer 280 has a single-layer structure. Note that the insulating layer 280 can have a stacked-layer structure of two or more layers. For example, as illustrated in FIG. 4B, the insulating layer 280 can have a three-layer structure of an insulating layer 280_1, an insulating layer 280_2 over the insulating layer 280_1, and an insulating layer 280_3 over the insulating layer 280_2. In that case, the above-described material with a low dielectric constant is preferably used for the insulating layer 280_2 and a barrier insulating layer against oxygen is preferably used as each of the insulating layer 280_1 and the insulating layer 280_3. Thus, the conductive layers 220, 240a, and 240b can be inhibited from being oxidized and having an increased resistance.

For example, a silicon nitride film or an aluminum oxide film is preferably used as each of the insulating layer 280_1 and the insulating layer 280_3, and a silicon oxide film is preferably used as the insulating layer 280_2. Note that each of the insulating layer 280_1 and the insulating layer 280_3 may have a stacked-layer structure of two or more layers.

As the insulating layer 250, a barrier insulating layer against hydrogen is preferably used. When the insulating layer 250 provided over the oxide semiconductor layer 230 has a barrier property against hydrogen, diffusion of hydrogen contained in the conductive layer 260 into the oxide semiconductor layer 230 can be inhibited. For example, a silicon nitride film is suitable for the insulating layer 250 because of its high barrier property against hydrogen.

Since the insulating layer 250 is in contact with the oxide semiconductor layer 230, an insulating layer having a function of capturing or fixing hydrogen is preferably used. In this case, hydrogen contained in the oxide semiconductor layer 230 can be captured or fixed more effectively. Thus, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

As the insulating layer 250, an insulating layer including a region containing excess oxygen is preferably used. Accordingly, oxygen can be supplied from the insulating layer 250 to the oxide semiconductor layer 230, so that oxygen vacancies in the oxide semiconductor layer 230 can be reduced. A silicon oxide film, a silicon oxynitride film, or the like has a thermally stable structure and is thus suitable for the insulating layer 250.

FIG. 3A illustrates an example where the insulating layer 250 has a single-layer structure. Note that the insulating layer 250 can have a stacked-layer structure of two or more layers. In this case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting hydrogen from the oxide semiconductor layer 230 and a function of inhibiting diffusion of hydrogen into the oxide semiconductor layer 230.

For example, the insulating layer 250 can have a two-layer structure of a first insulating layer and a second insulating layer over the first insulating layer. In this case, the first insulating layer is in contact with the oxide semiconductor layer 230. For example, an insulating layer having a function of capturing or fixing hydrogen is preferably used as the first insulating layer, and a barrier insulating layer against hydrogen is preferably used as the second insulating layer. With such a structure, the hydrogen concentration in the oxide semiconductor layer 230 can be reduced and diffusion of hydrogen into the oxide semiconductor layer 230 can be inhibited. Thus, the transistor can have high reliability. For example, a hafnium oxide film or a hafnium silicate film can be used as the first insulating layer, and a silicon nitride film can be used as the second insulating layer.

Alternatively, for example, an insulating layer including a region containing excess oxygen is preferably used as the first insulating layer, and a barrier insulating layer against hydrogen is preferably used as the second insulating layer. Alternatively, for example, an insulating layer including a region containing excess oxygen is preferably used as the first insulating layer, and an insulating layer having a function of capturing or fixing hydrogen is preferably used as the second insulating layer. With such a structure, the amount of oxygen vacancies and the hydrogen concentration in the oxide semiconductor layer 230 can be reduced, so that diffusion of hydrogen into the oxide semiconductor layer 230 can be inhibited. Thus, the transistor can have high reliability.

The insulating layer 250 can include a third insulating layer between the oxide semiconductor layer 230 and the first insulating layer, for example. In other words, the insulating layer 250 can have a three-layer structure of the third insulating layer, the first insulating layer over the third insulating layer, and the second insulating layer over the first insulating layer.

For example, an insulating layer including a region containing excess oxygen or an insulating layer containing a material with a low dielectric constant is preferably used as the third insulating layer, an insulating layer having a function of capturing or fixing hydrogen is preferably used as the first insulating layer, and an insulating layer having a barrier property against hydrogen and oxygen is preferably used as the second insulating layer. A silicon oxide film or a silicon oxynitride film is preferably used as the third insulating layer. When an oxide film is used as the third insulating layer in contact with the oxide semiconductor layer 230, oxygen can be supplied to the oxide semiconductor layer 230. Providing the second insulating layer can inhibit oxygen contained in the third insulating layer from diffusing into the conductive layer 260 and inhibit the conductive layer 260 from being oxidized. Furthermore, a reduction in the amount of oxygen supplied from the third insulating layer to the oxide semiconductor layer 230 can be inhibited.

The insulating layer 250 can include a fourth insulating layer between the oxide semiconductor layer 230 and the third insulating layer, for example. In other words, the insulating layer 250 can have a four-layer structure of the fourth insulating layer, the third insulating layer over the fourth insulating layer, the first insulating layer over the third insulating layer, and the second insulating layer over the first insulating layer.

As the fourth insulating layer, an insulating layer having a barrier property against oxygen is preferably used. Note that the first to third insulating layers can have a structure similar to that of the layers used in the above three-layer structure. The fourth insulating layer is in contact with the oxide semiconductor layer 230 and the conductive layer 240. When the fourth insulating layer has a barrier property against oxygen, release of oxygen from the oxide semiconductor layer 230 can be inhibited. This inhibits formation of an oxide film on the side surface of the conductive layer 240 due to oxidization of the side surface. It is thus possible to inhibit a reduction in the on-state current or field-effect mobility of the transistor 200.

As the fourth insulating layer, an aluminum oxide film is preferably used, for example. An aluminum oxide film has a function of capturing or fixing hydrogen, and is thus suitably used as the fourth insulating layer in contact with the oxide semiconductor layer 230. Specifically, the insulating layer 250 preferably has a four-layer structure where an aluminum oxide film, a silicon oxide film, a hafnium oxide film, and a silicon nitride film are stacked in this order from the oxide semiconductor layer 230 side.

The insulating layer 250 is preferably thin. For example, when the insulating layer 250 has a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in a subthreshold region when a drain voltage is constant and a drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5 nm, further preferably greater than or equal to 0.5 nm and less than or equal to 5 nm, further preferably greater than or equal to 1 nm and less than 5 nm, further preferably greater than or equal to 1 nm and less than or equal to 3 nm. Note that each layer included in the insulating layer 250 at least partly includes a region with the above-described thickness.

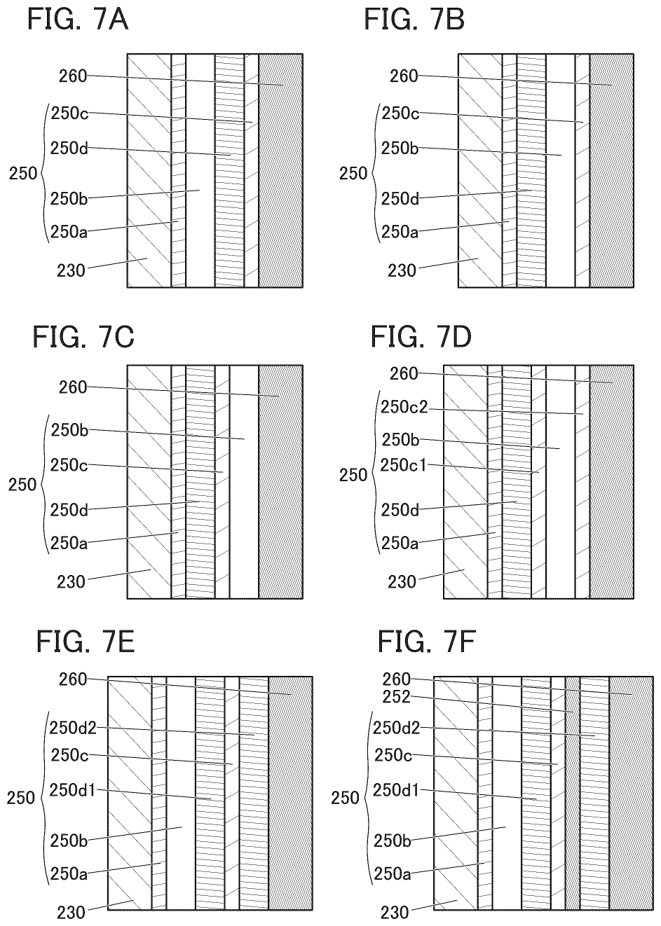

Typically, the thicknesses of the fourth insulating layer, the third insulating layer, the first insulating layer, and the second insulating layer are 1 nm, 2 nm, 2 nm, and 1 nm, respectively. For example, as illustrated in FIG. 7A, aluminum oxide with a thickness of 1 nm can be used as an insulating layer 250a, silicon oxide with a thickness of 2 nm can be used as an insulating layer 250b, hafnium oxide, hafnium zirconium oxide, or hafnium zirconium oxide containing yttrium with a thickness of 2 nm can be used as an insulating layer 250d, and silicon nitride with a thickness of 1 nm can be used as an insulating layer 250c. Here, the insulating layer 250a corresponds to the fourth insulating layer, the insulating layer 250b corresponds to the third insulating layer, the insulating layer 250d corresponds to the first insulating layer, and the insulating layer 250c corresponds to the second insulating layer. In this case, over the oxide semiconductor layer 230, the insulating layer 250 includes the insulating layer 250a, the insulating layer 250b over the insulating layer 250a, the insulating layer 250d over the insulating layer 250b, and the insulating layer 250c over the insulating layer 250d. Note that as illustrated in FIG. 7A and the like, when the groove portion 290 is seen locally, it can be regarded that the insulating layer 250a is provided inside the oxide semiconductor layer 230, the insulating layer 250b is provided inside the insulating layer 250a, the insulating layer 250d is provided inside the insulating layer 250b, and the insulating layer 250c is provided inside the insulating layer 250d. Note that FIG. 7A is an enlarged view corresponding to a region A illustrated in FIG. 3A.

Note that in formation of the insulating layer 250 having a stacked-layer structure of a plurality of insulating films, an atomic layer deposition (ALD) process is preferably performed twice or more. For example, two or more kinds of the insulating films in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of films, e.g., two or more kinds of insulating films are successively formed through an ALD process, the productivity can be increased.

In the structure illustrated in FIG. 7A, an insulator having a function of capturing or fixing hydrogen can be provided as the insulating layer 250d. For example, an oxide containing hafnium is preferably used as the insulating layer 250d. As the oxide containing hafnium, for example, hafnium oxide, hafnium aluminate, hafnium silicate, hafnium zirconium oxide, hafnium zirconium oxide containing yttrium, or the like can be used. Hafnium zirconium oxide containing a lanthanoid such as lanthanum can also be used as the insulating layer 250d.

Here, when the insulating layer 250d is provided between the insulating layer 250c and the insulating layer 250b, hydrogen contained in the insulating layer 250b and the like can be captured or fixed more effectively. The channel formation region of the oxide semiconductor layer 230 and the insulating layers 250a and 250d having a function of capturing or fixing hydrogen are provided below the insulating layer 250c having a function of inhibiting diffusion of hydrogen. In a region where diffusion of hydrogen from above is blocked by the insulating layer 250c, hydrogen contained in the channel formation region or the like of the oxide semiconductor layer 230 can be captured or fixed by the insulating layers 250a and 250d. Accordingly, the hydrogen concentration in the oxide semiconductor layer 230 can be reduced, so that a shift in the initial characteristics of the transistor 200 in the negative direction can be inhibited and the transistor 200 can have normally-off characteristics. In addition, negative drift degradation in a +gate bias temperature (+GBT) stress test can be inhibited.

Note that the insulating layers 250a, 250b, and 250d can be provided, excluding the insulating layer 250c. In this case, an insulator having a function of inhibiting diffusion of hydrogen (e.g., silicon nitride) is preferably provided as the insulating layer 284 over the insulating layer 250. With such a structure, the oxide semiconductor layer 230 and the insulating layers 250a and 250d having a function of capturing or fixing hydrogen are formed in a region covered with silicon nitride having a high hydrogen barrier property. Accordingly, hydrogen contained in the channel formation region or the like of the oxide semiconductor layer 230 can be captured or fixed by the insulating layers 250a and 250d.

With the above structure, the i-type or substantially i-type channel formation region and the n-type source and drain regions can be formed; therefore, a semiconductor device having favorable electrical characteristics can be provided. The semiconductor device with the above structure can have favorable electrical characteristics even when being miniaturized or highly integrated. Furthermore, miniaturization of the transistor 200 can improve the high frequency characteristics. Specifically, the cutoff frequency can be improved.

The metal oxide containing hafnium used for the insulating layer 250d preferably functions as a high-k material. With such a structure, a gate potential applied during operation of the transistor can be lowered while the physical thickness of the gate insulator is maintained. In addition, the equivalent oxide thickness (EOT) of the insulator functioning as the gate insulator can be reduced.

The insulating layer 250d preferably has ferroelectricity. For example, hafnium zirconium oxide having ferroelectricity, hafnium zirconium oxide containing yttrium and having ferroelectricity, or the like can be used as the insulating layer 250d. The insulating layer 250d may have a structure where a layer of hafnium zirconium oxide is stacked over a layer of hafnium zirconium oxide containing yttrium. Note that in the case where a ferroelectric is used for the insulating layer 250d, the insulating layer 250d does not necessarily have a function of capturing or fixing hydrogen. For example, the above-described material that can have ferroelectricity can be used for the insulating layer 250d.

The use of a ferroelectric for the insulating layer 250d as described above enables the transistor 200 to function as a ferroelectric field effect transistor (FeFET). The FeFET functions as a memory element by itself. Thus, the memory element can be smaller than a dynamic random access memory (DRAM) element including a transistor and a capacitor. Accordingly, miniaturization and high integration of a memory device including the transistor 200 can be achieved. In addition, the productivity of a memory device including the transistor 200 can be improved.

Although the insulating layer 250 has the three-layer structure of the insulating layers 250a to 250c or the four-layer structure of the insulating layers 250a to 250d in the above description, the present invention is not limited thereto. The insulating layer 250 can have a single-layer structure, a two-layer structure, or a stacked-layer structure of five or more layers. The insulating layer 250 can have a structure including at least one of the insulating layers 250a to 250d. For example, the insulating layer 250 can have a single-layer structure of the insulating layer 250c. In this case, the insulating layer 250 can be formed using a single layer of hafnium zirconium oxide. When the insulating layer 250 is formed of one, two, or three of the insulating layers 250a to 250d, the manufacturing process of the semiconductor device can be simplified and the productivity can be improved.

In the case where the insulating layer 250 has a four-layer structure or a five-layer structure, any of stacked-layer structures illustrated in FIGS. 7B to 7F can be employed, for example. Here, FIGS. 7B to 7F are enlarged views corresponding to the region A illustrated in FIG. 3A.

FIG. 7B illustrates an example where the insulating layer 250 has a stacked-layer structure of the insulating layer 250a over the oxide semiconductor layer 230, the insulating layer 250d over the insulating layer 250a, the insulating layer 250b over the insulating layer 250d, and the insulating layer 250c over the insulating layer 250b. That is, the insulating layer 250 illustrated in FIG. 7B has a structure where the positions of the insulating layer 250b and the insulating layer 250d in the insulating layer 250 illustrated in FIG. 7A are interchanged with each other. For example, aluminum oxide with a thickness of 1 nm can be used as the insulating layer 250a, hafnium zirconium oxide or hafnium zirconium oxide containing yttrium with a thickness of 2 nm can be used as the insulating layer 250d, silicon oxide with a thickness of 2 nm can be used as the insulating layer 250b, and silicon nitride with a thickness of 1 nm can be used as the insulating layer 250c. The insulating layer 250d may have a structure where a layer of hafnium zirconium oxide is stacked over a layer of hafnium zirconium oxide containing yttrium. Without limitation to the above, any of the above insulating materials and thicknesses can be selected as appropriate for the insulating layer 250a to the insulating layer 250d. When the insulating layer 250a to the insulating layer 250d are stacked as illustrated in FIG. 7B, the insulating layer 250a and the insulating layer 250d each having a function of capturing or fixing hydrogen are provided adjacent to each other, whereby hydrogen can be captured or fixed more effectively.

As illustrated in FIG. 7C, the positions of the insulating layer 250c and the insulating layer 250b can be interchanged with each other. In this case, the insulating layer 250 has a stacked-layer structure of the insulating layer 250a over the oxide semiconductor layer 230, the insulating layer 250d over the insulating layer 250a, the insulating layer 250c over the insulating layer 250d, and the insulating layer 250b over the insulating layer 250c.

In FIG. 7B, the insulating layer 250c can be provided in contact with the top and bottom surfaces of the insulating layer 250b. In this case, as illustrated in FIG. 7D, the insulating layer 250 has a stacked-layer structure of the insulating layer 250a over the oxide semiconductor layer 230, the insulating layer 250d over the insulating layer 250a, an insulating layer 250cl over the insulating layer 250d, the insulating layer 250b over the insulating layer 250cl, and an insulating layer 250c2 over the insulating layer 250b. Here, as each of the insulating layer 250cl and the insulating layer 250c2, an insulator that can be used as the insulating layer 250c is used. For example, silicon nitride with a thickness of 1 nm can be used as each of the insulating layer 250cl and the insulating layer 250c2.

FIG. 7E illustrates an example where the insulating layer 250 has a stacked-layer structure of the insulating layer 250a over the oxide semiconductor layer 230, the insulating layer 250b over the insulating layer 250a, an insulating layer 250d1 over the insulating layer 250b, the insulating layer 250c over the insulating layer 250d1, and an insulating layer 250d2 over the insulating layer 250c. That is, the insulating layer 250 illustrated in FIG. 7E has a structure where an insulator that can be used as the insulating layer 250d is provided in contact with the top and bottom surfaces of the insulating layer 250c in the insulating layer 250 illustrated in FIG. 7A. Here, an insulator having a function of capturing or fixing hydrogen (e.g., hafnium oxide) can be used as the insulating layer 250d1, and an insulator having ferroelectricity (e.g., hafnium zirconium oxide or hafnium zirconium oxide containing yttrium) can be used as the insulating layer 250d2. The insulating layer 250d2 may have a structure where a layer of hafnium zirconium oxide is stacked over a layer of hafnium zirconium oxide containing yttrium. The use of a ferroelectric for the insulating layer 250d2 in such a structure enables the transistor 200 to function as an FeFET. Furthermore, hydrogen can be captured or fixed by the insulating layer 250d1, so that the electrical characteristics and reliability of the transistor 200 can be improved.

In the case where the insulating layer 250d2 is formed using a ferroelectric material such as hafnium zirconium oxide, a conductive layer 252 can be provided in contact with the bottom surface of the insulating layer 250d2 as illustrated in FIG. 7F. For the conductive layer 252, a material that easily causes polarization in the insulating layer 250d2 is preferably used, and for example, titanium nitride is preferably used. In this case, titanium nitride is preferably used also for the lower portion of the conductive layer 260 that is in contact with the insulating layer 250d2. With such a structure, the insulating layer 250d2 can serve as a ferroelectric and the transistor 200 can function as an FeFET.

### [Conductive Layer]

For each of the conductive layers (the conductive layer 220, the conductive layer 240, the conductive layer 260, the conductive layer 265, and the like) included in the semiconductor device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as In—Sn oxide or ITO), indium tin oxide containing titanium oxide, indium tin oxide containing silicon (also referred to as ITSO), indium zinc oxide (also referred to as In—Zn oxide or IZO (a registered trademark)), and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

Each of the conductive layers 220 and 240 is in contact with the oxide semiconductor layer 230, and is thus preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of the conductive layers 220 and 240 can be inhibited.

When a conductive material containing oxygen is used for the conductive layer 220, the conductive layer 220 can maintain its conductivity even when after absorbing oxygen. Similarly, when a conductive material containing oxygen is used for the conductive layer 240, the conductive layer 240 can maintain its conductivity even after absorbing oxygen. It is also preferable that an insulating layer containing oxygen, such as hafnium oxide, be used as the insulating layer 210 in order that the conductive layer 220 can maintain its conductivity. For each of the conductive layers 220 and 240, ITO, ITSO, In—Zn oxide, or the like is preferably used, for example.

In the case where the conductive layer 220 and the conductive layer 240 each have a stacked-layer structure, a conductive material containing oxygen is preferably used for a layer having the largest contact area with the oxide semiconductor layer 230 in the stacked-layer structure, in which case the contact resistance between the conductive layer 220 and the oxide semiconductor layer 230 and the contact resistance between the conductive layer 240 and the oxide semiconductor layer 230 can be reduced.

The conductive layer 220 illustrated in FIG. 3A has the two-layer structure of the conductive layer 220_1 and the conductive layer 220_2 over the conductive layer 220_1. In this case, for example, a conductive material containing oxygen is preferably used for the conductive layer 220_2, and a material having higher conductivity than the material for the conductive layer 220_2 is preferably used for the conductive layer 220_1. Specifically, for example, an oxide conductor (e.g., ITO, ITSO, or In—Zn oxide) is preferably used for the conductive layer 220_2, and tungsten is preferably used for the conductive layer 220_1. For the conductive layer 220_1, ruthenium, titanium nitride, tantalum nitride, or the like may be used. When an oxide conductor is used for the conductive layer 220_2 mainly in contact with the oxide semiconductor layer 230, the contact resistance with the oxide semiconductor layer 230 can be reduced. A material having higher conductivity than an oxide conductor is preferably used for a layer included in the conductive layer 220, in which case the conductivity of the conductive layer 220 can be increased.

Note that a conductive material containing oxygen can be used for the conductive layer 220_1, and a material having higher conductivity than the material for the conductive layer 220_1 can be used for the conductive layer 220_2. In this case, a material having high conductivity is used for the layer of the conductive layer 220 which is closest to the channel formation region of the oxide semiconductor layer 230. Thus, the current path between the source and the drain can be shortened, so that the on-state current of the transistor 200 can be increased.

FIG. 3A illustrates an example where the conductive layer 220_1 and the conductive layer 220_2 each have a single-layer structure. Note that one or both of the conductive layer 220_1 and the conductive layer 220_2 may have a stacked-layer structure of two or more layers. For example, as illustrated in FIG. 4A, the conductive layer 220_1 may have a two-layer structure of a conductive layer 220_11 and a conductive layer 220_12 over the conductive layer 220_11. In this case, the conductive layer 220 has a three-layer structure of the conductive layer 220_11, the conductive layer 220_12 over the conductive layer 220_11, and the conductive layer 220_2 over the conductive layer 220_12. For example, a conductive material that is not easily oxidized or a conductive material that has a function of inhibiting diffusion of oxygen is preferably used for the conductive layer 220_11, a material that has high conductivity is preferably used for the conductive layer 220_12, and a conductive material that contains oxygen (preferably an oxide conductor) is preferably used for the conductive layer 220_2. Specifically, titanium nitride is preferably used for the conductive layer 220_11, tungsten is preferably used for the conductive layer 220_12, and an oxide conductor (e.g., ITO, ITSO, or In—Zn oxide) is preferably used for the conductive layer 220_2. In this case, a titanium nitride film is in contact with the insulating layer 210, and an oxide conductor film is in contact with the oxide semiconductor layer 230. In addition, the oxide conductor is used for the layer closest to the channel formation region of the oxide semiconductor layer 230. Since the oxide conductor has a lower contact resistance with the oxide semiconductor layer 230 than tungsten, the current path between the source and the drain can be shortened and the on-state current of the transistor 200 can be increased. Such a structure enables the conductive layer 220 to maintain its conductivity even when being in contact with the oxide semiconductor layer 230. In the case of using an oxide insulating layer as the insulating layer 210, the conductive layer 220 can be inhibited from being excessively oxidized by the insulating layer 210. When a metal material (here, tungsten) having higher conductivity than an oxide conductor and titanium nitride is used for the conductive layer 220_12, the conductivity of the conductive layer 220 can be increased.

The conductive layer 240a illustrated in FIG. 3A has the two-layer structure of the conductive layer 240al and the conductive layer 240a2 over the conductive layer 240al. In this case, for example, a conductive material containing oxygen is preferably used for the conductive layer 240a2, and a material having higher conductivity than the material for the conductive layer 240a2 is preferably used for the conductive layer 240al Specifically, for example, an oxide conductor (e.g., ITO, ITSO, or In—Zn oxide) is preferably used for the conductive layer 240a2, and tungsten is preferably used for the conductive layer 240al. For the conductive layer 240al, ruthenium, titanium nitride, tantalum nitride, or the like may be used. When an oxide conductor is used for the conductive layer 240a2 mainly in contact with the oxide semiconductor layer 230, the contact resistance with oxide semiconductor layer 230 can be reduced. A material having higher conductivity than an oxide conductor is preferably used for a layer included in the conductive layer 240a, in which case the conductivity of the conductive layer 240a can be increased.

Note that a conductive material containing oxygen can be used for the conductive layer 240a1, and a material having higher conductivity than the material for the conductive layer 240al can be used for the conductive layer 240a2. In this case, the oxide conductor is used for the layer of the conductive layer 240a which is closest to the channel formation region of the oxide semiconductor layer 230. Thus, the current path between the source and the drain can be shortened, so that the on-state current of the transistor 200 can be increased.

The conductive layer 260 includes a region functioning as a gate electrode. The conductive layer 260 is preferably formed using a material having high conductivity such as tungsten. For the conductive layer 260, a conductive material that is not easily oxidized, a conductive material having a function of inhibiting diffusion of oxygen, or the like is preferably used. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layer 260 can be inhibited.

It is particularly preferable to use, for the conductive layer 260, a conductive material containing oxygen and a metal element contained in the metal oxide where a channel is formed. Alternatively, a conductive material containing the above metal element and nitrogen (e.g., titanium nitride or tantalum nitride) may be used. One or more of ITO, indium oxide containing tungsten oxide, indium zinc oxide containing tungsten oxide, indium oxide containing titanium oxide, indium tin oxide containing titanium oxide, In—Zn oxide, and ITSO may be used. Indium gallium zinc oxide containing nitrogen may also be used. With the use of such a material, hydrogen contained in the metal oxide where a channel is formed can be captured in some cases. Hydrogen entering from a surrounding insulating layer or the like can also be captured in some cases.

FIG. 3A illustrates an example where the conductive layer 260 has a single-layer structure. Note that the conductive layer 260 can have a stacked-layer structure of two or more layers. For example, as illustrated in FIG. 4A, the conductive layer 260 has a two-layer structure of a conductive layer 260_1 and a conductive layer 260_2 over the conductive layer 260_1. In this case, for example, a titanium nitride film is preferably used as the conductive layer 260_1, and a tungsten film is preferably used as the conductive layer 260_2. Alternatively, a tantalum nitride film is preferably used as the conductive layer 260_1, and a copper film is preferably used as the conductive layer 260_2. Such a structure can increase the conductivity of the conductive layer 260.

Alternatively, the conductive layer 260 may have a stacked-layer structure of three or more layers. The conductive layer 260 may have a three-layer structure of a tantalum nitride film, a titanium nitride film over the tantalum nitride film, and a tungsten film over the titanium nitride film, for example.

The conductive layer 265 functions as a gate wiring. For the conductive layer 265, a material that can be used for the conductive layer 260 can be used. For example, a high-melting-point material that has both heat resistance and conductivity, such as tungsten or molybdenum, can be used for the conductive layer 265. Alternatively, a low-resistance conductive material such as aluminum or copper can be used. The use of a low-resistance conductive material can reduce wiring resistance.

FIG. 3A illustrates an example where the conductive layer 265 has a single-layer structure. Note that the conductive layer 265 can have a stacked-layer structure of two or more layers.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. A substrate which is an insulator substrate provided with a conductor or a semiconductor, a substrate which is a semiconductor substrate provided with a conductor or an insulator, a substrate which is a conductor substrate provided with a semiconductor or an insulator, or the like is also given. Alternatively, these substrates provided with elements may be used. Examples of the element provided over the substrate include a capacitor, a resistor, a switching element, a light-emitting element, and a memory element.

The above is the description of materials that can be used for the semiconductor device of this embodiment.

The semiconductor device of one embodiment of the present invention may include an insulating layer over the transistor 200. Specifically, an insulating layer may be provided over the conductive layer 265 and the insulating layer 285.

As the insulating layer, a barrier insulating layer against hydrogen is preferably used. Such a structure can inhibit diffusion of hydrogen from above the transistor 200 into the oxide semiconductor layer 230.

Although FIG. 3A illustrates a structure where the side surface of the conductive layer 240 in the groove portion 290 and the side surface of the insulating layer 280 in the groove portion 290 are on the same plane (also referred to as matching, substantially matching, being aligned with each other, or being substantially aligned with other), the present invention is not limited thereto. For example, the side surface of the conductive layer 240a in the groove portion 290 and the side surface of the insulating layer 280 in the groove portion 290 may be discontinuous. The inclination of the side surface of the conductive layer 240a in the groove portion 290 and the inclination of the side surface of the insulating layer 280 in the groove portion 290 may be different from each other. At this time, part of the side surface of the groove portion 290 has a tapered shape.

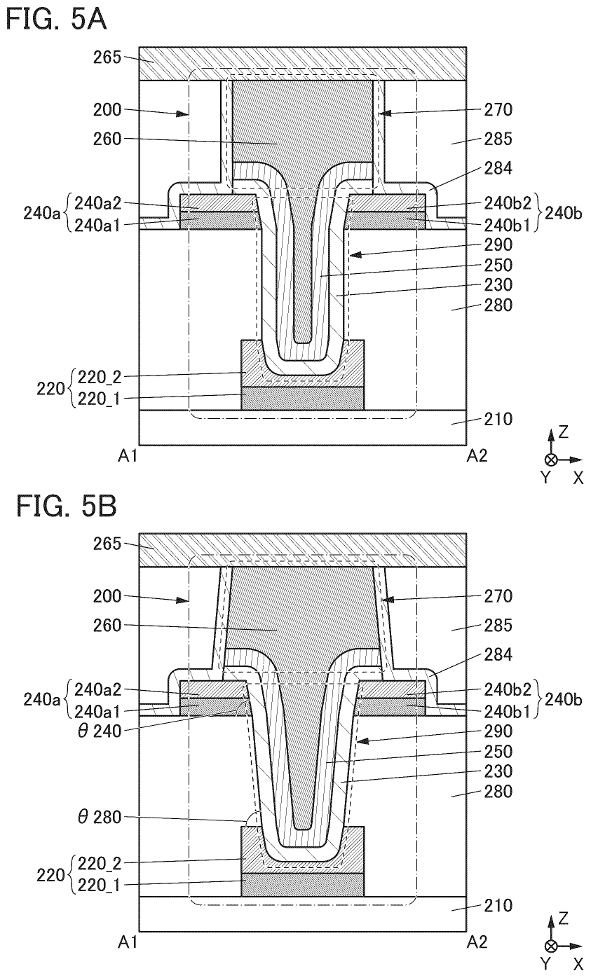

FIGS. 5A and 5B each illustrate an example where at least part of the side surface of the groove portion 290 has a tapered shape. FIG. 5A illustrates an example where the side surface of the conductive layer 240a in the groove portion 290 has a tapered shape, and FIG. 5B illustrates an example where the side surfaces of the conductive layer 240a and the insulating layer 280 in the groove portion 290 each have a tapered shape.

When the side surface of the groove portion 290 has a tapered shape, the coverage with the oxide semiconductor layer 230, the insulating layer 250, and the like can be improved, so that defects such as voids can be reduced. In the case where the side surface of the groove portion 290 has a tapered shape, for example, a taper angle (an angle θ240) of the side surface of the conductive layer 240a on the groove portion 290 side and a taper angle (an angle θ280) of the side surface of the insulating layer 280 in the groove portion 290 are each preferably greater than or equal to 45° and less than 90°. Specifically, the taper angle θ280 is preferably greater than or equal to 80° and less than 90°, in which case the semiconductor device can be miniaturized or highly integrated as described above. Alternatively, the taper angle θ280 is preferably greater than or equal to 45° or greater than or equal to 50° and less than 80°, less than or equal to 75°, less than or equal to 70°, less than or equal to 65°, or less than or equal to 60°, in which case the coverage with a film to be formed in the groove portion 290 is improved.

For example, the angle θ240 is preferably less than the angle θ280. With such a structure, the coverage of the side surface of the conductive layer 240a on the groove portion 290 side with the oxide semiconductor layer 230 or the like is improved, so that defects such as voids can be reduced. In the case where the insulating layer 280 has a stacked-layer structure, the inclinations of the side surfaces of the layers in the groove portion 290 may be different from each other. Similarly, in the case where the conductive layer 240a has a stacked-layer structure, the inclinations of the side surfaces of the layers on the groove portion 290 side may be different from each other.

As described above, the oxide semiconductor layer 230 can have a stacked-layer structure of two or more layers.

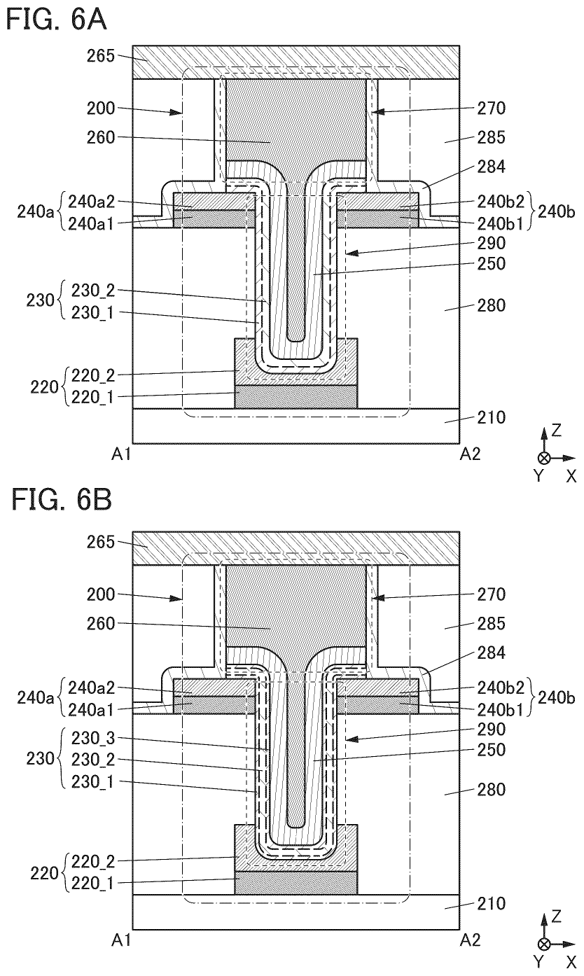

FIG. 6A illustrates an example where the oxide semiconductor layer 230 included in the semiconductor device illustrated in FIG. 3A has a two-layer structure. The oxide semiconductor layer 230 illustrated in FIG. 6A can have a two-layer structure of an oxide semiconductor layer 230_1 and an oxide semiconductor layer 230_2 over the oxide semiconductor layer 230_1.

FIG. 6B illustrates an example where the oxide semiconductor layer 230 included in the semiconductor device illustrated in FIG. 3A has a three-layer structure. The oxide semiconductor layer 230 illustrated in FIG. 6B can have a three-layer structure of the oxide semiconductor layer 230_1, the oxide semiconductor layer 230_2 over the oxide semiconductor layer 230_1, and an oxide semiconductor layer 230_3 over the oxide semiconductor layer 230_2.

For the oxide semiconductor layers that can be used as the oxide semiconductor layer 230_1 to the oxide semiconductor layer 230_3, description in Embodiment 2 can be referred to.

### <Example of Method for Manufacturing Semiconductor Device>

Next, a method for manufacturing the semiconductor device of one embodiment of the present invention is described. Note that as for a material and a formation method of each component, portions similar to those described in the above embodiment are not described in some cases.

Thin films included in the semiconductor device (e.g., insulating films, semiconductor films, and conductive films) can be formed by a sputtering method, a chemical vapor deposition (CVD) method, a vacuum evaporation method, a molecular beam epitaxy (MBE) method, a pulsed laser deposition (PLD) method, an ALD method, or the like.

Examples of the sputtering method include an RF sputtering method in which a high-frequency power source is used for a sputtering power source, a DC sputtering method in which a DC power source is used, and a pulsed DC sputtering method in which voltage applied to an electrode is changed in a pulsed manner. The RF sputtering method is mainly used for forming an insulating film, and the DC sputtering method is mainly used for forming a metal conductive film. A pulsed DC sputtering method is mainly employed in the case where a compound such as an oxide, a nitride, or a carbide is deposited by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a plasma CVD method. A thermal CVD method does not use plasma and thus causes less plasma damage to an object to be processed. A wiring, an electrode, an element (e.g., a transistor or a capacitor), or the like included in a semiconductor device might be charged up by receiving charge from plasma, for example. In that case, the accumulated charge might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during film formation.

As the ALD method, a thermal ALD method, in which a precursor and a reactant react with each other only by a thermal energy, a PEALD method, in which a reactant excited by plasma is used, or the like can be used.

Note that some precursors used in the ALD method contain an element such as carbon or chlorine. Thus, a film formed by the ALD method sometimes contains an element such as carbon or chlorine in a larger quantity than a film formed by another film formation method. Note that these elements can be quantified by XPS or SIMS. The formation method of a metal oxide of one embodiment of the present invention, which employs an ALD method and one or both of a deposition condition with a high substrate temperature and impurity removal treatment, can sometimes form a film with smaller amounts of carbon and chlorine than a method employing an ALD method without the deposition condition with a high substrate temperature or the impurity removal treatment.

Unlike in a film formation method in which particles ejected from a target or the like are deposited, a film is formed by reaction at a surface of an object to be processed in an ALD method. Thus, the ALD method can give good step coverage, almost regardless of the shape of an object to be processed. In particular, the ALD method allows excellent step coverage and excellent thickness uniformity and thus can be suitably used to cover a surface of an opening portion or a groove portion with a high aspect ratio, for example.

A CVD method and an ALD method differ from a sputtering method in which particles ejected from a target or the like are deposited. Thus, the ALD method can give good step coverage, almost regardless of the shape of an object to be processed. In particular, an ALD method allows excellent step coverage and excellent thickness uniformity and thus can be suitably used to cover a surface of an opening portion or a groove portion with a high aspect ratio, for example. Note that an ALD method has a relatively low film formation rate; hence, in some cases, an ALD method is preferably combined with another film formation method with a high film formation rate, such as a CVD method.

By a CVD method, a film with a desired composition can be formed by adjusting the flow rate ratio of the source gases. For example, a CVD method enables formation of a film whose composition is gradually changed by changing the flow rate ratio of the source gases during film formation. In the case where a film is formed while the flow rate ratio of the source gases is changed, as compared with the case where a film is formed using a plurality of film formation chambers, the time taken for the film formation can be shortened because the time taken for transfer or pressure adjustment is not required. Hence, the productivity of the semiconductor device can be improved in some cases.

An ALD method in which a plurality of kinds of precursors are introduced at a time enables formation of a film with a desired composition. In the case where a plurality of kinds of precursors are introduced, the number of cycles for each precursor is controlled, whereby a film with a desired composition can be formed.

Alternatively, thin films included in the semiconductor device (e.g., insulating films, semiconductor films, and conductive films) can be formed by a wet process such as a spin coating method, a dip coating method, a spray coating method, an inkjet method, dispensing, screen printing, offset printing, doctor blade coating, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light used for exposure, an electron beam can be used. EUV, X-rays, or an electron beam is preferably used to enable extremely minute processing. Note that when exposure is performed by scanning of a beam such as an electron beam, a photomask is not needed.

For etching of thin films, a dry etching method, a wet etching method, a sandblast method, or the like can be used.

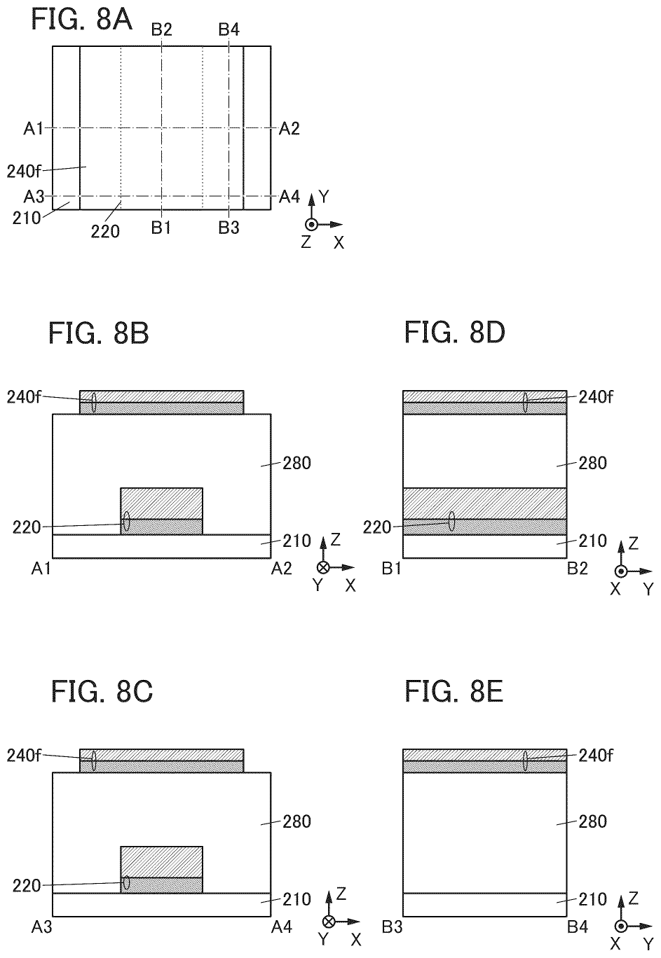

An example of a method for manufacturing the semiconductor device illustrated in FIGS. 1A1 to 1E is described with reference to FIGS. 8A to 8E, FIGS. 9A to 9E, FIGS. 10A to 10E, FIGS. 11A to 11E, FIGS. 12A to 12E, FIGS. 13A to 13E, FIGS. 14A to 14E, and FIGS. 15A to 15E.

First, as illustrated in FIGS. 8A to 8E, the insulating layer 210 is formed over a substrate (not illustrated), and the conductive layer 220 is formed over the insulating layer 210. For example, a first conductive film to be the conductive layer 220_1 is formed, a second conductive film to be the conductive layer 220_2 is formed over the first conductive film, and the first conductive film and the second conductive film are processed, so that the conductive layer 220 including the conductive layer 220_1 and the conductive layer 220_2 can be formed.

Next, as illustrated in FIGS. 8A to 8E, the insulating layer 280 is formed over the conductive layer 220 and the insulating layer 210. Note that planarization treatment is preferably performed after formation of the insulating layer 280 to planarize the top surface of the insulating layer 280. As the planarization treatment, planarization treatment using a chemical mechanical polishing (CMP) method (also referred to as CMP treatment) is suitable. By the planarization treatment of the insulating layer 280, the formation surface of the conductive layer 240a and the conductive layer 240b each including a region functioning as a wiring can be made flat, whereby disconnection of each of the conductive layer 240a and the conductive layer 240b can be inhibited. Note that the planarization treatment is not necessarily performed, in which case the manufacturing cost can be reduced.

After the formation of the insulating layer 280, treatment for supplying oxygen is preferably performed. Accordingly, oxygen can be supplied to the insulating layer 280, and the oxygen can be supplied from the insulating layer 280 to the oxide semiconductor layer 230 by heat applied after formation of the oxide semiconductor layer 230, for example.

Examples of the treatment for supplying oxygen include heat treatment in an oxygen-containing atmosphere and plasma treatment in an oxygen-containing atmosphere (including microwave plasma treatment). Alternatively, an oxide film (preferably a metal oxide film) may be formed by a sputtering method in an oxygen-containing atmosphere to supply oxygen to the insulating layer 280. The formed oxide film may be removed immediately or left as it is. In the case where the formed oxide film is left as it is, the oxide film can be used as part of the insulating layer 280. Note that the oxygen-containing atmosphere includes an atmosphere containing not only an oxygen gas (O₂) but also a gas of a compound containing oxygen, such as ozone (O₃) or dinitrogen monoxide (N₂O). The substrate temperature in the plasma treatment is higher than or equal to room temperature (25° C.) and lower than or equal to 450° C.

Next, as illustrated in FIGS. 8A to 8E, a conductive layer 240f is formed over the insulating layer 280. For example, a first conductive film to be the conductive layer 240al and the conductive layer 240b1 is formed, a second conductive film to be the conductive layer 240a2 and the conductive layer 240b2 is formed over the first conductive film, and the first conductive film and the second conductive film are processed, so that the conductive layer 240f including a first conductive layer and a second conductive layer can be formed.

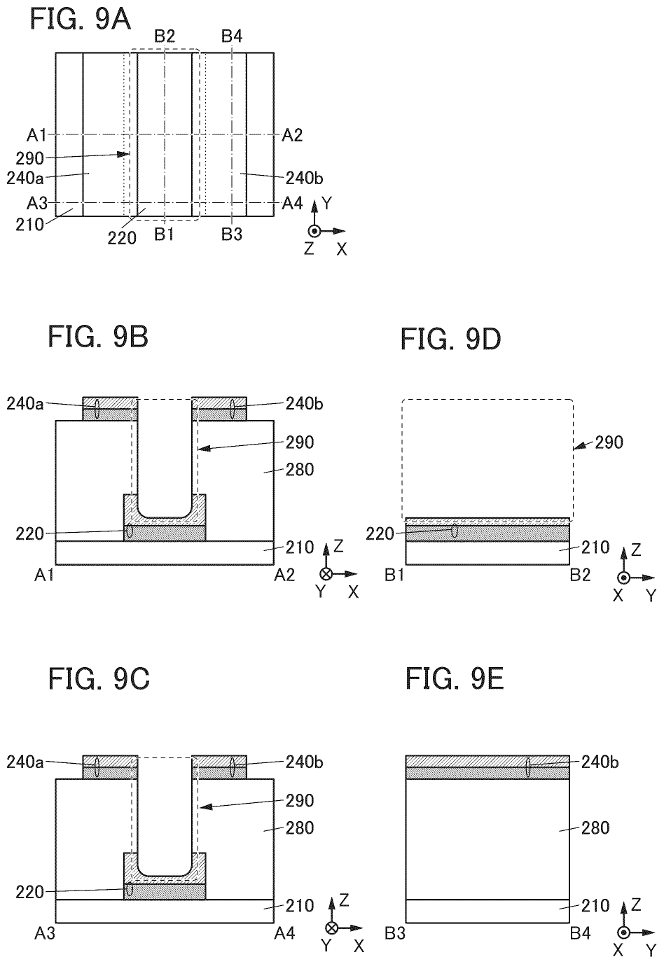

Next, as illustrated in FIGS. 9A to 9E, the groove portion 290 is formed in the conductive layer 240f and the insulating layer 280. The groove portion 290 is formed to expose at least part of the top surface of the conductive layer 220. By formation of the groove portion 290, the conductive layer 240f can be formed into the conductive layer 240a and the conductive layer 240b that are separated from each other. At this time, a depressed portion is preferably provided in the conductive layer 220 in a position overlapping with the groove portion 290. By formation of the groove portion 290, the bottom and side surfaces of the depressed portion of the conductive layer 220 are preferably exposed.

For microfabrication and a small transistor size, in forming the groove portion 290, part of the conductive layer 220, part of the insulating layer 280, and part of the conductive layer 240f are preferably processed using anisotropic etching. It is particularly preferable to use a dry etching method because it is suitable for microfabrication. The groove portion 290 may be formed under processing conditions different between layers. Note that the inclinations of the side surfaces of the conductive layer 220, the insulating layer 280, and the conductive layer 240f in the groove portion 290 may differ depending on the materials, the processing conditions, and the like of the conductive layer 220, the insulating layer 280, and the conductive layer 240f.

In the formation step of the groove portion 290 or the like, a region containing a halogen element is sometimes provided in at least one of the bottom and side surfaces of the depressed portion of the conductive layer 220, the side surface of the insulating layer 280, and the top and side surfaces of the conductive layer 240f. Examples of the region include a region containing fluorine, a region containing chlorine, and a region containing fluorine and chlorine. In some cases, a halogen element derived from an etching gas used in dry etching remains in the region, for example.

Next, heat treatment is preferably performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as hydrogen and water contained in the insulating layer 280 or the like can be reduced before the oxide semiconductor layer 230 is formed.

The gas used in the above heat treatment is preferably highly purified. For example, the amount of moisture contained in the gas used in the above heat treatment is preferably 1 ppb or less, further preferably 0.1 ppb or less, still further preferably 0.05 ppb or less. The heat treatment using a highly purified gas can prevent the entry of moisture or the like into the insulating layer 280 or the like as much as possible.

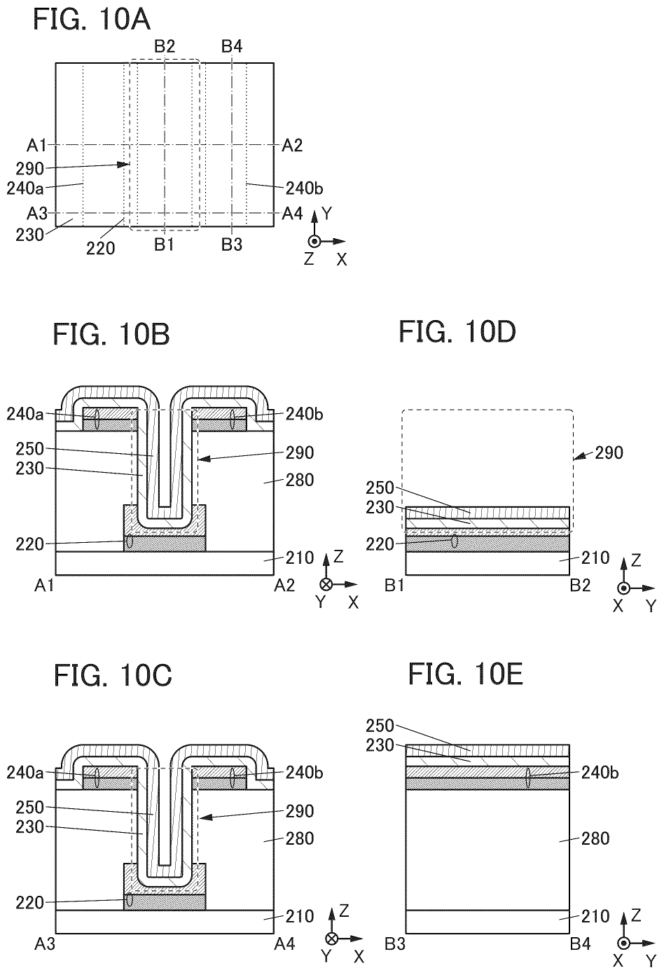

Next, as illustrated in FIGS. 10A to 10E, the oxide semiconductor layer 230 is formed to cover the groove portion 290, the conductive layer 240a, the conductive layer 240b, and the insulating layer 280. The oxide semiconductor layer 230 is provided in contact with the bottom and side surfaces of the depressed portion of the conductive layer 220, the side surface of the insulating layer 280, and the top and side surfaces of each of the conductive layers 240a and 240b. For a manufacturing method of the oxide semiconductor layer 230, description in Embodiment 2 can also be referred to.

In this embodiment, as the oxide semiconductor layer 230, a first oxide semiconductor film, a second oxide semiconductor film, and a third oxide semiconductor film are formed in this order. The first oxide semiconductor film is to be the oxide semiconductor layer 230_1 illustrated in FIG. 6B, the second oxide semiconductor film is to be the oxide semiconductor layer 230_2 illustrated in FIG. 6B, and the third oxide semiconductor film is to be the oxide semiconductor layer 230_3 illustrated in FIG. 6B.

For example, an In—Ga—Zn oxide film is formed by a thermal ALD method as the first oxide semiconductor film, an indium oxide film is formed by a thermal ALD method as the second oxide semiconductor film, and an In—Ga—Zn oxide film is formed by a sputtering method as the third oxide semiconductor film.

Note that the first oxide semiconductor film and the second oxide semiconductor film are preferably successively formed without exposure to the air. When the first oxide semiconductor film and the second oxide semiconductor film are successively formed without exposure to the air, the productivity can be increased. Furthermore, impurities (typically, moisture or the like) taken into the interface between the first oxide semiconductor film and the second oxide semiconductor film and the vicinity of the interface can be reduced.

After formation of the second oxide semiconductor film, treatment for supplying oxygen to the second oxide semiconductor film may be performed. Accordingly, oxygen can be supplied to the oxide semiconductor layer 230 by heat applied after the treatment, for example. Note that the above description can be referred to for the details of the treatment for supplying oxygen.

Next, heat treatment is preferably performed. The heat treatment temperature is, for example, preferably higher than or equal to 100° C. and lower than or equal to 650° C., further preferably higher than or equal to 250° C. and lower than or equal to 600° C., still further preferably higher than or equal to 350° C. and lower than or equal to 550° C. For the details of the heat treatment, the above description can be referred to.

The gas used in the above heat treatment is preferably highly purified. The heat treatment using a highly purified gas can, for example, prevent entry of moisture or the like into the oxide semiconductor layer 230 as much as possible.

By the heat treatment, impurities such as carbon, hydrogen, and water in the oxide semiconductor layer 230 can be reduced. Impurities in the film are reduced in the above manner, whereby the crystallinity of the oxide semiconductor layer 230 can be improved and a dense structure can be obtained. Accordingly, the crystal region in the oxide semiconductor layer 230 can be increased, and an in-plane variation in the crystal region in the oxide semiconductor layer 230 can be reduced. Thus, in-plane variation in the electrical characteristics of the transistors can be reduced.

In the case where the insulating layer 280 contains oxygen, oxygen is preferably supplied from an insulating layer containing the oxygen to the channel formation region of the oxide semiconductor layer 230 by the heat treatment. Accordingly, oxygen vacancies and V_{O}H can be reduced.

As described above, excess oxygen is sometimes supplied from the insulating layer 280 in contact with the oxide semiconductor layer 230 to the oxide semiconductor layer 230. Since excess oxygen has a function of trapping electrons, a negative charge is likely to be formed. Accordingly, the threshold voltage of the transistor can be shifted positively to enable the transistor to have normally-off characteristics.

Note that microwave plasma treatment may be performed after formation of the second oxide semiconductor film or the third oxide semiconductor film. The microwave plasma treatment can reduce the concentration of impurities such as hydrogen and water contained in the oxide semiconductor layer 230. In addition, the crystal region of the oxide semiconductor layer 230 grows in some cases. Note that the details of the microwave plasma treatment will be described in Embodiment 2.

Next, as illustrated in FIGS. 10A to 10E, the insulating layer 250 is formed over the oxide semiconductor layer 230. The insulating layer 250 is provided in contact with the oxide semiconductor layer 230. The insulating layer 250 is formed in the groove portion 290 having a high aspect ratio. Thus, the insulating layer 250 is preferably formed by a film formation method that provides favorable coverage, further preferably formed by a CVD method, an ALD method, or the like.

After formation of the insulating layer 250, microwave plasma treatment is preferably performed. The microwave plasma treatment can reduce the concentration of impurities such as hydrogen and water contained in the oxide semiconductor layer 230. In addition, the crystal region of the oxide semiconductor layer 230 grows in some cases.

Note that in the case where the insulating layer 250 has the four-layer structure of the fourth insulating layer, the third insulating layer over the fourth insulating layer, the first insulating layer over the third insulating layer, and the second insulating layer over the first insulating layer, microwave plasma treatment may be performed after formation of the third insulating layer. Furthermore, microwave plasma treatment may be performed again after formation of the first insulating layer. As described above, the microwave plasma treatment in an oxygen-containing atmosphere may be performed multiple times (at least twice).

After formation of the third insulating layer, treatment for supplying oxygen to the third insulating layer may be performed. Accordingly, oxygen can be supplied to the oxide semiconductor layer 230. Note that the above description can be referred to for the details of the treatment for supplying oxygen.

In this embodiment, as the insulating layer 250, an aluminum oxide film, a silicon oxide film, a hafnium oxide film, and a silicon nitride film are formed in this order by an ALD method. Instead of the hafnium oxide film, a hafnium zirconium oxide film or the like can be formed.

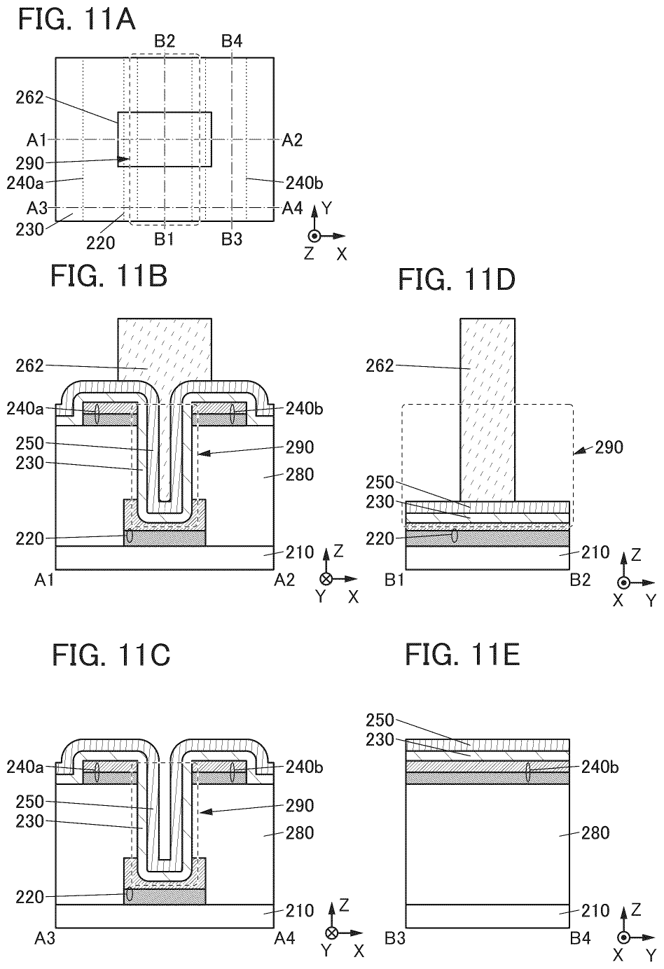

Next, as illustrated in FIGS. 11A to 11E, a sacrificial layer 262 is formed over the insulating layer 250. The sacrificial layer 262 is provided to overlap with at least part of the groove portion 290. As the sacrificial layer 262, a spin on carbon (SOC) film and a spin on glass (SOG) film are suitable. The sacrificial layer 262 preferably has a two-layer structure of an SOC film and an SOG film over the SOC film, for example.

The sacrificial layer 262 is preferably provided over and in contact with the insulating layer 250, in which case damage to the oxide semiconductor layer 230 can be reduced in the manufacturing process of the semiconductor device as compared with the case where the sacrificial layer 262 is provided over and in contact with the oxide semiconductor layer 230. Note that in the case where the insulating layer 250 has a stacked-layer structure, some of the layers constituting the insulating layer 250 may be formed before formation of the sacrificial layer 262, and the other layer(s) may be formed after removal of the sacrificial layer 262.

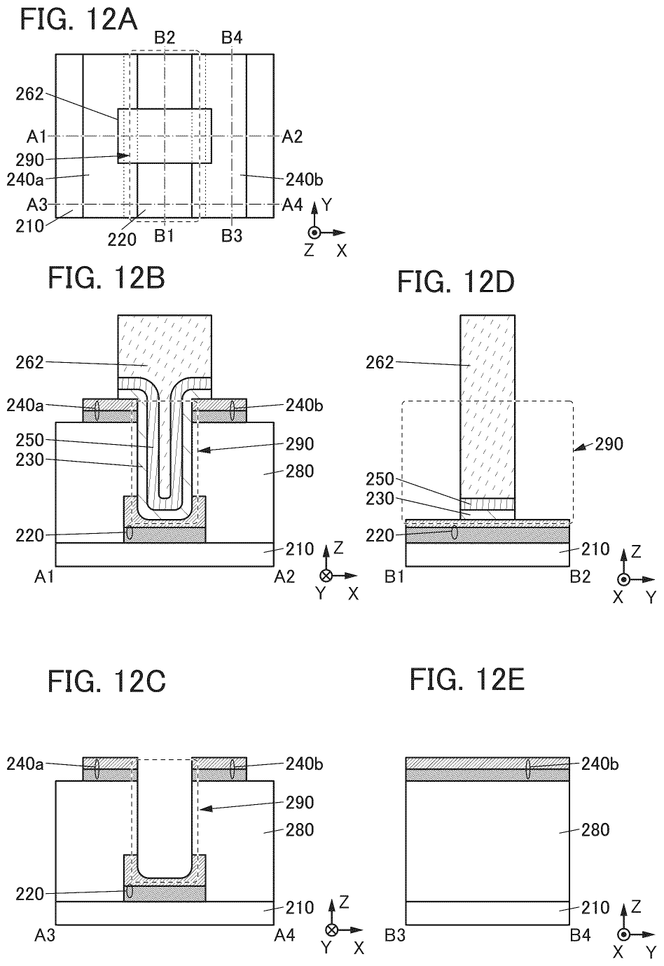

Next, as illustrated in FIGS. 12A to 12E, etching treatment is performed using the sacrificial layer 262 as a mask to remove part of the insulating layer 250 and part of the oxide semiconductor layer 230. Thus, the insulating layer 250 having an island shape and the oxide semiconductor layer 230 having an island shape can be formed.

The sacrificial layer 262 preferably overlaps with the top surfaces of the conductive layer 240a and the conductive layer 240b in large areas. The above etching treatment is performed to make the oxide semiconductor layer 230 in a region overlapping with the sacrificial layer 262 left. Thus, this structure can increase the contact area between the oxide semiconductor layer 230 and the conductive layer 240a, thereby reducing the contact resistance therebetween. This can inhibit a decrease in on-state current of the transistor 200 due to the contact resistance between the conductive layer 240a and the oxide semiconductor layer 230. The same applies to the conductive layer 240b and the oxide semiconductor layer 230.

The sacrificial layer 262 can overlap with the top surfaces of the conductive layer 240a and the conductive layer 240b in small areas. Since the gate electrode (the conductive layer 260) is provided in a later step in a region where the sacrificial layer 262 is provided, such a structure can increase the distance between the conductive layer 240a and the conductive layer 260 provided in the later step, thereby reducing the parasitic capacitance generated between the conductive layer 240a and the gate electrode. The same applies to the conductive layer 240b and the oxide semiconductor layer 230.

Note that the etching treatment sometimes reduces the thickness of a portion of the conductive layer 240a not overlapping with the sacrificial layer 262. Alternatively, the portion of the conductive layer 240a not overlapping with the sacrificial layer 262 is removed in some cases. The same applies to the conductive layer 240b.

By the etching treatment, a portion of the insulating layer 280 not overlapping with the conductive layer 240a or the conductive layer 240b is sometimes reduced in thickness (thinned).

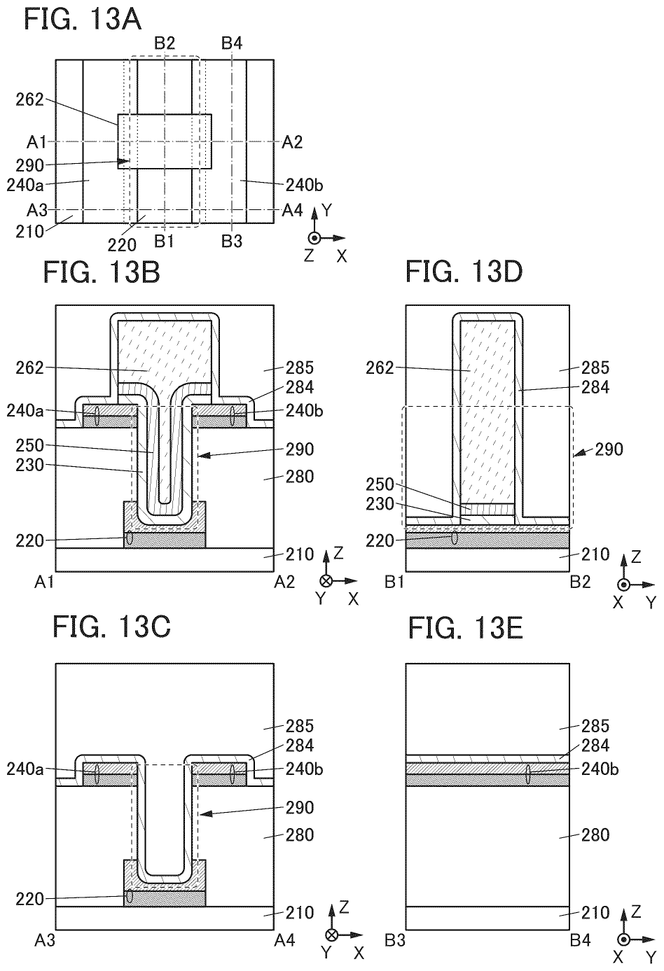

Next, as illustrated in FIGS. 13A to 13E, the insulating layer 284 is formed to cover the conductive layer 220, the conductive layer 240a, the conductive layer 240b, the insulating layer 280, and the sacrificial layer 262, and the insulating layer 285 is formed over the insulating layer 284.

When the insulating layer 285 is made thick, the distance between the conductive layer 240a or the conductive layer 240b and the conductive layer 265 to be formed in a later step can be increased, so that the parasitic capacitance generated between the conductive layer 240a or the conductive layer 240b and the gate wiring can be reduced.

A silicon oxide film is preferably formed by a sputtering method as the insulating layer 285, for example.

Here, in the case where the insulating layer 284 is not provided, the sacrificial layer 262 is exposed to plasma containing oxygen in forming a silicon oxide film by a sputtering method as the insulating layer 285, so that part or the whole of the sacrificial layer 262 is etched in some cases. As described above, depending on the formation method of the insulating layer 285, the sacrificial layer 262 might be shrunk or disappear. For this reason, the insulating layer formed over the sacrificial layer 262 preferably has not a single-layer structure of the insulating layer 285 but a stacked-layer structure of the insulating layer 284 and the insulating layer 285. This can produce effects of widening the range of choices of the materials for the sacrificial layer 262 and the insulating layer 285, lowering the difficulty of manufacturing the semiconductor device, and the like.

In the case where an oxide film is used as the insulating layer 284, the oxide film is preferably formed by a method other than a sputtering method, e.g., an ALD method. For example, an aluminum oxide film or a hafnium oxide film is preferably formed as the insulating layer 284 by an ALD method. Alternatively, a nitride film (e.g., a silicon nitride film) is preferably used as the insulating layer 284. Thus, the sacrificial layer 262 can be inhibited from being unintentionally processed in forming the insulating layer 284 and the insulating layer 285.

The insulating layer 284 is preferably formed by a CVD method or an ALD method, further preferably formed by an ALD method. In such a case, the insulating layer 284 can be provided on the side surface of the sacrificial layer 262, for example, with good coverage.

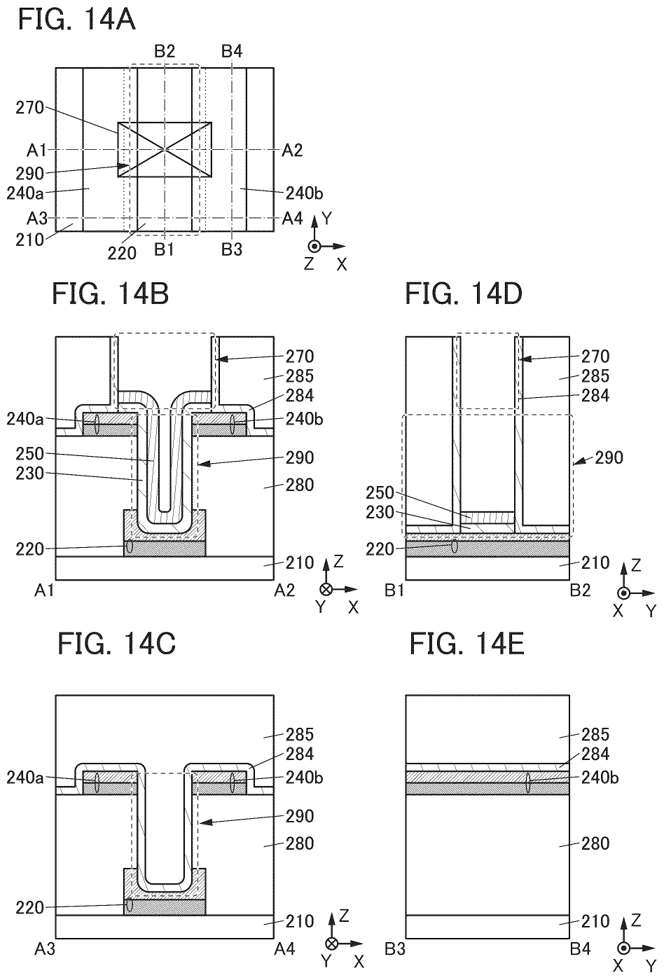

Subsequently, as illustrated in FIGS. 14A to 14E, planarization treatment is performed to expose the top surface of the sacrificial layer 262 and planarize the top surfaces of the sacrificial layer 262, the insulating layer 284, and the insulating layer 285. As the planarization treatment, CMP treatment is suitable. At least part of the insulating layer 284 and part of the insulating layer 285 are removed by the planarization treatment. Part of the sacrificial layer 262 may further be removed.

Then, as illustrated in FIGS. 14A to 14E, the sacrificial layer 262 is removed. There is no particular limitation on the method for removing the sacrificial layer 262. For example, the sacrificial layer 262 can be removed by dry etching. It can be said that the removal of the sacrificial layer 262 provides the opening portion 270 in the insulating layer 284 in a position overlapping with the groove portion 290 and the insulating layer 250.

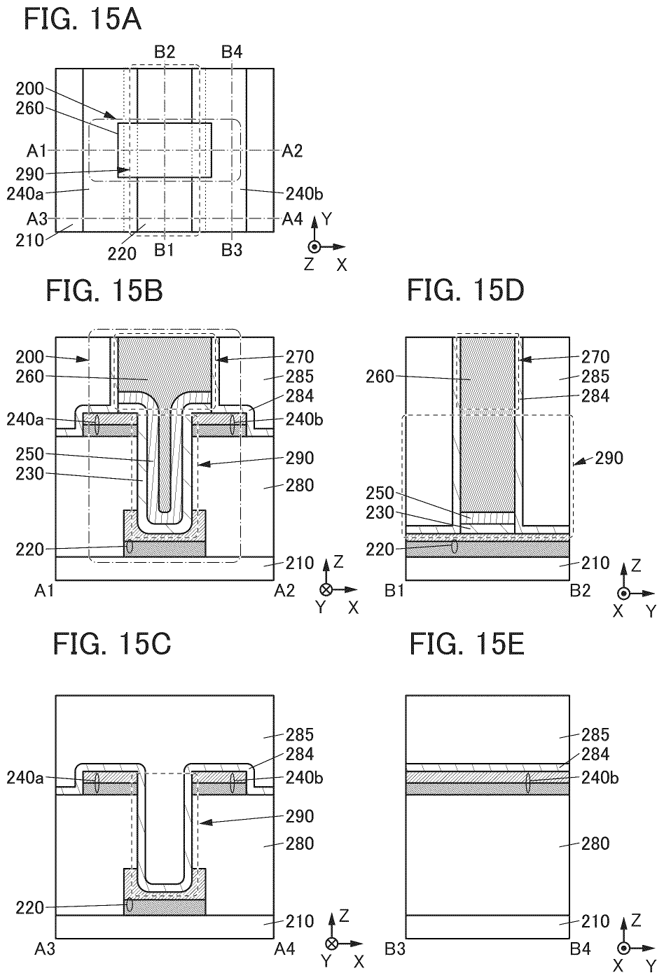

Next, as illustrated in FIGS. 15A to 15E, the conductive layer 260 is formed over the insulating layer 250. The conductive layer 260 is preferably provided to fill the groove portion 290 and the opening portion 270.

The conductive layer 260 is formed in the groove portion 290 having a high aspect ratio. Thus, the conductive layer 260 is preferably formed by a film formation method that provides favorable coverage, further preferably formed by a CVD method, an ALD method, or the like.

Next, the conductive layer 265 is formed over the conductive layer 260, the insulating layer 284, and the insulating layer 285.

Through the above steps, the semiconductor device in FIGS. 1A1 to 1E can be manufactured.

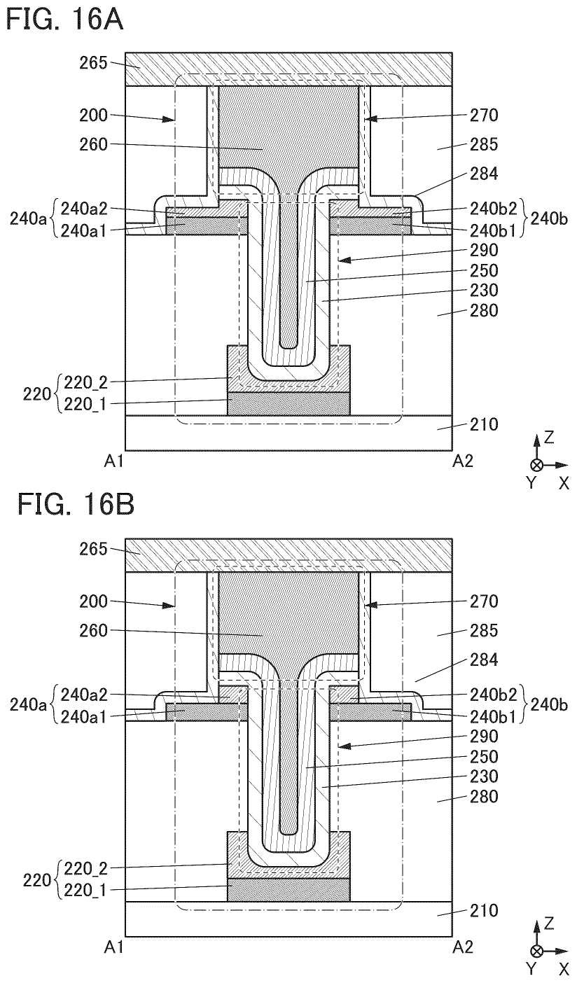

As described above, when etching treatment is performed using the sacrificial layer 262 as a mask, the portion of the conductive layer 240a not overlapping with the sacrificial layer 262 is sometimes reduced in thickness (thinned). FIG. 16A illustrates a semiconductor device manufactured in this case. Also in the structure illustrated in FIG. 16A, the contact area between the conductive layer 240a and the oxide semiconductor layer 230 and the contact area between the conductive layer 240b and the oxide semiconductor layer 230 are not reduced.

FIG. 16B illustrates a semiconductor device manufactured when the portion of the conductive layer 240a not overlapping with the sacrificial layer 262 is removed by etching treatment using the sacrificial layer 262 as a mask. Also in the structure illustrated in FIG. 16B, the contact area between the conductive layer 240a and the oxide semiconductor layer 230 and the contact area between the conductive layer 240b and the oxide semiconductor layer 230 are not reduced.

Although the sacrificial layer 262 is formed over the insulating layer 250 in the above-described example of the method for manufacturing the semiconductor device, the present invention is not limited thereto. For example, the sacrificial layer 262 can be formed before formation of the insulating layer 250, and the insulating layer 250 can be formed after the removal of the sacrificial layer 262 in manufacturing the semiconductor device (see FIGS. 14A to 14E). In other words, the sacrificial layer 262 can be formed over the oxide semiconductor layer 230 in manufacturing the semiconductor device.

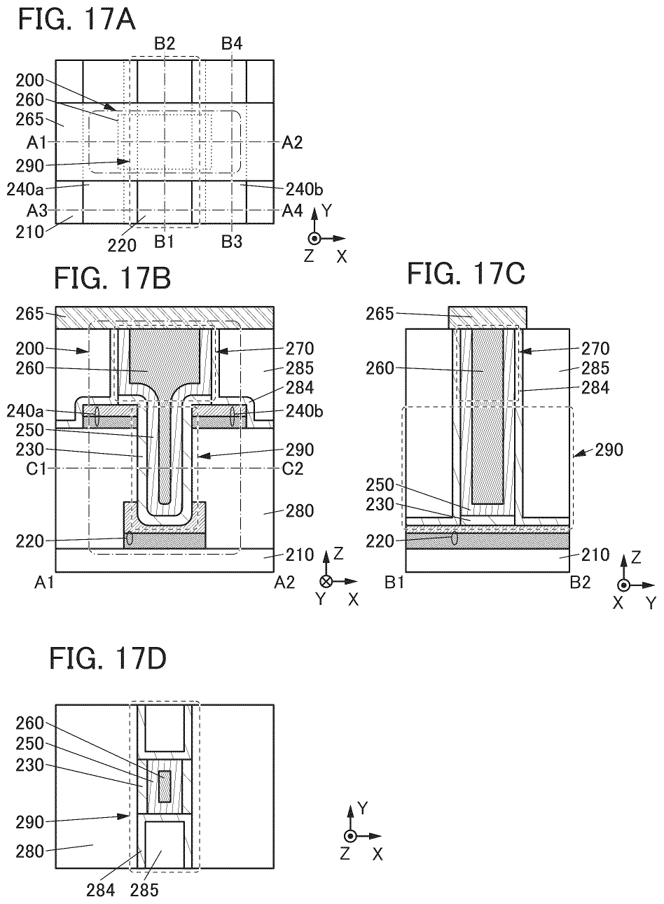

Another structure of the semiconductor device of one embodiment of the present invention is described with reference to FIGS. 17A to 17D. FIG. 17A is a plan view of the semiconductor device including a transistor. FIG. 17B is a cross-sectional view taken along dashed-dotted line A1-A2 in FIG. 17A. FIG. 17C is a cross-sectional view taken along dashed-dotted line B1-B2 in FIG. 17A. FIG. 17D is a cross-sectional view taken along dashed-dotted line C1-C2 in FIG. 17B. Note that FIG. 1C can be referred to for a cross-sectional view along dashed-dotted line A3-A4 in FIG. 17A, and FIG. 1E can be referred to for a cross-sectional view along dashed-dotted line B3-B4 in FIG. 17A.

The semiconductor device illustrated in FIGS. 17A to 17C includes the insulating layer 210 over a substrate (not illustrated); the transistor 200 over the insulating layer 210; the insulating layer 280 over the insulating layer 210; the insulating layer 284 over the insulating layer 280; the insulating layer 285 over the insulating layer 284; and the conductive layer 265 over the insulating layer 284.

The transistor 200 illustrated in FIGS. 17A to 17C includes the conductive layer 220 over the insulating layer 210; the conductive layer 240a and the conductive layer 240b over the insulating layer 280; the oxide semiconductor layer 230 over the conductive layer 220, the conductive layer 240a, and the conductive layer 240b; the insulating layer 250 over the oxide semiconductor layer 230; and the conductive layer 260 over the insulating layer 250.

The semiconductor device illustrated in FIGS. 17A to 17C is different from the semiconductor device illustrated in FIGS. 1A1 to 1E in that the insulating layer 250 includes a portion in contact with the conductive layer 265, for example.

Since the stacked-layer structure from the conductive layer 220 to the insulating layer 230 in the transistor 200 illustrated in FIGS. 17A to 17C is similar to that in the above-described transistor 200, the details thereof is not described.

The insulating layer 250 is in contact with the oxide semiconductor layer 230 and the insulating layer 284 in the opening portion 270. The insulating layer 250 includes a region in contact with at least part of the bottom surface of the conductive layer 265. A portion of the insulating layer 250 which is placed in the opening portion 270 reflects the shape of the opening portion 270. Specifically, the insulating layer 250 is provided to be in contact with the side surface of the opening portion 270 (the side surface of the insulating layer 284). Then, the conductive layer 260 is provided to fill at least part of a depressed portion of the insulating layer 250 reflecting the shape of the opening portion 270.

In the transistor 200 illustrated in FIGS. 17A to 17C, the insulating layer 250 is positioned between the insulating layer 284 and the conductive layer 260 in the opening portion 270; thus, the area where the conductive layer 240a and the conductive layer 260 overlap with each other is small in the plan view. Accordingly, the physical distance between the conductive layer 240a and the conductive layer 260 can be larger than that in the transistor 200 illustrated in FIGS. 1A1 to 1E. Thus, the parasitic capacitance generated between the conductive layer 240a and the conductive layer 260 can be reduced. The same applies to the conductive layer 240b and the conductive layer 260.

That is, the transistor 200 illustrated in FIGS. 17A to 17C has a structure where the parasitic capacitance generated between the other of the source electrode and the drain electrode and the gate electrode and the parasitic capacitance generated between the other of the source electrode and the drain electrode and the gate wiring are reduced. Accordingly, the frequency characteristics of a circuit including the transistor can be improved.

As illustrated in FIG. 17D, the conductive layer 260 is surrounded by the insulating layer 250 in the groove portion 290. That is, the conductive layer 260 is not in contact with the insulating layer 284. Thus, in the case where an oxide insulating layer is used as the insulating layer 284, the conductive layer 260 can be inhibited from being oxidized due to the insulating layer 284 and having an increased resistance.

In the case where the conductive layer 260 has the two-layer structure of the conductive layer 260_1 and the conductive layer 260_2, the sacrificial layer 262 can be formed over the conductive layer 260_1, and then the conductive layer 260_2 can be formed after the removal of the sacrificial layer 262 in manufacturing the semiconductor device (see FIGS. 14A to 14E).

Although the oxide semiconductor layer 230 is formed after formation of the groove portion 290 in the above-described example of the method for manufacturing the semiconductor device, the present invention is not limited thereto. For example, an insulating layer 225 can be formed before formation of the oxide semiconductor layer 230 in manufacturing the semiconductor device.

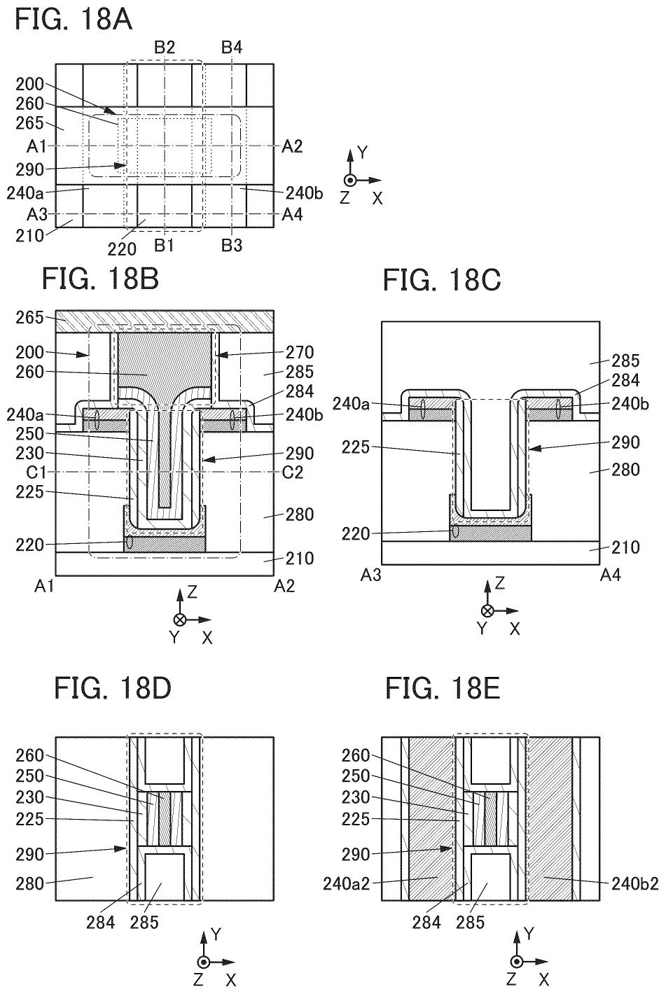

Another structure of the semiconductor device of one embodiment of the present invention is described with reference to FIGS. 18A to 18E. FIG. 18A is a plan view of a semiconductor device including a transistor. FIG. 18B is a cross-sectional view taken along dashed-dotted line A1-A2 in FIG. 18A. FIG. 18C is a cross-sectional view taken along dashed-dotted line A3-A4 in FIG. 18A. Note that FIG. 1D can be referred to for a cross-sectional view taken along dashed-dotted line B1-B2 in FIG. 18A, and FIG. 1E can be referred to for a cross-sectional view taken along dashed-dotted line B3-B4 in FIG. 18A.

FIG. 18D is a cross-sectional view taken along dashed-dotted line C1-C2 in FIG. 18B, and FIG. 18E is a cross-sectional view taken along the XY plane including the conductive layer 240a2.

The semiconductor device illustrated in FIGS. 18A to 18C includes the insulating layer 210 over a substrate (not illustrated); the transistor 200 over the insulating layer 210; the insulating layer 280 over the insulating layer 210; the insulating layer 284 over the insulating layer 280; the insulating layer 285 over the insulating layer 284; and the conductive layer 265 over the insulating layer 284.

The transistor 200 illustrated in FIGS. 18A to 18C includes the conductive layer 220 over the insulating layer 210; the conductive layer 240a and the conductive layer 240b over the insulating layer 280; the insulating layer 225; the oxide semiconductor layer 230 over the conductive layer 220, the insulating layer 225, the conductive layer 240a, and the conductive layer 240b; the insulating layer 250 over the oxide semiconductor layer 230; and the conductive layer 260 over the insulating layer 250.

The semiconductor device illustrated in FIGS. 18A to 18C is different from the semiconductor device illustrated in FIGS. 1A1 to 1E in including the insulating layer 225 in the groove portion 290.

In the transistor 200 illustrated in FIGS. 18A to 18C, the stacked-layer structure from the conductive layer 220 to the conductive layer 240 and the stacked-layer structure from the oxide semiconductor layer 230 to the conductive layer 260 are similar to those in the above-described transistor 200; thus, the detailed description thereof is omitted.

The insulating layer 225 is provided along at least part of the side surface of the groove portion 290. In FIGS. 18B to 18E, the insulating layer 225 is provided to cover the side surface of the groove portion 290. Specifically, the insulating layer 225 includes a region in contact with the side surface of the insulating layer 280 in the groove portion 290. The insulating layer 225 includes a region in contact with the side surface of the conductive layer 240a on the groove portion 290 side, a region in contact with the side surface of the conductive layer 240b on the groove portion 290 side, and a region in contact with the conductive layer 220. The insulating layer 225 can also be referred to as a sidewall, a sidewall insulating layer, a side surface protective layer, or the like.

The insulating layer 225 can be formed using a material that can be used for the insulating layer 250.

As described above, oxygen vacancies and impurities are preferably reduced as much as possible in the channel formation region of the oxide semiconductor layer. It is particularly preferable that hydrogen in the channel formation region of the oxide semiconductor layer be reduced as much as possible.

In view of this, as the insulating layer 225 provided outside the oxide semiconductor layer 230, a barrier insulating layer against hydrogen is preferably used. Accordingly, diffusion of hydrogen into the oxide semiconductor layer 230 can be inhibited, and the reliability of the transistor 200 can be improved. For example, as the insulating layer 225, a silicon nitride film, a silicon nitride oxide film, or an aluminum oxide film is preferably used, and a silicon nitride film is further preferably used.

Note that a silicon nitride film also has a barrier property against oxygen. Thus, using a silicon nitride film as the insulating layer 225 can inhibit extraction of oxygen from the oxide semiconductor layer 230, and accordingly can inhibit formation of oxygen vacancies in the oxide semiconductor layer 230. Furthermore, when a silicon nitride film is used as the insulating layer 225, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved. The insulating layer 225 is in contact with the side surface of the conductive layer 240a in the groove portion 290 in some cases. In this case, the use of a silicon nitride film as the insulating layer 225 can inhibit oxidation of the side surface of the conductive layer 240a in the groove portion 290 and formation of an oxide film on the side surface. It is thus possible to inhibit a reduction in the on-state current or field-effect mobility of the transistor 200.

A silicon nitride film included in the insulating layer 225 is preferably formed by a PEALD method. This can improve the coverage of the side surface of the groove portion 290 with the insulating layer 225, so that the insulating layer 225 with a uniform thickness can be formed.

FIG. 18B illustrates an example where the insulating layer 225 has a single-layer structure. Note that the insulating layer 225 can have a stacked-layer structure of two or more layers.

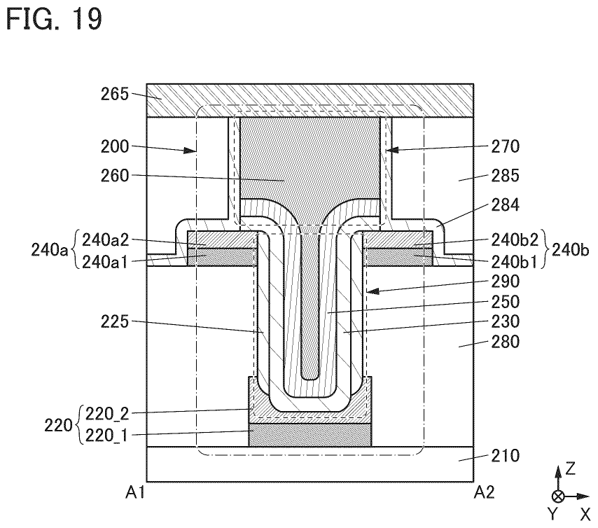

As illustrated in FIG. 19, the conductive layer 220_2 preferably includes a first depressed portion and a second depressed portion positioned outside the first depressed portion. The first depressed portion is deeper than the second depressed portion. In other words, the bottom surface of the first depressed portion is positioned below the bottom surface of the second depressed portion (on the insulating layer 210 side). The second depressed portion is provided in the conductive layer 220_2 at the time of forming the groove portion 290, and then the first depressed portion is provided in the conductive layer 220_2 at the time of processing the insulating layer 225. Thus, in FIG. 19, the side surface of the second depressed portion is aligned with the side surface of the insulating layer 280 in the groove portion 290, and the side surface of the first depressed portion is aligned with the side surface of the insulating layer 225 on the oxide semiconductor layer 230 side. Hereinafter, the first depressed portion and the second depressed portion are collectively referred to as a depressed portion in some cases.

In FIG. 19, the insulating layer 225 is in contact with the bottom and side surfaces of the depressed portion (specifically, the second depressed portion) of the conductive layer 220, and is in contact with the side surfaces of the insulating layer 280, the conductive layer 240a, and the conductive layer 240b in the groove portion 290. In the groove portion 290, the oxide semiconductor layer 230 is in contact with the bottom and side surfaces of the depressed portion (specifically, the first depressed portion) of the conductive layer 220 and the side surface of the insulating layer 225. The insulating layer 250 is positioned inside the oxide semiconductor layer 230 in the groove portion 290, and the conductive layer 260 is positioned inside the insulating layer 250 in the groove portion 290.

When the conductive layer 220_2 includes the first depressed portion and the second depressed portion, the side surface of the conductive layer 220_2 is in contact with the oxide semiconductor layer 230. Accordingly, the contact area between the conductive layer 220_2 and the oxide semiconductor layer 230 can be increased, so that the contact resistance therebetween can be reduced. This can inhibit a decrease in on-state current of the transistor 200 due to the contact resistance between the conductive layer 220_2 and the oxide semiconductor layer 230.

Although the groove portion 290 is formed after formation of the conductive layer 240f in the above-described example of the method for manufacturing the semiconductor device, the present invention is not limited thereto. For example, the groove portion 290 can be formed after formation of the first conductive film and the second conductive film to be the conductive layers 240f in manufacturing the semiconductor device.

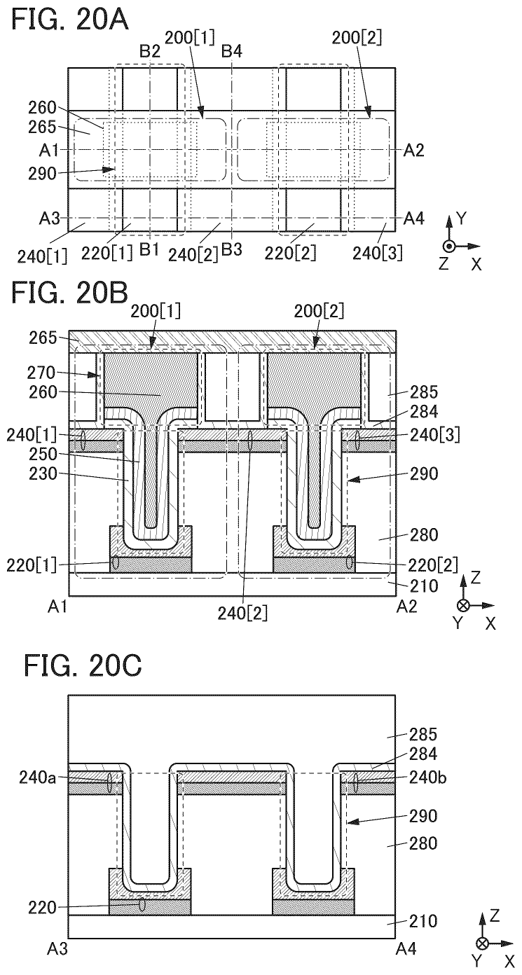

Another structure of the semiconductor device of one embodiment of the present invention is described with reference to FIGS. 20A to 20C. FIG. 20A is a plan view of the semiconductor device including a transistor. Note that FIG. 20A is a plan view of a region including two transistors adjacent to each other in the X direction. FIG. 20B is a cross-sectional view taken along dashed-dotted line A1-A2 in FIG. 20A. FIG. 20C is a cross-sectional view taken along dashed-dotted line A3-A4 in FIG. 20A. Note that FIG. 1D can be referred to for a cross-sectional view taken along dashed-dotted line B1-B2 in FIG. 20A, and FIG. 1E can be referred to for a cross-sectional view taken along dashed-dotted line B3-B4 in FIG. 20A.

The semiconductor device illustrated in FIGS. 20A to 20C includes the insulating layer 210 over a substrate (not illustrated); a transistor 200[1] and a transistor 200[2] over the insulating layer 210; the insulating layer 280 over the insulating layer 210; the insulating layer 284 over the insulating layer 280; the insulating layer 285 over the insulating layer 284; and the conductive layer 265 over the insulating layer 284. The transistor 200[1] and the transistor 200[2] are adjacent to each other in the X direction.

The transistor 200[1] includes a conductive layer 220[1] over the insulating layer 210; a conductive layer 240[1] and a conductive layer 240[2] over the insulating layer 280; the oxide semiconductor layer 230 over the conductive layer 220[1], the conductive layer 240[1], and the conductive layer 240[2]; the insulating layer 250 over the oxide semiconductor layer 230; and the conductive layer 260 over the insulating layer 250.

The transistor 200[2] includes a conductive layer 220[2] over the insulating layer 210; the conductive layer 240[2] and a conductive layer 240[3] over the insulating layer 280; the oxide semiconductor layer 230 over the conductive layer 220[2], the conductive layer 240[2], and the conductive layer 240[3]; the insulating layer 250 over the oxide semiconductor layer 230; and the conductive layer 260 over the insulating layer 250.

The semiconductor device illustrated in FIGS. 20A to 20C is different from the semiconductor device illustrated in FIGS. 1A1 to 1E in that the transistors 200 adjacent to each other in the X direction share the conductive layer 240. Specifically, the transistor 200[1] and the transistor 200[2] share the conductive layer 240[2]. When the transistors 200 adjacent to each other in the X direction share the conductive layer 240, the area occupied by the semiconductor device can be reduced.

The above description of the conductive layer 220 can be referred to for materials, structures, and the like that can be used for the conductive layer 220[1] and the conductive layer 220[2]. The above description of the conductive layer 240 can be referred to for materials, structures, and the like that can be used for the conductive layer 240[1] to the conductive layer 240[3].

### Structure Example 2 of Semiconductor Device

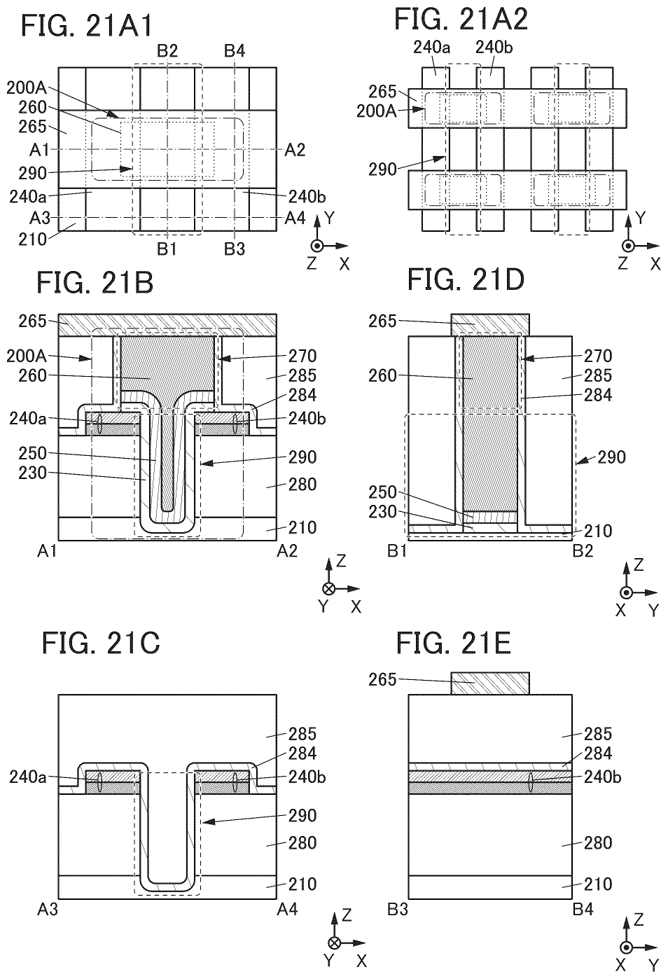

A structure example of a semiconductor device whose structure is partly different from that of the example of the semiconductor device described in <Structure example 1 of semiconductor device> will be described below with reference to FIGS. 21A1 to 21E and FIGS. 22A and 22B. Note that description of the portions already described is omitted and only different portions are described in detail. Even when positions or shapes of components are different from those in the above example, the same reference numerals are used as long as the components have the same functions as those in the above example, and detailed description thereof is omitted in some cases.

FIG. 21A1 is a plan view of a semiconductor device including a transistor. FIG. 21A2 is a plan view illustrating an example where a plurality of transistors are arranged. FIG. 21B is a cross-sectional view taken along dashed-dotted line A1-A2 in FIG. 21A1. FIG. 21C is a cross-sectional view taken along dashed-dotted line A3-A4 in FIG. 21A1. FIG. 21D is a cross-sectional view taken along dashed-dotted line B1-B2 in FIG. 21A1. FIG. 21E is a cross-sectional view taken along dashed-dotted line B3-B4 in FIG. 21A1. Note that for simplification, some components are not illustrated in the plan views in FIGS. 21A1 and 21A2.

The semiconductor device illustrated in FIGS. 21A1 to 21E includes the insulating layer 210 over a substrate (not illustrated); a transistor 200A over the insulating layer 210; the insulating layer 280 over the insulating layer 210; the insulating layer 284 over the insulating layer 280; the insulating layer 285 over the insulating layer 284; and the conductive layer 265 over the transistor 200A, the insulating layer 284, and the insulating layer 285.

### [Transistor 200A]

The transistor 200A includes the conductive layer 240a and the conductive layer 240b over the insulating layer 280; the oxide semiconductor layer 230 over the conductive layer 220, the conductive layer 240a, and the conductive layer 240b; the insulating layer 250 over the oxide semiconductor layer 230; and the conductive layer 260 over the insulating layer 250.

The transistor 200A illustrated in FIGS. 21A1 to 21E is different from the transistor 200 illustrated in FIGS. 1A1 to 1E in not including the conductive layer 220.

In the transistor 200A, the oxide semiconductor layer 230 functions as a semiconductor layer, the conductive layer 260 functions as a gate electrode, the insulating layer 250 functions as a gate insulating layer, the conductive layer 240a functions as one of a source electrode and a drain electrode, and the conductive layer 240b functions as the other of the source electrode and the drain electrode.

In the groove portion 290, a region of the oxide semiconductor layer 230 facing the conductive layer 260 with the insulating layer 250 therebetween and the vicinity of the region function as a channel formation region of the transistor 200A. A region of the oxide semiconductor layer 230 in the vicinity of the conductive layer 240a functions as one of the source region and the drain region, and a region of the oxide semiconductor layer 230 in the vicinity of the conductive layer 240b functions as the other of the source region and the drain region. That is, the channel formation region is interposed between the source region and the drain region.

Here, FIG. 22A is a cross-sectional view taken along dashed-dotted line A1-A2 in FIG. 21B. FIG. 22A corresponds to an example of an enlarged view of FIG. 21B.

As illustrated in FIG. 22A, the channel length of the transistor 200A is the distance between the source region and the drain region. For example, the channel length of the transistor 200A can be regarded as the sum of the height of the side surface of the groove portion 290 on the conductive layer 240a side, the width of the bottom portion, and the height of the side surface of the groove portion 290 on the conductive layer 240b side. That is, the channel length of the transistor 200A is determined by the depth of the groove portion of the insulating layer 280. In FIG. 22A, the channel length L of the transistor 200A is indicated by a dashed double-headed arrow.

Unlike a planar transistor, the transistor 200A can have a larger channel length as the groove portion 290 is deeper. In other words, the channel length can be increased without changing the area occupied by the transistor 200A. An increase in the channel length of the transistor can reduce a variation in the threshold voltage of the transistor.

In the case of manufacturing the transistor 200A having the same channel length as a vertical transistor, the groove portion of the insulating layer 280 can be shallower than that of the vertical transistor. That is, the groove portion 290 can be formed to be shallow. Thus, the minute groove portion 290 can be formed with high yield as compared with the case of manufacturing the transistor 200.

The channel width of the transistor 200A is equal or substantially equal to the length of the oxide semiconductor layer 230 in the Y direction (the length H230 shown in FIG. 3B). The channel width of the transistor 200A can be regarded as being equal or substantially equal to the width of the conductive layer 260 in the Y direction or the width of the insulating layer 250 in the Y direction.

Note that a structure similar to that of the transistor 200 can be employed for the transistor 200A. For example, as illustrated in FIG. 22B, the transistors 200A adjacent to each other in the X direction can share the conductive layer 240. Specifically, a transistor 200A[1] and a transistor 200A[2] adjacent to each other in the X direction share the conductive layer 240[2]. This can reduce the area occupied by the semiconductor device.

The above is the description of the structure example of the semiconductor device including the transistor 200A.

In the example of the semiconductor device described above in <Structure example 1 of semiconductor device>, one transistor is provided in a region where the groove portion 290 and the gate wiring overlap with each other. Note that the present invention is not limited thereto. For example, the semiconductor device can include two transistors in a region where the groove portion 290 and the gate wiring overlap with each other.

### Structure Example 3 of Semiconductor Device

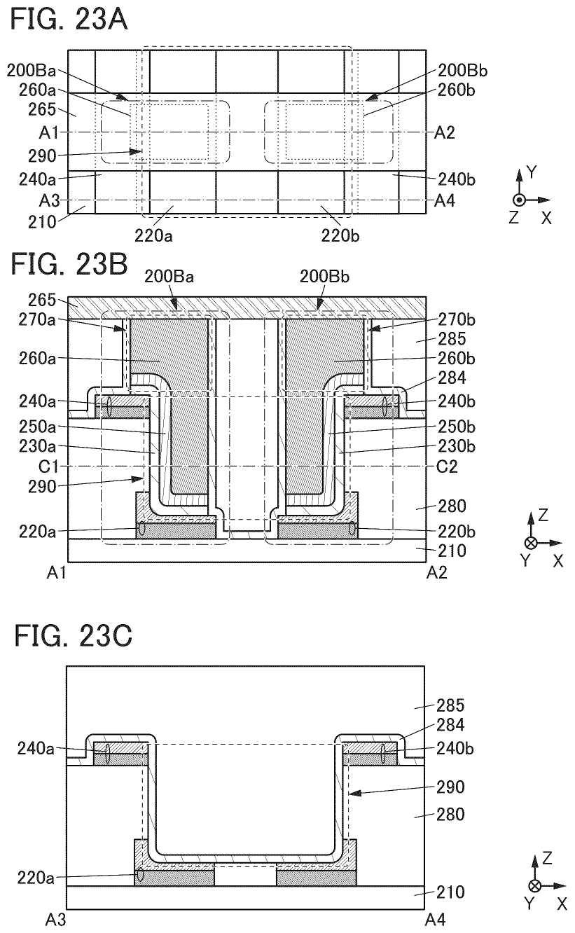

A structure example of a semiconductor device whose structure is partly different from that of the example of the semiconductor device described in <Structure example 1 of semiconductor device> will be described below with reference to FIGS. 23A to 23C, FIG. 24, FIGS. 25A to 25C, and FIGS. 26A to 26C. Note that description of the portions already described is omitted and only different portions are described in detail. Even when positions or shapes of components are different from those in the above example, the same reference numerals are used as long as the components have the same functions as those in the above example, and detailed description thereof is omitted in some cases.

FIG. 23A is a plan view of the semiconductor device including two transistors. FIG. 23B is a cross-sectional view taken along dashed-dotted line A1-A2 in FIG. 23A. FIG. 23C is a cross-sectional view taken along dashed-dotted line A3-A4 in FIG. 23A.

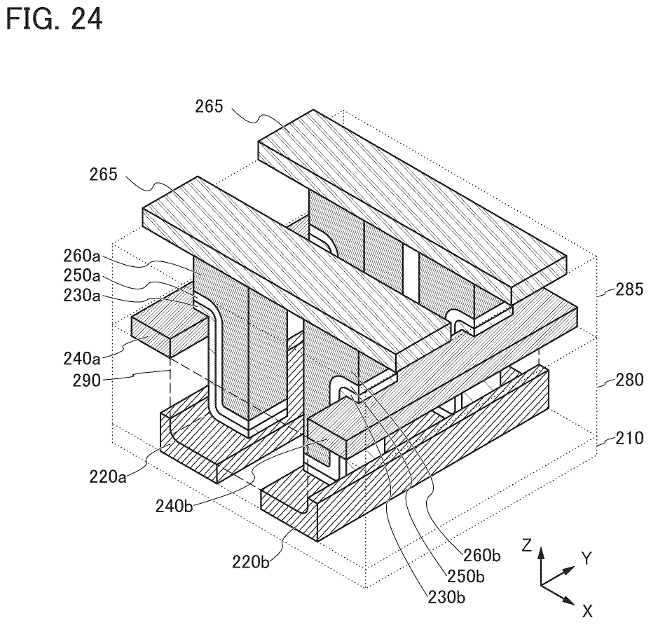

FIG. 24 is a schematic perspective view of the semiconductor device illustrated in FIGS. 23A to 23C. Specifically, FIG. 24 is a schematic perspective view of a semiconductor device including four transistors. For some components (e.g., interlayer insulating layers), FIG. 24 shows only outlines indicated by dotted lines.

The semiconductor device illustrated in FIGS. 23A to 23C includes the insulating layer 210 over a substrate (not illustrated); a transistor 200Ba and a transistor 200Bb over the insulating layer 210; the insulating layer 280 over the insulating layer 210; the insulating layer 284 over the insulating layer 280; the insulating layer 285 over the insulating layer 284; and the conductive layer 265 over the transistor 200Ba, the transistor 200Bb, the insulating layer 284, and the insulating layer 285. Hereinafter, the transistor 200Ba and the transistor 200Bb are collectively referred to as a transistor 200B in some cases.

The semiconductor device illustrated in FIGS. 23A to 23C is different from the semiconductor device illustrated in FIGS. 1A1 to 1E in including the transistor 200Ba and the transistor 200Bb in a region where the conductive layer 265 and the groove portion 290 overlap with each other.

### [Transistor 200B]

The transistor 200Ba includes a conductive layer 220a over the insulating layer 210; the conductive layer 240a over the insulating layer 280; an oxide semiconductor layer 230a over the insulating layer 220a and the conductive layer 240a; the insulating layer 250a over the semiconductor layer 230a; and a conductive layer 260a over the insulating layer 250a. An opening portion 270a reaching the insulating layer 250a is provided in the insulating layer 284 to overlap with the groove portion 290. The conductive layer 260a is placed to be positioned in the opening portion 270a at least partly.

Similarly, the transistor 200Bb includes a conductive layer 220b over the insulating layer 210; the conductive layer 240b over the insulating layer 280; an oxide semiconductor layer 230b over the insulating layer 220b and the conductive layer 240b; the insulating layer 250b over the semiconductor layer 230b; and a conductive layer 260b over the insulating layer 250b. An opening portion 270b reaching the insulating layer 250b is provided in the insulating layer 284 to overlap with the groove portion 290. The conductive layer 260b is placed to be positioned in the opening portion 270b at least partly.

In the plan view, the transistor 200Ba and the transistor 200Bb have a line-symmetric structure with a perpendicular bisector of the dashed-dotted line A1-A2 as the symmetric axis. Thus, description of the structure of the transistor 200Ba can be referred to for the structure of the transistor 200Bb by replacing the transistor 200Ba, the conductive layer 220a, the conductive layer 240a, the oxide semiconductor layer 230a, the insulating layer 250a, and the conductive layer 260a with the transistor 200Bb, the conductive layer 220b, the conductive layer 240b, the oxide semiconductor layer 230b, the insulating layer 250b, and the conductive layer 260b, respectively, and appropriately replacing words or sentences as necessary. The transistor 200Ba will be mainly described below.

In the transistor 200Ba, the oxide semiconductor layer 230a functions as a semiconductor layer, the conductive layer 260a functions as a gate electrode, the insulating layer 250a functions as a gate insulating layer, the conductive layer 220a functions as one of a source electrode and a drain electrode, and the conductive layer 240a functions as the other of the source electrode and the drain electrode. The conductive layer 265 including a region functioning as a gate wiring.

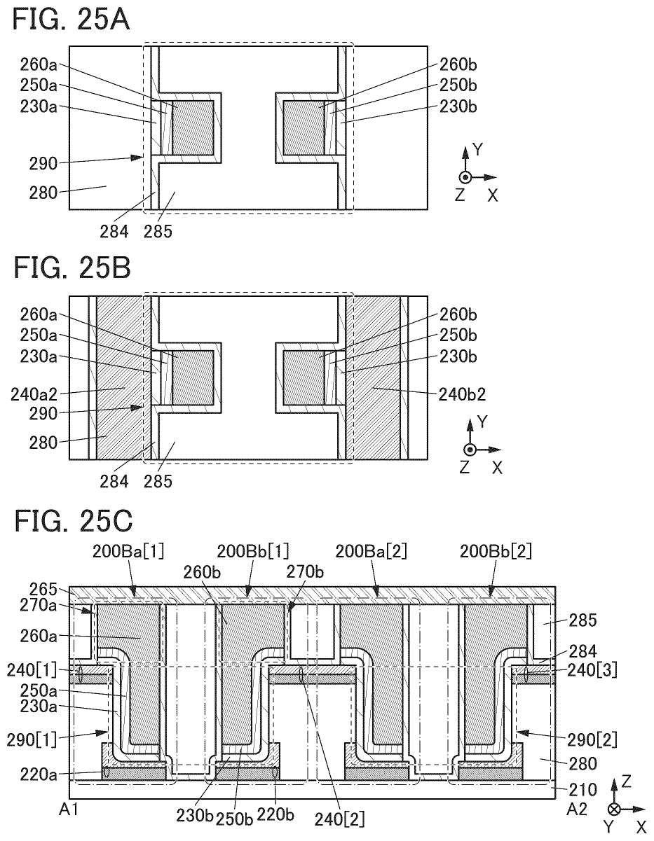

FIG. 25A is a cross-sectional view taken along dashed-dotted line C1-C2 in FIG. 23B. FIG. 25B is a cross-sectional view taken along the XY plane including the conductive layer 240a2.

As illustrated in FIGS. 25A and 25B, the insulating layer 284 is provided in contact with the side surface of the oxide semiconductor layer 230a inside the groove portion 290. When an insulating layer having a function of capturing or fixing hydrogen is used as the insulating layer 284, diffusion of hydrogen into the oxide semiconductor layer 230a from above the insulating layer 284 can be inhibited, and hydrogen contained in the oxide semiconductor layer 230a can be captured or fixed. Thus, the hydrogen concentration in the oxide semiconductor layer 230a can be reduced.

With the structure where the two transistors are provided in the region where the groove portion 290 and the conductive layer 265 overlap with each other, the area occupied by the semiconductor device can be reduced, and miniaturization or high integration of the semiconductor device can be achieved.

The transistor 200Ba and the transistor 200Bb can be formed in such a manner that two sacrificial layers 262 are provided to be apart from each other in a region where the conductive layer 265 is placed in the groove portion 290, for example.

Note that a structure similar to that of at least one of the transistor 200 and the transistor 200A can also be employed for the transistor 200B. For example, as illustrated in FIG. 25C, the transistor 200Ba and the transistor 200Bb adjacent to each other in the X direction can share the conductive layer 240. Specifically, a transistor 200Bb[1] and a transistor 200Ba[2] share the conductive layer 240[2]. This can reduce the area occupied by the semiconductor device. Note that the components of each of the transistor 200Ba[1] and the transistor 200Bb[1] are placed in the groove portion 290[1] at least partly, and the components of each of the transistor 200Ba[2] and the transistor 200Bb[2] are placed in the groove portion 290[2] at least partly.

Although FIG. 25C illustrates a structure example where the transistor 200Bb[1] and the transistor 200Ba[2] are connected to the same conductive layer 265, the present invention is not limited thereto. For example, the transistor 200Bb[1] and the transistor 200Ba[2] can be connected to different conductive layers 265.

Although FIG. 25A illustrates a structure where the oxide semiconductor layer 230a and the oxide semiconductor layer 230b adjacent to each other in the X direction in one groove portion 290 are provided to face each other with the insulating layer 285 therebetween, the present invention is not limited thereto.

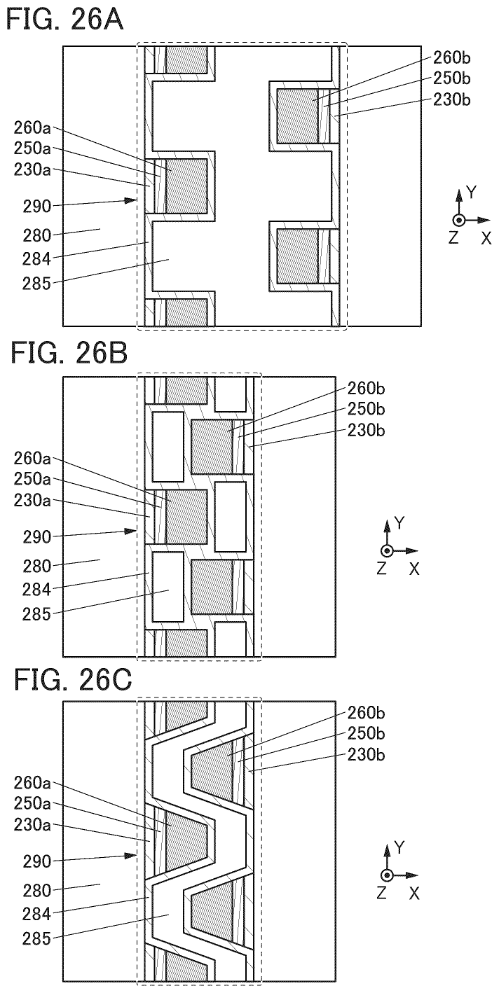

For example, as illustrated in FIG. 26A, the oxide semiconductor layer 230a and the oxide semiconductor layer 230b positioned in one groove portion 290 may be placed to be shifted in the Y direction or may be arranged alternately. Specifically, the oxide semiconductor layer 230a and the oxide semiconductor layer 230b can be placed so as not to face each other in the plan view. With such a structure, the width of the groove portion 290 in the X direction can be small, so that the semiconductor device can be miniaturized and highly integrated. FIG. 26B illustrates a structure where the width of the groove portion 290 in the X direction is smaller than that in FIG. 26A.

Note that as illustrated in FIG. 26C, the conductive layer 260a, the insulating layer 250a, and the oxide semiconductor layer 230a may be formed such that their side surfaces in the plan view are inclined with respect to the X direction. With such a structure, the width of the groove portion 290 in the X direction can be reduced, and the semiconductor device can be miniaturized and highly integrated in some cases. Alternatively, with the structure illustrated in FIG. 26C, foreign matters such as dust and particles that might be generated in the manufacturing process are easily removed from the groove portion 290 by a cleaning step. Thus, a semiconductor device with high yield can be provided.

This embodiment can be combined with any of the other embodiments as appropriate. In this specification, in the case where a plurality of structure examples are shown in one embodiment, the structure examples can be combined as appropriate.

### Embodiment 2

In this embodiment, an oxide semiconductor layer that can be used as an oxide semiconductor layer of a transistor will be described. As the oxide semiconductor layer of one embodiment of the present invention, a single layer or stacked layers including a metal oxide can be used. Note that in an oxide semiconductor layer having a stacked-layer structure, a boundary between stacked films is sometimes difficult to observe as described later.

### [Metal Oxide]

The metal oxide of one embodiment of the present invention preferably contains at least indium (In) or zinc (Zn), particularly preferably contains indium as its main component. The metal oxide preferably contains two or three selected from indium, an element M, and zinc, and particularly preferably contains indium and zinc as its main components. Here, the metal oxide contains indium and zinc as its main components, and can further contain the element M. The element M is a metal element or a metalloid element that has a high bonding energy with oxygen, such as a metal element or a metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, still further preferably one or more selected from gallium and tin. When the element M included in the metal oxide is gallium, the metal oxide of one embodiment of the present invention preferably includes one or more selected from indium, gallium, and zinc. In this specification and the like, a metal element and a metalloid element may be collectively referred to as a “metal element”, and a “metal element” in this specification and the like may include a metalloid element.

Examples of the metal oxide of one embodiment of the present invention include indium zinc oxide (also referred to as In—Zn oxide or IZO (registered trademark)), indium tin oxide (also referred to as In—Sn oxide or ITO), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), indium aluminum zinc oxide (also referred to as In—Al—Zn oxide or IAZO), indium tin zinc oxide (also referred to as In—Sn—Zn oxide), indium titanium zinc oxide (In—Ti—Zn oxide), indium gallium zinc oxide (also referred to as In—Ga—Zn oxide or IGZO), indium gallium zinc oxide containing silicon oxide (ITSO), indium gallium tin zinc oxide (also referred to as In—Ga—Sn—Zn oxide or IGZTO), and indium gallium aluminum zinc oxide (also referred to as In—Ga—Al—Zn oxide, IGAZO, or IAGZO). Alternatively, it is possible to use, for example, gallium zinc oxide (also referred to as Ga—Zn oxide or GZO), aluminum zinc oxide (also referred to as Al—Zn oxide or AZO), gallium tin oxide (Ga—Sn oxide), or aluminum tin oxide (Al—Sn oxide). As the metal oxide of one embodiment of the present invention, indium oxide can be used. Alternatively, as the metal oxide of one embodiment of the present invention, gallium oxide, zinc oxide, or the like can be used.

When the indium content percentage in the metal oxide is increased, the transistor can have a high on-state current and excellent frequency characteristics.

Instead of indium, the metal oxide may contain one or more kinds of metal elements with a large period number in the periodic table. Alternatively, in addition to indium, the metal oxide may contain one or more kinds of metal elements with a large period number in the periodic table. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A metal oxide having a high zinc content percentage has high crystallinity, whereby diffusion of impurities in the metal oxide can be inhibited. Consequently, a change in electrical characteristics of the transistor is suppressed, and the transistor can have high reliability.

A high content percentage of the element M in a metal oxide can inhibit formation of oxygen vacancies in the metal oxide. Accordingly, generation of carriers due to oxygen vacancies is inhibited, which makes the off-state current of the transistor low. Furthermore, changes in the electrical characteristics of the transistor can be reduced to improve the reliability of the transistor.

The description is made on a structure example of an oxide semiconductor layer that enables the field-effect mobility of a transistor to be increased. For example, indium oxide or a stacked-layer structure of indium oxide and IGZO is preferably used. Specifically, the oxide semiconductor layer preferably contains indium oxide and IGZO over the indium oxide. Moreover, IGZO containing nitrogen is preferably used as the oxide semiconductor layer. For example, IGZO containing nitrogen can be formed by performing N₂O plasma treatment during or after the deposition of IGZO. For the oxide semiconductor layer, at least one of indium oxide, In—Ga oxide, In—Zn oxide, and IGZTO is preferably used.

In this embodiment, In-M-Zn oxide is sometimes described as an example of the metal oxide.

The oxide semiconductor layer of one embodiment of the present invention preferably includes a metal oxide having crystallinity. Examples of the structure of a metal oxide having crystallinity include a c-axis-aligned crystalline (CAAC) structure, a polycrystalline structure, and a nanocrystalline (nc) structure. By using a metal oxide having crystallinity for the oxide semiconductor layer, the density of defect states in the oxide semiconductor layer can be reduced. This can improve the reliability of a transistor including the oxide semiconductor layer of one embodiment of the present invention, thereby improving the reliability of a semiconductor device including the transistor.

Note that there is no particular limitation on the crystallinity of the metal oxide included in the oxide semiconductor layer. The oxide semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions). The oxide semiconductor layer having crystallinity can inhibit deterioration of the transistor characteristics in some cases.

The crystallinity of the oxide semiconductor layer can be analyzed with an X-ray diffraction (XRD) pattern, a transmission electron microscope (TEM) image, or an electron diffraction (ED) pattern, for example. Alternatively, these methods may be combined to be employed for analysis.

The oxide semiconductor layer of one embodiment of the present invention preferably includes a metal oxide having a CAAC structure. The CAAC structure is a crystal structure where a plurality of microcrystals (typically, a plurality of microcrystals each having a hexagonal crystal structure) have c-axis alignment and are connected on the a-b plane without alignment. According to a high-resolution TEM image (also referred to as a multi-wavelength interference image) of a cross section of an oxide semiconductor layer having the CAAC structure, metal atoms are arranged in a layered manner in crystal parts. Thus, the oxide semiconductor layer having the CAAC structure can be regarded as having a structure including the layered crystal parts.

The CAAC structure is formed such that the c-axis is perpendicular or substantially perpendicular to a formation surface or a surface of an oxide semiconductor layer, for example. In the CAAC structure, metal atoms are arranged in a layered manner in the direction parallel or substantially parallel to the formation surface. In a region having the CAAC structure, an angle formed by the c-axis and the formation surface is preferably within 90°±20° (greater than or equal to 70° and less than or equal to 110°), further preferably within 90°±15° (greater than or equal to 75° and less than or equal to 105°), still further preferably within 90°±10° (greater than or equal to 80° and less than or equal to 100°), yet further preferably within 90°±5° (greater than or equal to 85° and less than or equal to 95°).

In the case where the oxide semiconductor layer has the CAAC structure, a group of bright spots (specifically, bright spots arranged in a layered manner) reflecting a layered arrangement of metal atoms is observed in a cross-sectional TEM image of the oxide semiconductor layer. Specifically, a state where bright spots are arranged in a layered manner in the direction parallel or substantially parallel to the formation surface is observed.

When the oxide semiconductor layer having the CAAC structure is subjected to electron diffraction, spots indicating c-axis alignment (bright spots) are observed in the electron diffraction pattern.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form an FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably greater than or equal to 70° and less than or equal to 110° (within 90°±20°), further preferably greater than or equal to 75° and less than or equal to 105° (within 90°±15°), still further preferably greater than or equal to 80° and less than or equal to 100° (within 90°±10°), yet further preferably greater than or equal to 85° and less than or equal to 95° (within 90°±5°) can be regarded as having the CAAC structure.

When the oxide semiconductor layer having the CAAC structure is observed from the direction perpendicular to the formation surface by using the TEM image, a triangular or hexagonal atomic arrangement and crystallinity are observed in the a-b plane.

### [Composition of Metal Oxide]

The metal oxide of one embodiment of the present invention preferably contains indium (In), and further preferably has a high In content percentage. The use of a metal oxide having a high In content percentage as the oxide semiconductor layer can increase the on-state current of the transistor and improve the frequency characteristics of the transistor. For example, indium oxide is preferably used as the oxide semiconductor layer.

The metal oxide of one embodiment of the present invention can contain zinc. The metal oxide containing zinc has high crystallinity, e.g., has the CAAC structure. For example, In—Zn oxide can be used for the oxide semiconductor layer. Specifically, it is possible to use a metal oxide having an atomic ratio of In:Zn=1:1 or the neighborhood thereof, In:Zn=2:1 or the neighborhood thereof, or In:Zn=4:1 or the neighborhood thereof. Note that the neighborhood of the atomic ratio includes ±30% of an intended atomic ratio.

The metal oxide of one embodiment of the present invention can contain the element M. When the metal oxide contains the element M, formation of oxygen vacancies in the metal oxide can be inhibited. Thus, the reliability of the transistor including the oxide semiconductor layer can be increased.

For example, In—Zn oxide containing a slight amount of the element M can be used for the oxide semiconductor layer. Specifically, it is possible to use a metal oxide having an atomic ratio of In:Ga:Zn=4:0.1:1 or the neighborhood thereof, In:Ga:Zn=2:0.1:1 or the neighborhood thereof, or In:Ga:Zn=1:0.1:1 or the neighborhood thereof. It is also possible to use a metal oxide having an atomic ratio of In:Sn:Zn=4:0.1:1 or the neighborhood thereof, In:Sn:Zn=2:0.1:1 or the neighborhood thereof, or In:Sn:Zn=1:0.1:1 or the neighborhood thereof.

Moreover, In—Zn oxide containing the element M can be used for the oxide semiconductor layer. Specifically, it is possible to use a metal oxide having an atomic ratio of In:M:Zn=1:1:1 or the neighborhood thereof, In:M:Zn=1:1:1.2 or the neighborhood thereof, In:M:Zn=1:1:0.5 or the neighborhood thereof, In:M:Zn=1:1:2 or the neighborhood thereof, In:M:Zn=4:2:3 or the neighborhood thereof, In:M:Zn=1:3:2 or the neighborhood thereof, or In:M:Zn=1:3:4 or the neighborhood thereof.

Note that in the case where the metal oxide is formed by a sputtering method, the composition of the formed metal oxide may be different from that of a sputtering target. In particular, the zinc content percentage of the formed metal oxide may be reduced to approximately 50% of that of the sputtering target.

In the case where a metal oxide containing a plurality of kinds of metal elements, such as In—Ga—Zn oxide, is formed by an ALD method, the cycle ratio of precursors containing respective metal elements can be set in accordance with the target composition. For example, to form an In—Ga—Zn oxide film having an atomic ratio of In:Ga:Zn=1:3:2, it is possible to perform one cycle of deposition using a precursor containing In and treatment with an oxidizer, three cycles of deposition using a precursor containing Ga and treatment with an oxidizer, and two cycles of deposition using a precursor containing Zn and treatment with an oxidizer. Note that the atomic ratio of the metal elements in the formed metal oxide film does not sometimes correspond with the cycle ratio of the precursors containing the respective metal elements.

Analysis of the composition of the metal oxide used for the oxide semiconductor layer can be performed by EDX, XPS, inductively coupled plasma-mass spectrometry (ICP-MS), or inductively coupled plasma-atomic emission spectrometry (ICP-AES), for example. Alternatively, these methods may be combined to be employed for analysis. As for an element whose content percentage is low, the actual content percentage may be different from the content percentage obtained by analysis because of the influence of the analysis accuracy. For example, in the case where the content percentage of the element M is low, the content percentage of the element M obtained by analysis may be lower than the actual content percentage.

The oxide semiconductor layer of one embodiment of the present invention may have a stacked-layer structure of two or more layers. In the case where the oxide semiconductor layer has a two-layer structure of a first layer and a second layer over the first layer, the composition of the second layer is preferably different from that of the first layer. In the case where the oxide semiconductor layer has a three-layer structure of a first layer, a second layer over the first layer, and a third layer over the second layer, the composition of the second layer is preferably different from those of the first and third layers. Note that the composition of the first layer can be the same as that of the third layer. Alternatively, the first and third layers can have different compositions.

For each of the first to third layers, the above-described metal oxide can be used.

For the second layer, indium oxide, In—Zn oxide, In—Zn oxide containing a slight amount of the element M, or the like can be used, for example. Specifically, it is possible to use a metal oxide having an atomic ratio of In:Zn=1:1 or the neighborhood thereof, In:Zn=2:1 or the neighborhood thereof, or In:Zn=4:1 or the neighborhood thereof. For example, it is possible to use a metal oxide having an atomic ratio of In:Ga:Zn=4:0.1:1 or the neighborhood thereof, In:Ga:Zn=2:0.1:1 or the neighborhood thereof, or In:Ga:Zn=1:0.1:1 or the neighborhood thereof. As another example, it is possible to use a metal oxide having an atomic ratio of In:Sn:Zn=4:0.1:1 or the neighborhood thereof, In:Sn:Zn=2:0.1:1 or the neighborhood thereof, or In:Sn:Zn=1:0.1:1 or the neighborhood thereof. Increasing the content percentage of In in the second layer can increase the on-state current and improve the frequency characteristics.

The conduction band minimum of each of the first and third layers is preferably positioned closer to the vacuum level than the conduction band minimum of the second layer is. In other words, the energy of the conduction band minimum of each of the first and third layers is preferably lower than the energy of the conduction band minimum of the second layer. In this case, the second layer is sandwiched between the first layer and the third layer, each of which has a conduction band minimum positioned closer to the vacuum level, and can function mainly as a current path (channel).

When the second layer is interposed between the first layer and the third layer, carriers trapped at and near the interfaces between the second layer and each of the first and third layers can be reduced. Moreover, the channel can be distanced from the surface of a gate insulating layer, so that the influence of surface scattering can be reduced. Accordingly, a buried-channel transistor where a channel is distanced from the interface with an insulating layer can be achieved, whereby the field-effect mobility can be increased. Furthermore, the influence of interface states that may be formed on the back channel side is reduced, so that light deterioration (e.g., light negative bias deterioration) of the transistor can be inhibited and the reliability of the transistor can be increased.

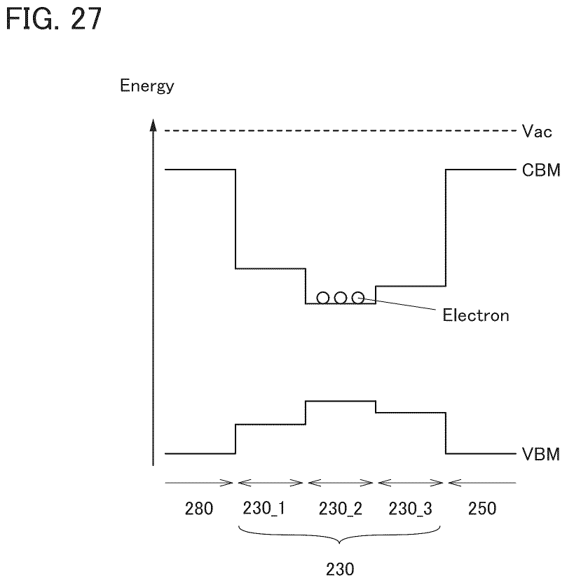

For example, a band diagram of the oxide semiconductor layer 230 including the oxide semiconductor layers 230_1 to 230_3 and its vicinity illustrated in FIG. 21B is as shown in FIG. 27. In FIG. 27, the vertical axis represents energy and the horizontal direction represents the thickness direction of a center portion of a channel formation region. FIG. 27 shows a valence band maximum (VBM) and a conduction band minimum (CBM) of each of the oxide semiconductor layers 230_1 to 230_3 and the insulating layers 280 and 250 in a state where no voltage is applied between the gate and the source. In FIG. 27, a vacuum level Vac is denoted by a dashed line.

Note that energy of the valence band maximum and energy of the conduction band minimum change depending on constituent elements and compositions of the oxide semiconductor layers 230_1 to 230_3 and the insulating layers 280 and 250; thus, the relation between energy levels of the valence band maximum and the relation between energy levels of the conduction band minimum are mainly described with reference to the band diagram in FIG. 27.

With certain constituent elements and compositions of the oxide semiconductor layers 230_1 to 230_3, the oxide semiconductor layer 230_2 is sandwiched between the oxide semiconductor layers 230_1 and 230_3 each of which has a conduction band minimum that is positioned closer to the vacuum level than that of the oxide semiconductor layer 230_2 is, as shown in FIG. 27. This structure achieves a buried channel. That is, in this structure, a path through which a larger amount of current (electrons are shown as carriers in FIG. 27) flows is formed in the oxide semiconductor layer 230_2. Accordingly, the on-state current or reliability can be increased. for example.

In the case where a buried channel is formed using the first to third layers, a metal oxide having a higher Ga content percentage than that for the second layer can be used for the first and third layers, for example. Specifically, for each of the first and third layers, it is possible to use a metal oxide having an atomic ratio of In:Ga:Zn=1:1:1 or the neighborhood thereof, In:Ga:Zn=1:3:2 or the neighborhood thereof, or In:Ga:Zn=1:3:4 or the neighborhood thereof. Alternatively, Ga—Zn oxide or gallium oxide can be used. When the Ga content percentage in the first and third layers is increased, the conduction band minimum of each of the first and third layers is sometimes positioned closer to the vacuum level than the conduction band minimum of the second layer is.

Increasing the Ga content percentage in the first and third layers can improve the barrier property against hydrogen in the first and third layers. Thus, diffusion of hydrogen into the second layer from below the first layer or above the third layer can be inhibited. In addition, increasing the Ga content percentage in the first and third layers enables impurities such as hydrogen and water contained in the oxide semiconductor layer to be reduced by heat applied after formation of the oxide semiconductor layer, for example. Note that when a metal oxide having a lower In content percentage than that for the second layer is used for the first and third layers, a similar effect can be obtained in some cases.

For the third layer, it is preferable to use a metal oxide having an atomic ratio of In:Ga:Zn=1:1:1 or the neighborhood thereof, In:Ga:Zn=1:3:2 or the neighborhood thereof, or In:Ga:Zn=1:3:4 or the neighborhood thereof, for example. In this case, the third layer contains indium and gallium.

Increasing the Ga content percentage in the first and third layers can improve the barrier property against oxygen in the first and third layers. Thus, release of oxygen from the second layer where the channel is formed is inhibited, thereby inhibiting formation of oxygen vacancies in the second layer or an increase in the amount of oxygen vacancies in the second layer. Accordingly, the transistor can have favorable electrical characteristics.

When the Ga content percentage in the first layer is increased, the resistivity of the first layer can be higher than that of the second layer in some cases. In the case where the first layer is provided on the back channel side, providing a layer having high resistivity as the first layer can inhibit a negative shift of the threshold voltage or a decrease in the on-state current. Accordingly, the threshold voltage of the transistor shifts positively, so that the transistor can have normally-off characteristics. In the above manner, the electrical characteristics and reliability of the transistor can be improved.

The band gap of the metal oxide can be evaluated using optical evaluation with a spectrophotometer, spectroscopic ellipsometry, a photoluminescence method, X-ray photoelectron spectroscopy, or an X-ray absorption fine structure (XAFS). Alternatively, these methods can be combined as appropriate to be employed for analysis. The electron affinity or the conduction band minimum can be obtained from a band gap and an ionization potential, which is a difference in energy between the vacuum level and the valence band maximum. The ionization potential can be evaluated by ultraviolet photoelectron spectroscopy (UPS), for example.

Note that a metal oxide having a higher In content percentage than that for the second layer may be used for the first and third layers. Moreover, a metal oxide having a higher In content percentage than that for the second layer may be used for one of the first and third layers, and a metal oxide having a higher Ga content percentage than that for the second layer may be used for the other.

Each of the first to third layers may include a stack of a plurality of layers each having the above-described composition. For example, the first layer may have a structure where a metal oxide with a high In content percentage is stacked over a metal oxide with a high Ga content percentage. As another example, the third layer may have a structure where a metal oxide with a high Ga content percentage is stacked over a metal oxide with a high In content percentage.

### [Formation Method of Oxide Semiconductor Layer]

The oxide semiconductor layer of one embodiment of the present invention can be formed by a sputtering method, a CVD method, a vacuum evaporation method, an MBE method, a PLD method, an ALD method, or the like.

The oxide semiconductor layer of one embodiment of the present invention can be formed by forming metal oxides using two kinds of formation methods. For example, the oxide semiconductor layer of one embodiment of the present invention can be formed by forming metal oxides using a first formation method and a second formation method.

The oxide semiconductor layer of one embodiment of the present invention can have a two-layer structure of a first layer and a second layer over the first layer. In the case where the oxide semiconductor layer has a two-layer structure, the oxide semiconductor layer can be formed in the following manner: the first layer is formed over a formation surface by a first formation method, and then the second layer is formed over the first layer by a second formation method.

As the first formation method, a formation method that causes less damage to the formation surface than the second formation method is preferably used. Accordingly, formation of a mixed layer at the interface between the oxide semiconductor layer and a layer serving as the formation surface of the oxide semiconductor layer can be inhibited. Moreover, entry of impurities such as silicon into the second layer formed over the first layer can be inhibited, so that the crystallinity of the oxide semiconductor layer can be further increased in some cases.

Examples of the first formation method include an ALD method, a CVD method, and an MBE method. Examples of a CVD method include a PECVD method, a thermal CVD method, a photo CVD method, and an MOCVD method. An MBE method is a film formation method by which a thin film having a crystal structure reflecting a crystal system of a substrate is grown, and is one of film formation methods that cause less damage to a formation surface. A wet method can be used as the first formation method. A wet method is one of film formation methods that cause less damage to a formation surface. An example of a wet method is a spray coating method.

As the second formation method, a method by which a metal oxide having crystallinity can be formed is preferably used. The metal oxide formed at this time particularly preferably has the CAAC structure. Examples of the second formation method include a sputtering method and a PLD method. A metal oxide formed by a sputtering method is likely to have crystallinity; thus, a sputtering method is suitable as the second formation method.

When a metal oxide is formed over the formation surface by the second formation method, damage to the formation surface might cause alloying of a component contained in the metal oxide with a component contained in the layer serving as the formation surface. When alloying occurs, a mixed layer is sometimes formed at the interface between the metal oxide and the layer serving as the formation surface. The mixed layer can also be referred to as an alloyed region. The formation of the mixed layer can also be referred to as alloying.

For example, in the case where a sputtering method is used as the second formation method, a mixed layer is sometimes formed owing to particles ejected from a target or the like (also referred to as sputtered particles) or energy applied to the substrate side by sputtered particles or the like, for example. Specifically, in the case where a metal oxide is formed over an insulating layer containing silicon, e.g., a silicon oxide film as the formation surface by the second formation method, silicon might enter the metal oxide. There is a concern that the entry of impurities such as silicon into the metal oxide may hinder crystallization of the metal oxide. When an oxide semiconductor layer into which impurities enter is used for a transistor, the initial characteristics or reliability of the transistor may be adversely affected. It is difficult to increase the crystallinity of an alloyed region even when heat treatment described later is performed.

Accordingly, forming the metal oxide by the first formation method before forming the metal oxide by the second formation method as described above can inhibit entry of impurities into the oxide semiconductor layer. In addition, alloying with the layer serving as the formation surface can be inhibited. Thus, the initial characteristics and reliability of the transistor can be improved. Moreover, the crystallinity of the oxide semiconductor layer can be further increased.

Note that a mixed layer is sometimes formed at the interface between the first layer and the second layer. The mixed layer includes a component contained in the first layer and a component contained in the second layer. For example, in the case where gallium oxide is used for the first layer and a metal oxide containing indium is used for the second layer, the mixed layer includes gallium and indium. For example, in the case where the indium content percentage in the second layer is higher than that in the first layer, the indium content percentage in the mixed layer is higher than or equal to that in the first layer and lower than or equal to that in the second layer.

An ALD method is suitable as the first formation method because damage to the formation surface can be inhibited as compared with a sputtering method. An ALD method is a film formation method that gives higher coverage than a sputtering method, and the use of an ALD method as the formation method of the first layer enables the oxide semiconductor layer to adequately cover a component thereunder. Thus, the oxide semiconductor layer can suitably cover a step, an opening portion, a groove portion, or the like having a high aspect ratio.

For the first layer, a metal oxide having a microcrystalline structure or an amorphous structure that has lower crystallinity than the CAAC structure is formed in some cases, for example. Forming the second layer having high crystallinity on the first layer having low crystallinity or performing heat treatment after formation of the second layer can increase the crystallinity of the first layer with the second layer as a nucleus in some cases. Accordingly, in some cases, the crystallinity can be increased in the whole oxide semiconductor layer including the vicinity of the interface with the formation surface.

The layer serving as the formation surface is an insulating film such as a silicon oxide film, a silicon oxynitride film, a silicon nitride film, a silicon nitride oxide film, an aluminum oxide film, or a hafnium oxide film, for example. Note that the layer serving as the formation surface may be a conductive film such as a titanium nitride film, a tungsten film, or an ITSO film in some transistor structures. The layer serving as the formation surface does not necessarily have crystallinity. In the case of having crystallinity, the layer serving as the formation surface may have a crystal structure with low lattice matching with the metal oxide included in the oxide semiconductor layer.

The first layer is preferably formed by an ALD method. Here, a method for forming In-M-Zn oxide for the first layer by an ALD method is described.

First, a source gas that contains a precursor containing indium is introduced into a reaction chamber (also referred to as a chamber) so that the precursor is adsorbed on the formation surface. Then, an oxidizer is introduced as a reactant into the reaction chamber to react with the adsorbed precursor, and components other than indium are released while indium is adsorbed on the substrate, whereby a layer in which indium and oxygen are bonded to each other is formed.

Subsequently, a source gas that contains a precursor containing the element M is introduced into the reaction chamber, and the precursor is adsorbed on the layer in which indium and oxygen are bonded to each other. Then, an oxidizer is introduced as a reactant into the reaction chamber to react with the adsorbed precursor, and components other than the element M are released while the element M is adsorbed on the substrate, whereby a layer in which the element M and oxygen are bonded to each other is formed.

Next, a source gas that contains a precursor containing zinc is introduced into the reaction chamber, and the precursor is adsorbed on the layer in which the element M and oxygen are bonded to each other. Then, an oxidizer is introduced as a reactant into the reaction chamber to react with the adsorbed precursor, and components other than zinc are released while zinc is adsorbed on the substrate, whereby a layer in which zinc and oxygen are bonded to each other is formed.

By repeating the above steps, In-M-Zn oxide can be formed by an ALD method as the oxide semiconductor layer over the layer serving as the formation surface.

When the oxide semiconductor layer is formed by an ALD method, ozone (O₃), oxygen (O₂), water (H₂O), or the like can be used as the oxidizer. The use of an oxidizer without hydrogen, such as ozone (O₃) or oxygen (O₂), can reduce the amount of hydrogen entering the oxide semiconductor layer.

It is preferable that after the precursor is adsorbed in the above steps, introduction of the source gas containing the precursor be stopped and the reaction chamber be purged so that an excess precursor, a reaction product, and the like are removed from the reaction chamber. Moreover, it is preferable that after the adsorbed precursor reacts with the oxidizer in the above steps, introduction of the oxidizer be stopped and the reaction chamber be purged so that an excess reactant, a reaction product, and the like are removed from the reaction chamber.

In the description of this specification and the like, in the case of using ozone, oxygen, and water as a reactant or an oxidizer, they include not only those in gas or molecular states but also those in plasma, radical, and ion states, unless otherwise specified.

The second layer is preferably formed by a sputtering method.

As a target used in a sputtering method, In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen in the oxide film to be formed.

A higher proportion of the flow rate of an oxygen gas to the flow rate of the whole film formation gas (also referred to as oxygen flow rate ratio) used at the time of forming the metal oxide enables the formed metal oxide to have higher crystallinity in some cases.

When the metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess metal oxide in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the formation of the metal oxide by a sputtering method, substrate heating is preferably performed. Increasing the substrate temperature (stage temperature) at the time of forming the metal oxide enables a metal oxide with high crystallinity to be formed in some cases. In the formation of the metal oxide by a sputtering method, the substrate heating temperature is preferably higher than or equal to 100° C. and lower than or equal to 400° C., further preferably higher than or equal to 200° C. and lower than or equal to 300° C., for example.

With the above-described formation method, the thickness of the mixed layer formed at the interface between the layer serving as the formation surface and the metal oxide can be reduced or the thickness of the alloyed region formed at the interface between the layer serving as the formation surface and the metal oxide can be thin enough to be unobserved. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm.

Note that the thickness of the alloyed region can sometimes be calculated by performing SIMS or composition line analysis by energy dispersive X-ray spectroscopy (EDX) on the region and its vicinity.

For example, EDX line analysis is performed on the alloyed region and its vicinity with the direction perpendicular to the formation surface of the first layer regarded as the depth direction. Next, in the profile of quantitative values of the elements in the depth direction, which is obtained from the analysis, the depth at which the quantitative value of a metal that is the main component of the first layer and is not the main component of the layer serving as the formation surface (In in the case where the first layer contains In) becomes half is defined as the depth (position) of the interface between the region and the first layer. The depth at which the quantitative value of an element (e.g., Si) that is a main component of the layer serving as the formation surface and that is not a main component of the first layer becomes half is defined as the depth (position) of the interface between the region and the layer serving as the formation surface. In the above manner, the thickness of the alloyed region can be calculated.

When the thickness of the alloyed region in the oxide semiconductor layer of one embodiment of the present invention is observed by EDX analysis, the thickness is greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm, for example.

For example, when SIMS analysis is performed on the oxide semiconductor layer formed over a silicon oxide film serving as the formation surface, the depth at which the silicon concentration is 50% of the maximum value of the silicon concentration in the silicon oxide film is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t. The thickness t is preferably less than or equal to 3 nm, further preferably less than or equal to 2 nm.

When the thickness of the alloyed region is reduced, the thickness t can be a value within the above range.

Note that when the thickness of the alloyed region is reduced, the CAAC structure can be formed in the vicinity of the formation surface. Here, the vicinity of the formation surface refers to, for example, a region ranging from the formation surface of the oxide semiconductor layer to greater than 0 nm and less than or equal to 3 nm, preferably greater than 0 nm and less than or equal to 2 nm, further preferably greater than or equal to 1 nm and less than or equal to 2 nm in the direction substantially perpendicular to the formation surface.

Note that the CAAC structure in the vicinity of the formation surface can be confirmed in TEM observation in some cases. For example, in high-resolution TEM cross-sectional observation of the oxide semiconductor layer, bright spots arranged in a layered manner in the direction parallel to the formation surface are observed in the vicinity of the formation surface.

The oxide semiconductor layer of one embodiment of the present invention can have a three-layer structure of a first layer, a second layer over the first layer, and a third layer over the second layer.

In the case where the oxide semiconductor layer has a three-layer structure, the oxide semiconductor layer can be formed in the following manner: the first layer is formed over a formation surface by a first formation method, the second layer is formed by a second formation method, and then the third layer is formed by the first formation method.

Even when the first and third layers in the oxide semiconductor layer have a composition that is less likely to achieve the CAAC structure in the formation of a single layer, crystal growth occurring with the second layer as a nucleus enables the whole oxide semiconductor layer including the first and third layers to have the CAAC structure. Alternatively, the oxide semiconductor layer can have the CAAC structure in a region that includes the second layer and at least part of each of the first and third layers.

In particular, even with a composition where the first and third layers have a high In content percentage, crystallinity suitable for a semiconductor layer of a transistor can be obtained. The oxide semiconductor layer of one embodiment of the present invention achieves both high on-state characteristics and high reliability of the transistor owing respectively to the increase in the In content percentage and achievement of the CAAC structure with high crystallinity.

The first and third layers may employ a metal oxide having the same composition as the second layer. By using the same composition, the oxide semiconductor layer may easily have the CAAC structure after heat treatment.

Since the second layer has high crystallinity, the crystal growth of the third layer can be achieved with the use of the crystal of the second layer as a nucleus or a seed. Thus, the third layer can be crystallized even when a film formation method that easily gives crystallinity is not employed as the formation method of the third layer. Here, for example, when a film formation method that gives higher coverage than that of the second layer is used to form the third layer, the whole oxide semiconductor layer can have both high crystallinity and high coverage.

When influence of the formation surface on the second layer is reduced by provision of the first layer, the crystallinity of the second layer is increased to an extremely high level. Thus, the third layer whose crystal is grown with the second layer as a nucleus or a seed is also expected to have extremely excellent crystallinity.

Note that in the case where an oxide semiconductor layer is used as a semiconductor layer of a transistor, the third layer, which is the uppermost layer of the oxide semiconductor layer, is in contact with a gate insulating layer in some cases. Increasing the crystallinity of the layer in contact with the gate insulating layer can increase the carrier mobility in an on state of the transistor.

The crystallinity of the first and third layers is increased with the use of the second layer having high crystallinity as a nucleus or a seed. Specifically, the crystallinity of the first layer may be increased by heat treatment in formation of the second layer or after formation of the third layer. The crystallinity of the third layer may be increased in formation of the third layer or by heat treatment after formation of the third layer. Note that the above heat treatments have a function of assisting in increasing the crystallinity.

As described above, in the method for forming the oxide semiconductor layer of one embodiment of the present invention, with the use of the second layer including a metal oxide with high crystallinity, (i.e., a c-axis-aligned crystal or CAAC), as a nucleus or a seed, the crystallinity of the metal oxides above and below the second layer (here, the first and third layers) can be increased. Accordingly, the crystallinity of the whole oxide semiconductor layer can be increased. In other words, the second layer serves as a nucleus or a seed to cause solid-phase growth of the metal oxides above and below the second layer, so that the oxide semiconductor layer with high crystallinity can be formed. An oxide semiconductor layer formed by such a formation method, here, a CAAC film, can be referred to as an axial growth CAAC (AG CAAC).

A region having the CAAC structure preferably spreads in the whole layer of the oxide semiconductor layer. Crystals in the region having the CAAC structure in the first layer are connected to crystals in the region having the CAAC structure in the second layer. Crystals in the region having the CAAC structure in the third layer are connected to crystals in the region having the CAAC structure in the second layer. Accordingly, a boundary between the first layer and the second layer is not observed in some cases. In addition, a boundary between the second layer and the third layer is not observed in some cases. The oxide semiconductor layer may be expressed as one layer where interfaces are not clearly observed. The oxide semiconductor layer may be expressed as a single layer.

In the region having the CAAC structure in each of the first to third layers, bright spots arranged parallel or substantially parallel to the formation surface are observed in a high-resolution cross-sectional TEM image, for example. The c-axis of the CAAC structure included in each of the first to third layers is preferably parallel or substantially parallel to the normal direction of the formation surface or the surface of the oxide semiconductor layer.

Part of the first layer or the third layer is not crystallized in some cases.

In the case where the oxide semiconductor layer has a three-layer structure, the oxide semiconductor layer can also be formed in the following manner: a first layer is formed over a formation surface by a first formation method, a second layer is formed by the first formation method, and then a third layer is formed by a second formation method.

As described above, when a metal oxide with a high In content percentage is used for a transistor, the field-effect mobility of the transistor can be increased. On the other hand, a metal oxide with a high In content percentage tends to have a cubic crystal structure. Thus, when a metal oxide with a high In content percentage is used for the second layer in contact with the third layer, crystals reflecting the orientation of crystals included in the third layer can be formed.

It is preferable that the crystals included in the third layer and the crystals included in the second layer have a small lattice mismatch. Thus, crystals reflecting the orientation of the crystals included in the third layer can be formed in the second layer. At this time, for example, in high-resolution cross-sectional TEM observation of the oxide semiconductor layer, bright spots arranged in a layered manner in the direction parallel to the formation surface are observed in the second layer.

There is no particular limitation on the crystal structure of the second layer as long as the crystals included in the third layer and the crystals included in the second layer have a small lattice mismatch. The crystal structure of the second layer may be any of a cubic crystal structure, a tetragonal crystal structure, an orthorhombic crystal structure, a hexagonal crystal structure, a monoclinic crystal structure, and a trigonal crystal structure.

In the above structure, typically, the first layer can be a layer including a metal oxide having an atomic ratio of In:Ga:Zn=1:3:2 or the neighborhood thereof or a layer including gallium oxide, the second layer can be a layer including a metal oxide containing a slight amount of the element M or a layer including indium oxide, and the third layer can be a layer including a metal oxide having an atomic ratio of In:Ga:Zn=1:1:1 or the neighborhood thereof. In this case, the first layer contains gallium. In the case where the first layer includes a metal oxide having an atomic ratio of In:Ga:Zn=1:3:2 or the neighborhood thereof, the indium content percentage is lower than the gallium content percentage in the first layer. The indium content percentage in the second layer is higher than the indium content percentage in the third layer.

In the case where the first layer and the second layer are formed by the first formation method, the first layer and the second layer are preferably formed successively without exposure to the air. Forming the first layer and the second layer successively without exposure to the air can increase the productivity. Furthermore, impurities (typically, moisture or the like) taken into the interface between the first layer and the second layer and the vicinity thereof can be reduced.

One or more of the first to third layers may include a stack of a plurality of layers with different compositions. For example, the first layer may be formed in the following manner: a layer including a metal oxide with a high Ga content percentage is formed by the first formation method, and then a layer including a metal oxide with a higher In content percentage than the layer is formed by the first formation method.

After formation of the layers by the first formation method, microwave plasma treatment is preferably performed.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the oxide semiconductor layer 230 can be reduced. Specific examples of impurities include hydrogen and carbon. Although the microwave plasma treatment in an oxygen-containing atmosphere is performed on the metal oxide in the above example, one embodiment of the present invention is not limited thereto. For example, microwave plasma treatment in an oxygen-containing atmosphere may be performed on an insulating film, specifically a silicon oxide film, which is provided in the vicinity of the metal oxide. Furthermore, the crystallinity of the oxide semiconductor layer is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. For example, the substrate heating temperature is preferably higher than or equal to room temperature and lower than or equal to 500° C., further preferably higher than or equal to 100° C. and lower than or equal to 450° C., still further preferably higher than or equal to 200° C. and lower than or equal to 450° C., yet still further preferably higher than or equal to 300° C. and lower than or equal to 450° C., yet still further preferably higher than or equal to 400° C. and lower than or equal to 450° C.

The microwave plasma treatment can be performed using an oxygen gas and an argon gas, for example. In the microwave plasma treatment using an oxygen gas and an argon gas, oxygen radicals can be mainly in three states: triplet oxygen (O(³Pⱼ)), singlet oxygen (O(¹D₂)), and an oxygen ion (O₂⁺). Note that the oxygen ion effectively acts for reducing the hydrogen concentration in an oxide film by the microwave plasma treatment. The amount of oxygen radicals in each state changes depending on the oxygen flow rate ratio or a pressure in the microwave plasma treatment. For example, the amount of oxygen ions tends to increase under a condition with a low oxygen flow rate ratio and a low pressure. Meanwhile, an extremely low oxygen flow rate ratio or pressure might destabilize the control of the oxygen flow rate, thereby making stable discharging difficult or causing etching of an oxide film, for example. Therefore, for example, the oxygen flow rate ratio (O₂/(O₂+Ar)) in the microwave plasma treatment is preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

As the microwave plasma treatment time is shorter, oxidation of the conductive layer 220, the conductive layer 240, or the like can be inhibited more. In addition, the productivity is improved. In view of this, the microwave plasma treatment time is preferably longer than or equal to 1 minute and shorter than or equal to 60 minutes, further preferably longer than or equal to 1 minute and shorter than or equal to 30 minutes, still further preferably longer than or equal to 1 minute and shorter than or equal to 10 minutes.

The microwave plasma treatment in an oxygen-containing atmosphere can convert an oxygen gas into plasma by using a high-frequency wave such as a microwave or an RF, and apply, to the oxide semiconductor layer, oxygen radicals that are generated by conversion of the oxygen gas into plasma. By the effects of plasma, a microwave, oxygen radicals, and the like, V_{O}H in the oxide semiconductor layer can be divided into an oxygen vacancy and hydrogen, and hydrogen which is an impurity can be removed from the oxide semiconductor layer. In this manner, V_{O}H contained in the oxide semiconductor layer can be reduced. At this time, carbon bonded to oxygen, hydrogen, or the like can also be removed in some cases. Performing the microwave plasma treatment in such a manner can reduce impurities such as carbon and hydrogen. Supplying the oxygen radicals to oxygen vacancies formed in the oxide semiconductor layer can further reduce oxygen vacancies in the oxide semiconductor layer.

The microwave plasma treatment can increase the crystallinity of the layers formed by the first formation method. Here, the principles of improving the crystallinity of the oxide semiconductor layer by the microwave plasma treatment will be described. First, active species excited by a microwave, such as oxygen radicals, reach the surface of the oxide semiconductor layer, and a substitution reaction between the active species and oxygen in the oxide semiconductor layer occurs. At this time, a nucleus or a seed is formed. In addition, lateral growth of the nucleus or the seed is caused. Note that it is preferable that the active species excited by the microwave contain oxygen (typically, oxygen ions) that is likely to be adsorbed onto a side surface of the nucleus or the seed, in which case the lateral growth is promoted. The microwave plasma treatment causes formation of a nucleus or a seed and lateral growth of the nucleus or the seed, so that the crystallinity of the oxide semiconductor layer is improved.

Meanwhile, when part of oxygen that is present in the oxide semiconductor layer before the microwave plasma treatment reacts with hydrogen in the oxide semiconductor layer, i.e., a reaction of “2H+O→H₂O↑” occurs, the hydrogen can be removed as H₂O (i.e., dehydration or dehydrogenation can be achieved). H₂O is a limiting factor in improving crystallinity and is thus preferably removed from the oxide semiconductor layer. Hydrogen in the oxide semiconductor layer is removed as H₂O to reduce the hydrogen concentration in the oxide semiconductor layer, whereby an improvement in crystallinity can be promoted. When the temperature of the microwave plasma treatment is increased, the hydrogen concentration in the oxide semiconductor layer can be further reduced.

Note that the microwave plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example.

Note that the crystallinity can also be improved by performing plasma treatment using an oxygen gas, instead of the microwave plasma treatment.

The increase in the crystallinity of the layer formed by the first formation method can further increase the crystallinity of a layer formed over the layer. Thus, the crystallinity of the whole oxide semiconductor layer can be increased.

Oxygen supplied to the oxide semiconductor layer is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Oxygen injected into the oxide semiconductor layer preferably has one or more of the above forms. An oxygen radical is particularly preferable.

Heat treatment is preferably performed after formation of the oxide semiconductor layer. By performing the heat treatment, the crystallinity of the oxide semiconductor layer can be increased. The heat treatment here is not limited to treatment with application of heat. For example, heat applied during the formation process may be regarded as the heat treatment.

The heat treatment temperature can be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be 400° C.±25° C. (higher than or equal to 375° C. and lower than or equal to 425° C.). The treatment time can be shorter than or equal to 10 hours and can be, for example, longer than or equal to 1 minute and shorter than or equal to 5 hours, or longer than or equal to 1 minute and shorter than or equal to 2 hours. In the case of using an RTA apparatus, the treatment time can be longer than or equal to 1 second and shorter than or equal to 5 minutes, for example. By the heat treatment, the third layer formed by the first formation method is expected to fill an atomic-level space between crystal parts of the CAAC structure of the second layer formed by the second formation method.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

By the heat treatment step, the crystallinity of the region having the CAAC structure may be increased in the third layer formed by the first formation method. In the case where the region is formed only in the lower portion of the third layer after the deposition by an ALD method, the region may be extended upward by the heat treatment step. That is, by the heat treatment, the region having the CAAC structure may be formed in the whole third layer.

By the heat treatment step, at least part of the first layer or the second layer formed by the first formation method preferably has the CAAC structure. The CAAC structure is expected to be easily generated with a mixed layer that is formed in the first layer or the second layer and serves as a nucleus or a seed at the time of forming the layer by the second formation method. The CAAC region in the first layer or the second layer is preferably large, and the CAAC region preferably extends to the vicinity of the formation surface.

Since the CAAC region extends from the upper portion to the lower portion of the first layer or the second layer, the CAAC region can extend to the vicinity of the layer serving as the formation surface, regardless of the material and crystallinity of the layer serving as the formation surface. For example, even when the layer serving as the formation surface has an amorphous structure, the crystallinity of the first layer or the second layer can be increased. Thus, the method for forming the oxide semiconductor layer of one embodiment of the present invention is suitable particularly for the case where the layer serving as the formation surface has an amorphous structure.

When one or both of the microwave plasma treatment and the heat treatment are performed as described above, the crystallinity of the whole oxide semiconductor layer can be increased. Moreover, impurities in the oxide semiconductor layer can be reduced. Crystal growth of the oxide semiconductor layer with a low impurity concentration can further make crystallinity higher.

Increasing the crystallinity of the oxide semiconductor layer can inhibit an increase in the electric resistance of the semiconductor layer of a transistor including the oxide semiconductor layer or improve the initial characteristics (in particular, the on-state current) of the transistor, and thus a transistor suitable for high-speed operation can be expected. In addition, the reliability and on-state current of the transistor can be increased.

Note that one or both of the microwave plasma treatment and the heat treatment may be performed directly on the oxide semiconductor layer or performed on an insulating film or the like formed over the oxide semiconductor layer.

Before formation of the first layer or after formation of the first layer or the second layer by the first formation method, treatment for supplying oxygen to the first layer or the second layer may be performed. Accordingly, oxygen can be supplied to the oxide semiconductor layer by heat applied after this treatment, for example.

Examples of the treatment for supplying oxygen include heat treatment in an oxygen-containing atmosphere and plasma treatment (including microwave plasma treatment) in an oxygen-containing atmosphere. Moreover, an oxide film (preferably a metal oxide film) may be formed in an oxygen-containing atmosphere by a sputtering method, thereby supplying oxygen to the first layer or the second layer formed by the first formation method. The formed oxide film may be removed immediately or left as it is. In the case where the formed oxide film is left as it is, the oxide film can be used as the layer provided over the first layer or the second layer (i.e., used as the second layer or the third layer). Note that an oxygen-containing atmosphere includes not only an oxygen gas (O₂) but also a gas of an oxygen-containing compound such as ozone (O₃) or dinitrogen monoxide (N₂O). The substrate temperature in the plasma treatment is higher than or equal to room temperature (25° C.) and lower than or equal to 450° C.

The oxide semiconductor layer of one embodiment of the present invention has high crystallinity throughout the whole layer. Thus, in the oxide semiconductor layer, boundaries between the stacked first to third layers are not observed in some cases. The boundaries between the stacked layers may be difficult to observe particularly after heat treatment is performed. Whether the boundaries between the stacked layers are present can be checked in cross-sectional observation with a TEM or a scanning transmission electron microscope (STEM), for example.

The oxide semiconductor layer that is formed by the above-described two kinds of formation methods and has the CAAC structure sometimes has one or more of a higher dielectric constant, a higher film density, and higher film hardness than an oxide semiconductor layer that is formed by one kind of formation method and has the CAAC structure.

When the oxide semiconductor layer that is formed by the above-described two kinds of formation methods and has the CAAC structure is used for a channel formation region of a transistor, the transistor can have excellent characteristics (e.g., a high on-state current, high field-effect mobility, a low S value, high frequency characteristics (also referred to as f characteristics), or high reliability).

The oxide semiconductor layer of one embodiment of the present invention can sometimes be formed by using the first formation method and one or both of microwave plasma treatment and heat treatment. In other words, the oxide semiconductor layer of one embodiment of the present invention can be formed without using the second formation method in some cases. For example, after the first layer is formed by the first formation method, one or both of microwave plasma treatment and heat treatment are performed, whereby the crystallinity of the first layer can be increased. Thus, the crystallinity of the second layer that is formed over the first layer by the first formation method can be increased using the first layer as a nucleus or a seed. When one or both of microwave plasma treatment and heat treatment are performed after formation of the second layer, the crystallinity of the oxide semiconductor layer can be increased. Accordingly, the CAAC structure can be formed in the oxide semiconductor layer.

As described above, even in the formation method not using the second formation method, the use of the first layer formed by the first formation method as a nucleus or a seed enables solid-phase growth of the layer above the first layer, whereby an oxide semiconductor with high crystallinity can be formed. An oxide semiconductor formed by such a formation method can also be referred to as an AG CAAC.

Note that in the case where the oxide semiconductor layer has a stacked-layer structure of two or more layers, the oxide semiconductor layer can also be formed by forming metal oxides by one kind of formation method. In the case where the oxide semiconductor layer has a two-layer structure of a first layer and a second layer over the first layer, the oxide semiconductor layer can be formed by forming the first layer and the second layer in this order by a sputtering method, for example. A sputtering method, which achieves a higher deposition rate than an ALD method, can increase the productivity. As another example, in the case where the oxide semiconductor layer has a three-layer structure of a first layer, a second layer over the first layer, and a third layer over the second layer, the first to third layers can be formed by a sputtering method. Furthermore, some of the first to third layers can be formed by an ALD method. For example, one or both of the second layer and the third layer may be formed by an ALD method.

### [Oxide Semiconductor Layer of Transistor]

The oxide semiconductor layer of this embodiment can be used as a semiconductor layer of a transistor.

The oxide semiconductor layer of this embodiment can be used as the oxide semiconductor layer 230 or the like included in the transistors described in Embodiment 1. The layer serving as the formation surface corresponds to the insulating layer 280 or the like described in Embodiment 1. For example, the first layer can be used as the oxide semiconductor layer 230_1, the second layer can be used as the oxide semiconductor layer 230_2, and the third layer can be used as the oxide semiconductor layer 230_3.

The oxide semiconductor layer of this embodiment preferably has the CAAC structure. In the oxide semiconductor layer having the CAAC structure, metal atoms are arranged in a crystal part in a layered manner in the direction parallel or substantially parallel to the formation surface.

The oxide semiconductor layer having the CAAC structure is presumed to exhibit current anisotropy. For example, in an IGZO crystal, current flows more easily in the a-axis direction than in the c-axis direction. That is, in the oxide semiconductor layer having the CAAC structure, current is presumed to flow easily in the lateral direction rather than in the vertical direction.

In the oxide semiconductor layer 230 of the semiconductor device described in the foregoing embodiment, metal atoms are arranged in a layered manner in the direction parallel or substantially parallel to the formation surface. This can also be expressed that “the a-b plane of the CAAC structure is provided to be parallel or substantially parallel to the formation surface”. With such a structure, the a-b plane of the CAAC structure can be provided along a current flow direction in a channel of the transistor. Accordingly, the transistor can have a high on-state current.

In the case where the oxide semiconductor layer of this embodiment is used as a semiconductor layer of a transistor, the thickness of the oxide semiconductor layer is preferably greater than or equal to 3 nm and less than or equal to 200 nm, further preferably greater than or equal to 3 nm and less than or equal to 100 nm, further preferably greater than or equal to 5 nm and less than or equal to 100 nm, still further preferably greater than or equal to 10 nm and less than or equal to 100 nm, still further preferably greater than or equal to 10 nm and less than or equal to 70 nm, yet further preferably greater than or equal to 15 nm and less than or equal to 70 nm, yet further preferably greater than or equal to 15 nm and less than or equal to 50 nm, yet still further preferably greater than or equal to 20 nm and less than or equal to 50 nm, for example. In a transistor used for a further downsized semiconductor device, the thickness of the oxide semiconductor layer is preferably greater than or equal to 1 nm and less than or equal to 20 nm, further preferably greater than or equal to 3 nm and less than or equal to 15 nm, still further preferably greater than or equal to 5 nm and less than or equal to 12 nm, yet further preferably greater than or equal to 5 nm and less than or equal to 10 nm. The average thickness of the oxide semiconductor layer in a channel formation region of the transistor is particularly preferably greater than or equal to 2 nm and less than or equal to 15 nm, for example.

The thickness of the first layer is preferably greater than or equal to 0.5 nm and less than or equal to 50 nm, further preferably greater than or equal to 0.5 nm and less than or equal to 30 nm, further preferably greater than or equal to 0.5 nm and less than or equal to 20 nm, still further preferably greater than or equal to 1 nm and less than or equal to 50 nm, still further preferably greater than or equal to 1 nm and less than or equal to 30 nm, yet further preferably greater than or equal to 1 nm and less than or equal to 20 nm, yet still further preferably greater than or equal to 2 nm and less than or equal to 20 nm, for example. The thickness of the first layer is further preferably greater than or equal to 0.5 nm and less than or equal to 3.0 nm.

The first layer preferably includes a region with a thickness greater than or equal to 0.1 nm and less than or equal to 3 nm, and further preferably includes a region with a thickness greater than or equal to 0.1 nm and less than or equal to 2 nm. Alternatively, the first layer preferably includes a region with a thickness greater than or equal to 0.5 nm and less than or equal to 3 nm, and further preferably includes a region with a thickness greater than or equal to 0.5 nm and less than or equal to 2 nm.

The thickness of the second layer is preferably less than or equal to 200 nm, for example. In the case where the second layer is in the form of layer, the thickness of the second layer is preferably greater than or equal to 1 nm and less than or equal to 200 nm, further preferably greater than or equal to 1 nm and less than or equal to 100 nm, still further preferably greater than or equal to 2 nm and less than or equal to 100 nm, for example.

Alternatively, in some cases, the second layer is not in the form of layer but is an aggregate of island-shaped regions as long as the second layer can function as a crystal nucleus. In such a case, the island-shaped regions of the second layer are present discretely, for example.

The description of the thickness of the first layer can be referred to for the preferred range of the thickness of the third layer.

### [Impurities in Oxide Semiconductor Layer]

The influence of impurities in the oxide semiconductor layer is described here.

As has been described in the foregoing embodiment, in a transistor using the oxide semiconductor for a semiconductor layer, the electrical characteristics may vary easily and the reliability may be decreased when oxygen vacancies (V_{O}) and impurities are present in a channel formation region in the oxide semiconductor layer. Accordingly, in order to obtain stable electrical characteristics of the OS transistor, reducing the impurity concentration in the oxide semiconductor layer is effective. In order to reduce the impurity concentration in the oxide semiconductor layer, it is preferable that the impurity concentration in an adjacent film be also reduced. Examples of impurities include hydrogen, carbon, and nitrogen.

When an oxide semiconductor contains silicon or carbon, which is a Group 14 element, defect states are formed in the oxide semiconductor. Accordingly, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. Alternatively, when the oxide semiconductor contains nitrogen, a trap state is sometimes formed. This may make the electrical characteristics of the transistor unstable. Accordingly, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor that contains hydrogen tends to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

This embodiment can be combined with any of the other embodiments as appropriate. In this specification, in the case where a plurality of structure examples are shown in one embodiment, the structure examples can be combined as appropriate.

### Embodiment 3

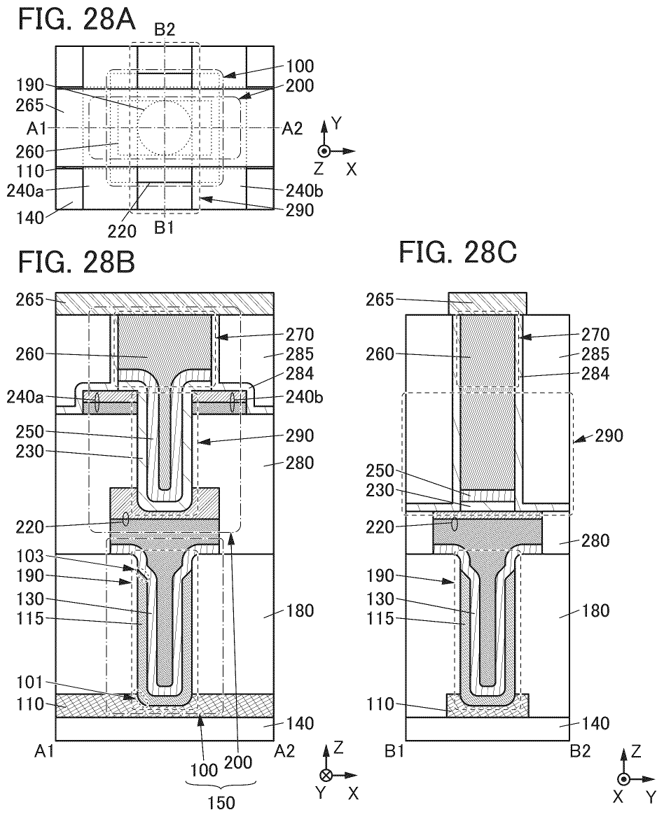

In this embodiment, memory devices of embodiments of the present invention will be described with reference to FIGS. 28A to 28C, FIGS. 29A to 29D, FIG. 30, FIGS. 31A and 31B, FIGS. 32A to 32C, FIG. 33, FIGS. 34A and 34B, FIG. 35, FIG. 36, FIG. 37, and FIG. 38. The memory device of one embodiment of the present invention includes a memory cell. The memory cell includes a transistor and a capacitor.

### Structure Example 1 of Memory Device

A structure of a memory device including a transistor and a capacitor is described with reference to FIGS. 28A to 28C, FIGS. 29A to 29D, and FIG. 30. FIG. 28A is a plan view of a memory device including a memory cell. FIG. 28B is a cross-sectional view taken along dashed-dotted line A1-A2 in FIG. 28A, and FIG. 28C is a cross-sectional view taken along dashed-dotted line A3-A4 in FIG. 28A.

The memory device illustrated in FIGS. 28A to 28C includes an insulating layer 140 over a substrate (not illustrated); a conductive layer 110 over the insulating layer 140; a memory cell 150 over the conductive layer 110; an insulating layer 180 over the conductive layer 110; the insulating layer 280 over the insulating layer 180; the insulating layer 284 over the insulating layer 280; the insulating layer 285 over the insulating layer 284; and the conductive layer 265 over the insulating layer 284, the insulating layer 285, and the memory cell 150. The insulating layer 140, the insulating layer 180, the insulating layer 280, the insulating layer 284, and the insulating layer 285 function as interlayer films. The conductive layer 110 functions as a wiring.

The memory cell 150 includes a capacitor 100 over the conductive layer 110 and the transistor 200 over the capacitor 100.

The capacitor 100 includes a conductive layer 115 over the conductive layer 110, an insulating layer 130 over the conductive layer 115, and the conductive layer 220 over the insulating layer 130.

In the capacitor 100, the conductive layer 220 functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (MIM) capacitor.

As illustrated in FIGS. 28B and 28C, an opening portion 190 reaching the conductive layer 110 is provided in the insulating layer 180. The conductive layer 115 is placed in the opening portion 190. Note that in the opening portion 190, the conductive layer 115 includes a region in contact with the top surface of the conductive layer 110 and a region in contact with the side surface of the insulating layer 180. The insulating layer 130 is placed to be positioned in the opening portion 190. The conductive layer 220 is placed to be positioned in the opening portion 190 at least partly. Note that the conductive layer 220 is preferably provided to fill the opening portion 190 as illustrated in FIG. 28B. Note that the films provided in the opening portion 190 are preferably formed by an ALD method. Thus, the coverage with the films can be improved. For example, the conductive layer 115, the insulating layer 130, and the conductive layer 220 are preferably formed by an ALD method.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This also allows further miniaturization or high integration of the memory device.

As illustrated in FIG. 28A, the opening portion 190 preferably has a circular shape in the plan view. When the opening portion 190 has a circular shape in the plan view, processing accuracy in forming the opening portion 190 can be high, whereby the opening portion 190 can be formed to have a minute size. Note that in this specification and the like, a circular shape is not necessarily a perfect circular shape. Although an example where the opening portion 190 is circular in the plan view is described in this embodiment, the present invention is not limited thereto. The shape that can be employed for the opening portion 190 is similar to the above-described shape that can be employed for the opening portion 270.

FIG. 28B illustrate an example where the side surface of the opening portion 190 is perpendicular to the top surface of the conductive layer 110. At this time, the opening portion 190 has a cylindrical shape. Such a structure enables miniaturization or high integration of the memory device.

The conductive layer 115 is provided along the side surface of the opening portion 190 and the top surface of the conductive layer 110. The insulating layer 130 is provided over the conductive layer 115. The conductive layer 220 is provided over the insulating layer 130 to fill the opening portion 190. The capacitor 100 having such a structure may be referred to as a trench-type capacitor or a trench capacitor. Note that the structure of the capacitor 100 is not limited thereto; a pillar capacitor, a parallel plate capacitor, or the like may be used, for example.

The insulating layer 140 can be formed using an insulating material that can be used for the insulating layer 210, for example.

The insulating layer 180 functions as an interlayer film and thus preferably has a low dielectric constant. In the case where a material with a low dielectric constant is used for an interlayer film, the parasitic capacitance generated between wirings can be reduced. As the insulating layer 180, an insulating layer containing a material with a low dielectric constant can be used as a single layer or stacked layers. Silicon oxide and silicon oxynitride, which have thermal stability, are preferable. Note that the insulating layer 180 can be formed using an insulating material that can be used for the insulating layer 280, for example.

The insulating layer 280 is placed over the capacitor 100.

FIG. 28B illustrates components of the transistor 200. The description in Embodiment 1 (e.g., FIG. 1B) can be referred to for the transistor 200; thus, the detailed description thereof is omitted. The transistor included in the memory cell 150 is not limited to the transistor 200, and any of the transistors described as examples in Embodiment 1 can be used.

As illustrated in FIG. 28B, the transistor 200 is provided to overlap with the capacitor 100. The groove portion 290 where part of the components of the transistor 200 is provided includes a region overlapping with the opening portion 190 where part of the components of the capacitor 100 is provided. With such a structure, the transistor 200 and the capacitor 100 can be provided without an increase in the area in the plan view. Thus, the area occupied by the memory cell 150 can be reduced, so that the memory cells 150 can be arranged densely and the storage capacity of the memory device can be increased. In other words, the memory device can be highly integrated.

FIG. 28B illustrates an example where the width of the opening portion 190 in the X direction is equal or substantially equal to that of the groove portion 290. There is no particular limitation on the magnitude relation between the widths of the opening portion 190 and the groove portion 290. The width of the opening portion 190 can be smaller than that of the groove portion 290. When the width of the opening portion 190 in the X direction is smaller than that of the groove portion 290, the required alignment accuracy of the end portion of the conductive layer 220 and the opening portion 190 can be reduced, so that the conductive layer 220 can be relatively easily processed. This also enables further miniaturization and higher integration of the memory device. Alternatively, the width of the opening portion 190 can be larger than that of the groove portion 290 in the X direction. When the width of the opening portion 190 is larger than that of the groove portion 290 in the X direction, the capacitance of the capacitor 100 can be increased. Note that for example, as illustrated in FIG. 28B, the relation between the two widths in the semiconductor device of one embodiment of the present invention can be found in one cross section parallel to the Z direction.

When the transistor 200 is provided above the capacitor 100, the transistor 200 is not affected by heat treatment in manufacturing the capacitor 100. Thus, in the transistor 200, degradation of the electrical characteristics such as variation in threshold voltage and an increase in parasitic resistance, and an increase in variation in electrical characteristics due to the degradation of the electrical characteristics can be inhibited.

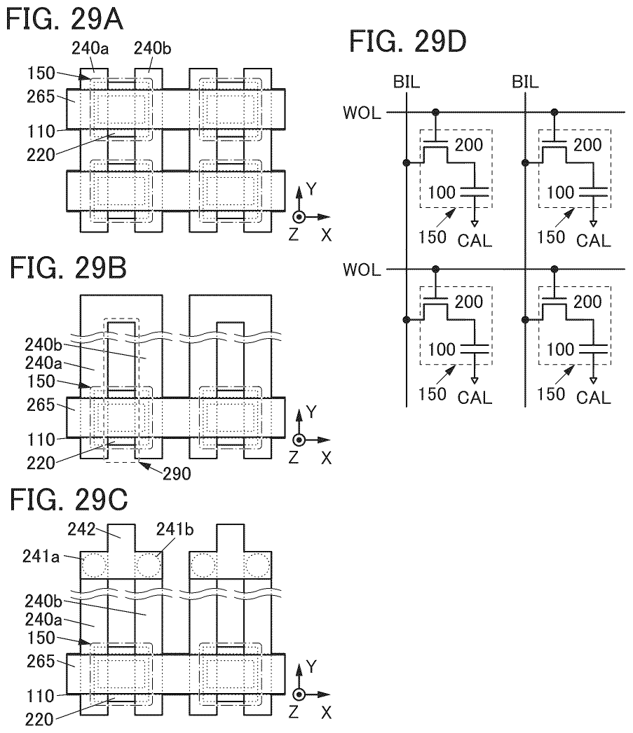

FIG. 29A is a plan view illustrating an example of a memory device where a plurality of memory cells 150 illustrated in FIGS. 28A to 28C are arranged. FIG. 29A illustrates an example where 2×2 memory cells 150 are arranged in the X direction and the Y direction. The X direction and the Y direction shown in FIG. 29A are respectively parallel to the A1-A2 direction and the B1-B2 direction shown in FIG. 1A1.

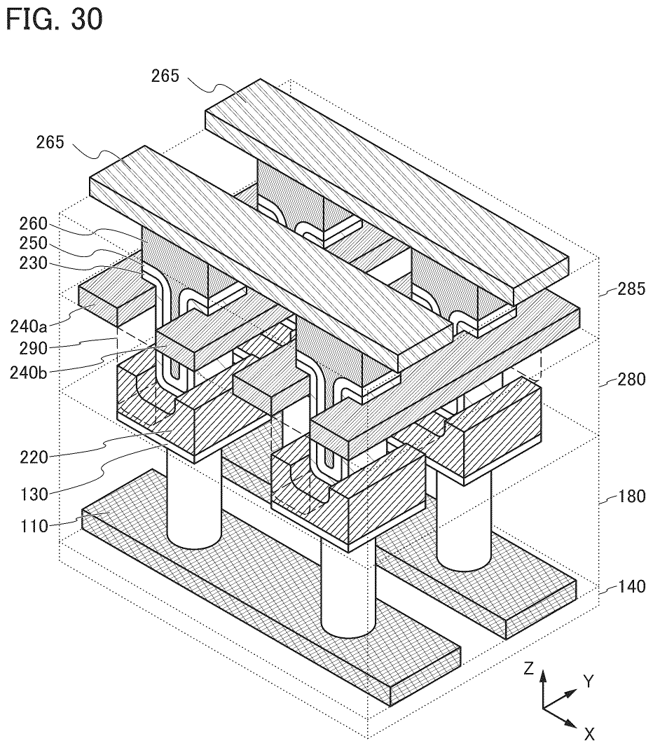

FIG. 30 is a schematic perspective view of the memory device illustrated in FIG. 29A. FIG. 30 is a schematic perspective view of a memory device including four memory cells. For some components (e.g., interlayer insulating layers), FIG. 30 shows only outlines indicated by dotted lines.

As described in Embodiment 1, when the conductive layer 240a and the conductive layer 240b are connected to each other, the conductive layer 240a and the conductive layer 240b can function as the other of the source electrode and the drain electrode of the transistor 200 included in the memory cell 150.

Examples of a method for connecting the conductive layer 240a and the conductive layer 240b include a method in which one conductive layer is used as the conductive layer 240a and the conductive layer 240b, a method in which the conductive layer 240a and the conductive layer 240b are connected through a conductive layer, and a method in which the same potential is applied to the conductive layer 240a and the conductive layer 240b.

FIG. 29B illustrates a structure example where one conductive layer is used as the conductive layer 240a and the conductive layer 240b. As illustrated in FIG. 29B, a groove portion can be provided in a region of the one conductive layer where the memory cell 150 is placed. With such a structure, the conductive layer in the region where the memory cell 150 is placed can function as the conductive layer 240a or the conductive layer 240b. The groove portion can be formed to overlap with the groove portion 290 described in Embodiment 1, for example. Accordingly, the groove portion can be formed without an increase in the number of steps.

FIG. 29C illustrates a structure example where the conductive layer 240a and the conductive layer 240b are connected to each other through a conductive layer. As illustrated in FIG. 29C, the conductive layer 240a and the conductive layer 240b can be connected to each other through a conductive layer 241a, a conductive layer 241b, and a conductive layer 242. The conductive layer 241a and the conductive layer 241b function as plugs and the conductive layer 242 functions as a wiring.

FIG. 29D is a circuit diagram where the conductive layer 240a and the conductive layer 240b are connected to each other in the memory device illustrated in FIG. 29A.

One of the source and the drain of the transistor 200 is connected to one of the pair of electrodes of the capacitor 100, the other of the source and the drain of the transistor 200 is connected to a wiring BIL, and the gate of the transistor 200 is connected to a wiring WOL. The other of the pair of electrodes of the capacitor 100 is connected to a wiring CAL.

Here, the wiring BIL corresponds to the conductive layer 240a and the conductive layer 240b, the wiring WOL corresponds to the conductive layer 265, and the wiring CAL corresponds to the conductive layer 110.

As illustrated in FIG. 29A, the conductive layer 265 is preferably provided to extend in the X direction, and the conductive layer 240a and the conductive layer 240b are preferably provided to extend in the Y direction. With such a structure, the wiring BIL and the wiring WOL are provided to intersect with each other. In FIG. 29A, the wiring CAL is provided parallel to the wiring WOL. Note that the present invention is not limited thereto. The wiring CAL may be provided parallel to the wiring BIL, for example.

Note that the memory cell will be described in detail in a later embodiment.

### [Capacitor 100]

The capacitor 100 includes the conductive layer 115, the insulating layer 130, and the conductive layer 220. The conductive layer 110 is provided below the conductive layer 115. The conductive layer 115 includes a region in contact with the conductive layer 110.

The conductive layer 110 functions as the wiring CAL and can be provided in a belt-like shape, for example. Note that a belt-like shape refers to a shape including a region extending in a certain direction (e.g., the X direction, the Y direction, or the Z direction).

The conductive layer 110 includes a depressed portion in a region overlapping with the opening portion 190.

The conductive layer 110 can be formed as a single layer or stacked layers using the conductive material described in [Conductive layer] in Embodiment 1. For example, a conductive material with high conductivity such as tungsten can be used for the conductive layer 110. With the use of a conductive material with high conductivity, the conductivity of the conductive layer 110 can be improved and the wiring CAL can function sufficiently.

The conductive layer 115 includes a region 101 with a curved corner in the depressed portion of the conductive layer 110. Thus, electric field concentration in the insulating layer 130 in the vicinity of the region 101 can be inhibited as compared with the case where the region 101 has a right-angle or acute-angle corner (in the case where the region 101 has an angular portion), for example. An end portion 103 of the conductive layer 115 is provided at a lower position than the top surface of the insulating layer 180 with respect to a reference surface. Accordingly, electric field concentration in the insulating layer 130 in the vicinity of the end portion 103 can be inhibited as compared with the case where the end portion 103 is positioned above the insulating layer 180. When electric field concentration in the insulating layer 130 is inhibited in this manner, the dielectric breakdown of the insulating layer 130 can be inhibited, so that a highly reliable memory device can be provided. Note that the reference surface can be the top surface of the substrate, the top surface of the insulating layer 140, or the like.

The conductive layer 115 can be formed as a single layer or stacked layers using the conductive material described in [Conductive layer] in Embodiment 1. For the conductive layer 115, a single layer or stacked layers of a conductive material that is not easily oxidized, a conductive material having a function of inhibiting diffusion of oxygen, or the like is preferably used. For example, titanium nitride, ITSO, or the like may be used. Alternatively, a structure where titanium nitride is stacked over tungsten may be used, for example. Alternatively, a structure where tungsten is stacked over first titanium nitride and second titanium nitride is stacked over the tungsten may be used, for example. With such a structure, when an oxide is used for the insulating layer 130, the conductive layer 115 can be inhibited from being oxidized by the insulating layer 130. When an oxide is used for the insulating layer 180, the conductive layer 115 can be inhibited from being oxidized by the insulating layer 180.

The insulating layer 130 is provided over the conductive layer 115. The insulating layer 130 can be provided to be in contact with the top surface of the conductive layer 115. That is, the insulating layer 130 preferably covers the side end portion of the conductive layer 115. This can prevent a short circuit between the conductive layer 115 and the conductive layer 220. The insulating layer 130 is preferably formed using a material with a high dielectric constant. Using a material with a high dielectric constant for the insulating layer 130 allows the insulating layer 130 to be thick enough to inhibit a leakage current and the capacitor 100 to have a sufficiently high capacitance.

The insulating layer 130 is preferably formed of stacked insulating layers each formed using a material with a high dielectric constant, and preferably has a stacked-layer structure of a material with a high dielectric constant and a material with higher dielectric strength than the material with a high dielectric constant. For example, for the insulating layer 130, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity can be used for the insulating layer 130. Description in Embodiment 1 can also be referred to for the details of the material that can have ferroelectricity.

A metal oxide containing one or both of hafnium and zirconium is preferable for the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable for the insulating layer 130 because the metal oxide can have ferroelectricity even with a minute area. For example, a ferroelectric layer can have ferroelectricity even with an area (occupied area) less than or equal to 100 μm², less than or equal to 10 μm², less than or equal to 1 μm², or less than or equal to 0.1 μm² in a plan view. Furthermore, even with an area less than or equal to 10000 nm² or less than or equal to 1000 nm², a ferroelectric layer has ferroelectricity in some cases. With a small-area ferroelectric layer, the area occupied by the capacitor 100 can be reduced.

Yttrium can be added to the metal oxide containing one or both of hafnium and zirconium. For example, addition of yttrium to hafnium zirconium oxide can increase ferroelectricity.

The ferroelectric refers to an insulator having a property of causing internal polarization by application of an electric field from the outside and maintaining the polarization even after the electric field is made zero. Thus, with the use of a capacitor containing this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 220 is provided to cover the insulating layer 130. The side end portion of the conductive layer 220 is preferably positioned outward from the side end portion of the conductive layer 115. With such a structure, the conductive layer 220 can be embedded in the opening portion 190. When the area of the conductive layer 220 in the plan view is increased, the required alignment accuracy with the groove portion 290 can be reduced and the groove portion 290 can be relatively easily processed.

For the material, structure, and the like that can be used for the conductive layer 220, the description in Embodiment 1 can be referred to.

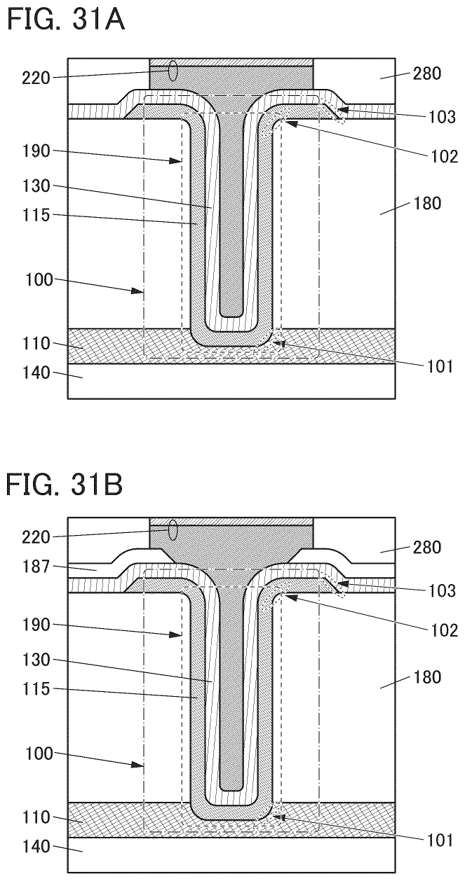

FIG. 31A illustrates an example where the end portion 103 illustrated in FIG. 28B is positioned over the insulating layer 180. In the example illustrated in FIG. 31A, a region 102 from the top surface of the insulating layer 180 to the side surface of the opening portion 190 has a curved portion. In the example illustrated in FIG. 31A, the end portion 103 has a tapered shape. When the region 102 has a curved portion and the end portion 103 has a tapered shape, electric field concentration in the insulating layer 130 in the vicinity of the region 102 and in the vicinity of the end portion 103 can be inhibited even when the end portion 103 is positioned over the insulating layer 180. Accordingly, dielectric breakdown of the insulating layer 130 is inhibited, so that a highly reliable memory device can be provided.

FIG. 31B illustrates an example where an insulating layer 187 is provided over the insulating layer 130 illustrated in FIG. 31A, for example, over a region of the insulating layer 130 overlapping with the insulating layer 180. Providing the insulating layer 187 can suitably inhibit electric field concentration in the insulating layer 130 in some cases.

### Structure Example 2 of Memory Device

Although <Structure example 1 of memory device> describes the example where the transistor 200 described in Embodiment 1 is used as the transistor included in the memory cell 150, a transistor that can be used as the transistor is not limited thereto. For example, the transistor 200B described in Embodiment 1 can be used.

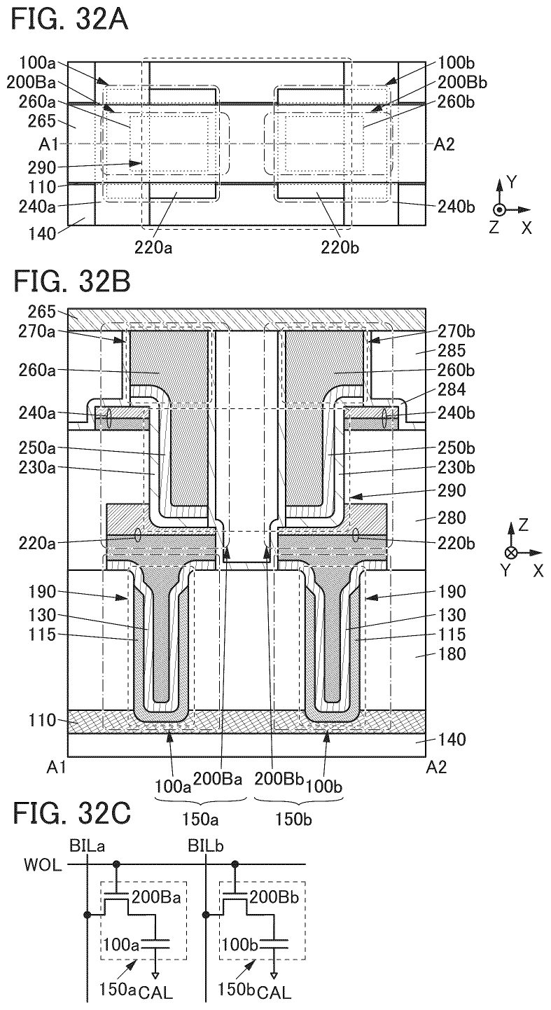

Another structure of a memory device including a transistor and a capacitor is described with reference to FIGS. 32A and 32B. FIG. 32A is a plan view of a memory device including two memory cells. FIG. 32B is a cross-sectional view taken along dashed-dotted line A1-A2 in FIG. 32A.

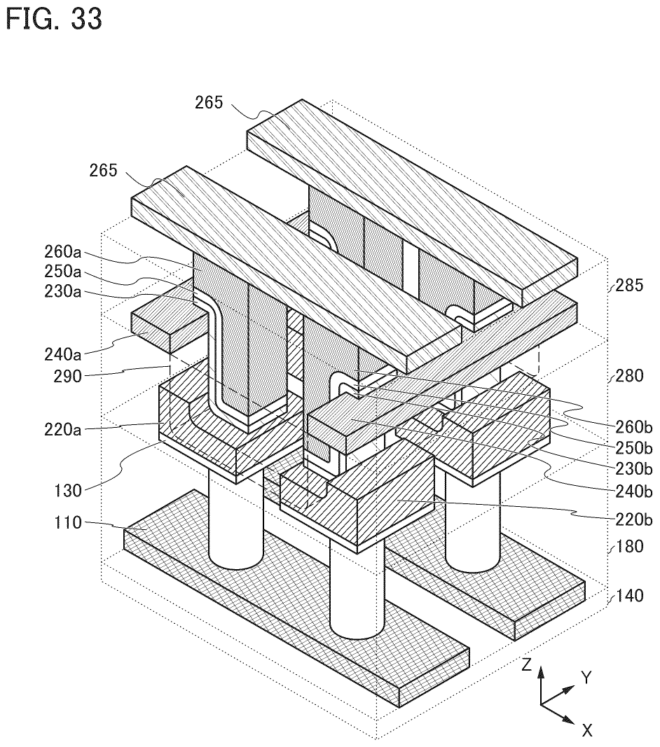

FIG. 33 is a schematic perspective view of the memory device illustrated in FIGS. 32A and 32B. FIG. 33 is a schematic perspective view of a memory device including four memory cells. For some components (e.g., interlayer insulating layers), FIG. 33 shows only outlines indicated by dotted lines.

The memory device illustrated in FIGS. 32A and 32B includes the insulating layer 140 over a substrate (not illustrated); the conductive layer 110 over the insulating layer 140; a memory cell 150a and a memory cell 150b over the conductive layer 110; the insulating layer 180 over the conductive layer 110; the insulating layer 280 over the insulating layer 180; the insulating layer 284 over the insulating layer 280; the insulating layer 285 over the insulating layer 284; and the conductive layer 265 over the insulating layer 284, the insulating layer 285, the memory cell 150a, and the memory cell 150b. The insulating layer 140, the insulating layer 180, the insulating layer 280, the insulating layer 284, and the insulating layer 285 function as interlayer films. The conductive layer 110 functions as a wiring. Hereinafter, the memory cell 150a and the memory cell 150b are collectively referred to as the memory cell 150 in some cases.

The memory cell 150a includes a capacitor 100a over the conductive layer 110 and the transistor 200Ba over the capacitor 100a. Similarly, the memory cell 150b includes a capacitor 100b over the conductive layer 110 and the transistor 200Bb over the capacitor 100b. Hereinafter, the transistor 200Ba and the transistor 200Bb are collectively referred to as the transistor 200B in some cases.

For the capacitor 100a and the capacitor 100b each having a structure similar to that of the capacitor 100 described above in <Structure example 1 of memory device>, the description of the capacitor 100 can be referred to.

In the memory device illustrated in FIGS. 32A and 32B, the transistor 200B described as example in Embodiment 1 is used as the transistor included in the memory cell 150 of the memory device. Therefore, the description in Embodiment 1 (FIG. 23B) can be referred to for the transistor 200Ba and the transistor 200Bb; thus, the detailed description thereof is omitted.

With the structure illustrated in FIGS. 32A and 32B, two memory cells can be provided in a region where the groove portion 290 and the gate wiring (the conductive layer 265) overlap with each other. Accordingly, the area occupied by the memory device can be reduced, and the memory device can be miniaturized or highly integrated.

FIG. 32C is a circuit diagram of the memory device illustrated in FIGS. 32A and 32B.

One of a source and a drain of the transistor 200Ba is connected to one of a pair of electrodes of the capacitor 100a, the other of the source and the drain of the transistor 200Ba is connected to the wiring BILa, and a gate of the transistor 200Ba is connected to the wiring WOL. The other of the pair of electrodes of the capacitor 100a is connected to the wiring CAL.

One of a source and a drain of the transistor 200Bb is connected to one of a pair of electrodes of the capacitor 100b, the other of the source and the drain of the transistor 200Bb is connected to the wiring BILb, and a gate of the transistor 200Bb is connected to the wiring WOL. The other of the pair of electrodes of the capacitor 100b is connected to the wiring CAL.

Here, the wiring BILa corresponds to the conductive layer 240a, the wiring BILb corresponds to the conductive layer 240b, the wiring WOL corresponds to the conductive layer 265, and the wiring CAL corresponds to the conductive layer 110.

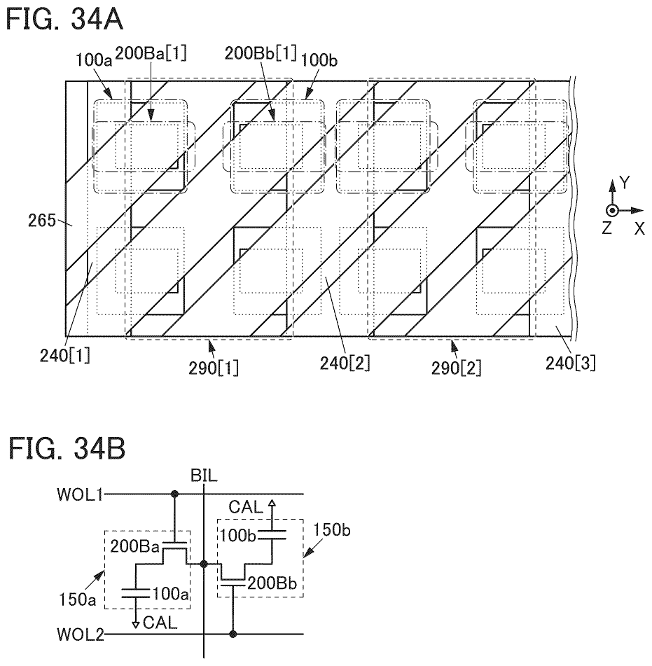

The semiconductor device illustrated in FIG. 25C can be used as each of the transistor 200Ba and the transistor 200Bb included in the memory device illustrated in FIGS. 32A and 32B. FIG. 34A is a plan view of the memory device in this case. Note that a structure where the semiconductor device illustrated in FIG. 25C and the memory device illustrated in FIG. 32B are combined can be referred to for the cross-sectional view of the memory device in FIG. 34A.

As illustrated in FIG. 34A, the conductive layer 265 is placed such that its extending direction is inclined with respect to the Y direction. Each of the memory cells 150a and 150b is provided at an intersection portion of the conductive layer 240 extending in the Y direction and the conductive layer 265. Such a structure enables miniaturization or high integration of the memory device.

FIG. 34B is a circuit diagram of the memory device illustrated in FIG. 34A.

One of the source and the drain of the transistor 200Ba is connected to one of the pair of electrodes of the capacitor 100a, the other of the source and the drain of the transistor 200Ba is connected to the wiring BIL, and the gate of the transistor 200Ba is connected to a wiring WOL1. The other of the pair of electrodes of the capacitor 100a is connected to the wiring CAL.

One of the source and the drain of the transistor 200Bb is connected to one of the pair of electrodes of the capacitor 100b, the other of the source and the drain of the transistor 200Bb is connected to the wiring BIL, and the gate of the transistor 200Bb is connected to a wiring WOL2. The other of the pair of electrodes of the capacitor 100b is connected to the wiring CAL.

Here, the wiring BIL corresponds to the conductive layer 240, the wiring WOL1 corresponds to the conductive layer 265, the wiring WOL2 corresponds to another conductive layer 265 adjacent to the wiring WOL1, and the wiring CAL corresponds to the conductive layer 110.

### Structure Example 3 of Memory Device

The memory cell 150 described in this embodiment can be used as a memory cell of a memory device. The transistor 200 is preferably an OS transistor. Since the off-state current of the OS transistor is low, a memory device including the transistor can retain stored data for a long time. In other words, such a memory device does not require refresh operation or has an extremely low frequency of refresh operation, leading to a sufficient reduction in power consumption. When the transistor 200 is used for a memory device, the memory device can be highly integrated and reduced in power consumption. An OS transistor has high frequency characteristics and thus can perform reading and writing of a memory device at high speed.

The memory cells 150 can be arranged in a matrix three-dimensionally to form a memory cell array.

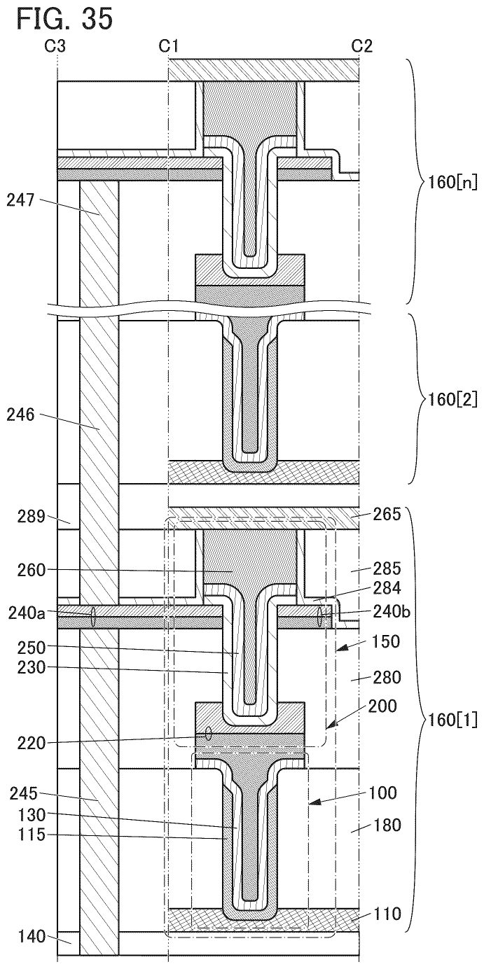

FIG. 35 illustrates an example where n layers (n is an integer greater than or equal to 3) each including one memory cell illustrated in FIG. 28B are stacked in the Z direction. The C1-C2 direction shown in FIG. 35 is parallel to the X direction, and a region between C1 and C2 includes two memory cells. The C1-C3 direction shown in FIG. 35 is parallel to the Y direction, and a region between C1-C3 includes a region where the conductive layer 240a extends.

The memory device illustrated in FIG. 35 includes n memory layers 160. Specifically, a memory layer 160[2] is provided over a memory layer 160[1], (n−3) memory layers are provided over the memory layer 160[2], and a memory layer 160[n] is provided in the uppermost stage. There is no particular limitation on the number of memory cells included in one memory layer 160, and two or more memory cells can be included. Through a conductive layer 245, a conductive layer 246, a conductive layer 247, and the like, the memory cells included in the n memory layers 160 are connected to a sense amplifier (not illustrated) provided below the n memory layers 160. In this case, the conductive layer 245, the conductive layer 246, and the like function as part of the wiring BIL. When the memory device or the like is provided above or below the memory device illustrated in FIG. 28B in this manner, the storage capacity per unit area can be increased.

Note that the conductive layer 245, the conductive layer 246, the conductive layer 247, and the like may each function as a plug or a wiring for connecting the memory cells 150 to a wiring, an electrode, a terminal, or a circuit element such as a switch, a transistor, a capacitor, an inductor, a resistor, or a diode.

FIG. 35 illustrates an example where the conductive layer 245 is in contact with the bottom surface of the conductive layer 240a and the conductive layer 246 is in contact with the top surface of the conductive layer 240a. The conductive layer 245 is placed in an opening portion formed in the insulating layer 140, the insulating layer 180, and the insulating layer 280. The conductive layer 246 is placed in an opening portion formed in an insulating layer 289, the insulating layer 285, and the insulating layer 284. Note that a conductive material that can be used for the conductive layer 240, for example, can be used for the conductive layer 245, the conductive layer 246, and the conductive layer 247, and the like.

Note that a connection portion between the plug such as the conductive layer 245 or the conductive layer 246 and each memory cell can have any of a variety of modes and is not limited to the structure in FIG. 35. For example, the conductive layer 246 can be in contact with the top surface of the conductive layer 240al. That is, the conductive layer 240a2 may include an opening portion in a position overlapping with the conductive layer 246. As a connection portion between the memory cell and the plug, a layer having a low contact resistance with the conductive layer 246 among the layers included in the conductive layer 240 is preferably in contact with the conductive layer 246. Among the layers included in the conductive layer 240, a layer having a low wiring resistance is preferably in contact with the conductive layers 245 and 246.

When a plurality of memory cells are stacked as illustrated in FIG. 35, the cells can be placed in an integrated manner without increasing the area occupied by the memory cell array. That is, a 3D memory cell array can be formed. This results in an increase in the storage capacity per unit area of the storage.

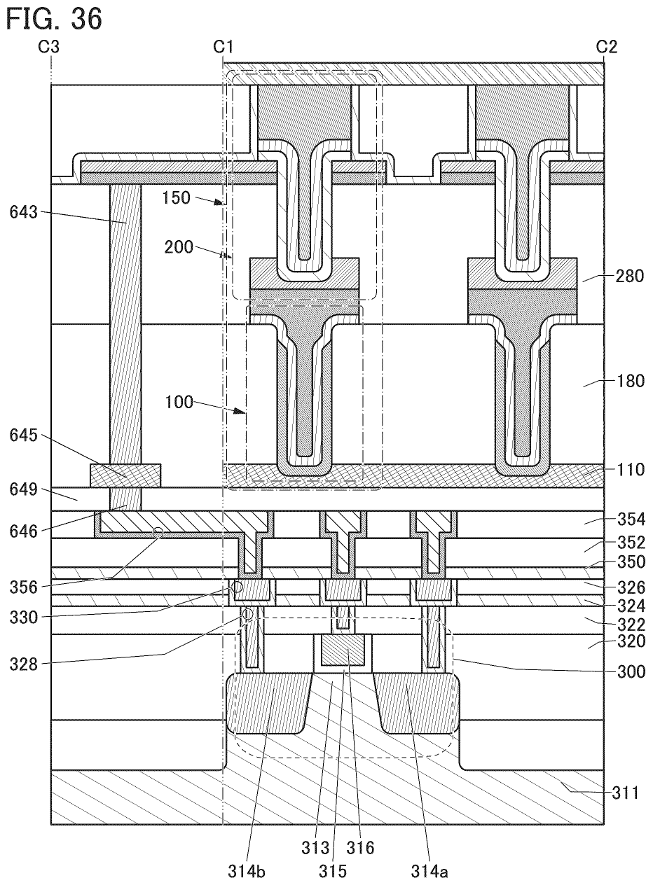

FIG. 36 illustrates a cross-sectional structure example of a memory device where a layer including a memory cell is stacked over a layer including a driver circuit provided with a sense amplifier.

In FIG. 36, the memory cell 150 (the transistor 200 and the capacitor 100) is provided above a transistor 300.

The transistor 300 is one of the transistors included in the sense amplifier.

For the memory cell 150 illustrated in FIG. 36, the description of the memory cell 150 in <Structure example 1 of memory device> can be referred to.

When the sense amplifier is provided to overlap with the memory cell 150 as illustrated in FIG. 36, the bit line can be shortened. Accordingly, the bit line capacitance can be reduced and the memory device can be driven at high speed.

The memory device illustrated in FIG. 36 can correspond to a semiconductor device 900 described in Embodiment 5. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 may be either a p-channel transistor or an n-channel transistor. The substrate 311 preferably includes a silicon-based semiconductor, specifically, single crystal silicon.

In the transistor 300 illustrated in FIG. 36, the semiconductor region 313 (part of the substrate 311) where a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 36 is just an example and is not limited to having the structure illustrated therein; an appropriate transistor can be used in accordance with a circuit structure or a driving method.

A wiring layer including an interlayer film, a wiring, a plug, and the like may be provided between components. A plurality of wiring layers can be provided in accordance with the design. Here, a plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 36, an insulating layer 350, an insulating layer 352, and an insulating layer 354 are stacked in this order. Furthermore, a conductive layer 356 is formed in the insulating layer 350, the insulating layer 352, and the insulating layer 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 200 is electrically connected to the low-resistance region 314b functioning as the source region or the drain region of the transistor 300 through a conductive layer 643, a conductive layer 645, a conductive layer 646, the conductive layer 356, the conductive layer 330, and the conductive layer 328.

The conductive layer 643 is embedded in the insulating layer 280 and the insulating layer 180. The conductive layer 645 is embedded in the insulating layer 180. The conductive layer 645 and the conductive layer 110 can be formed using the same material in the same step. The conductive layer 646 is embedded in an insulating layer 649. The transistor 300 and the conductive layer 110 are insulated from each other by the insulating layer 649.

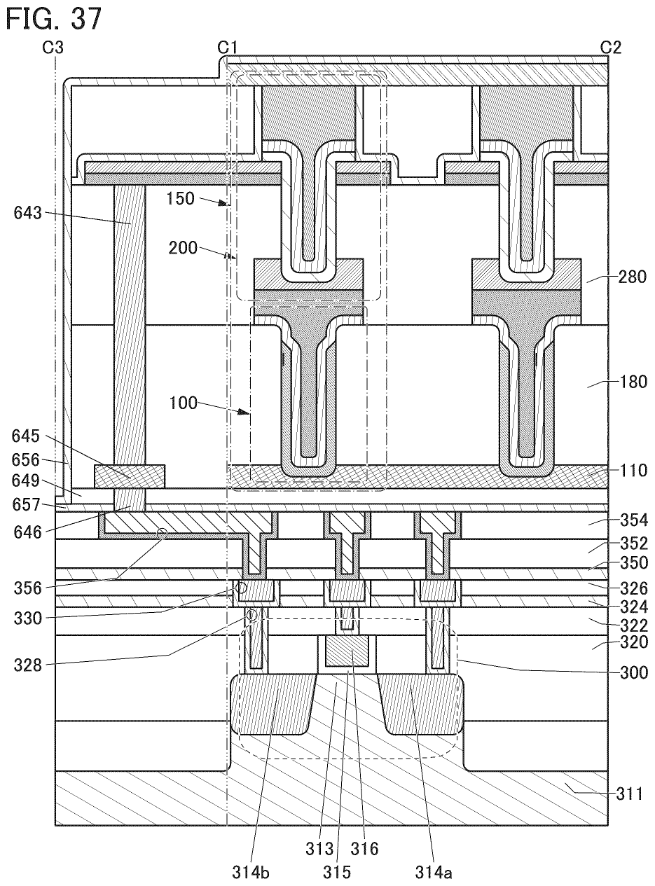

As illustrated in FIG. 37, a structure can be employed where an insulating layer 657 is provided over the insulating layer 354 and the conductive layer 356 and an insulating layer 656 is provided to cover the memory cell 150. Here, for the insulating layer 657 and the insulating layer 656, an insulating material similar to that for the insulating layer 284 can be used, and the above-described barrier insulating layer against hydrogen is preferably used. For example, silicon nitride is preferably used for the insulating layer 657 and the insulating layer 656.

As illustrated in FIG. 37, the insulating layer 656 is preferably provided in contact with the top surface of the insulating layer 657. With such a structure, the memory cell 150 can be sealed with the insulating layer 657 and the insulating layer 656. This can inhibit entry of hydrogen into the memory cell 150 from the outside. Accordingly, degradation of the electrical characteristics and reliability of the OS transistor included in the memory cell 150 can be inhibited.

In the case where a plurality of memory layers 160 are provided as illustrated in FIG. 35, the plurality of memory layers 160 can be collectively covered with the insulating layer 656. Alternatively, the insulating layer 656 may cover each memory layer 160.

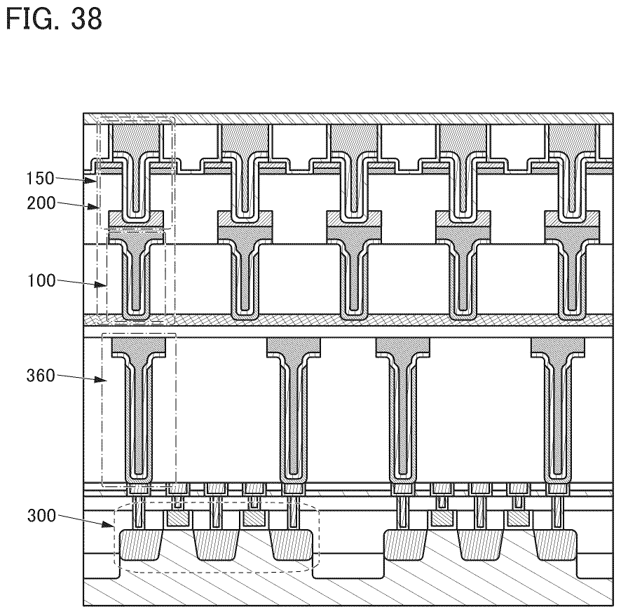

As illustrated in FIG. 38, one of a source and a drain of the transistor 300 can be connected to a capacitor 360. The capacitor 360 is placed in an opening of an interlayer film provided over the transistor 300. The capacitor 360 can have a structure similar to that of the capacitor 100. With such a structure, the transistor 300 and the capacitor 360 can function as a DRAM. A material that can have ferroelectricity can be used as a dielectric of the capacitor 360. As illustrated in FIG. 38, a set of adjacent transistors 300 can be provided in one semiconductor region 313. In this case, a common electrode can be provided for the other of the source and the drain of each of the adjacent transistors 300.

This embodiment can be combined with any of the other embodiments as appropriate. In this specification, in the case where a plurality of structure examples are shown in one embodiment, the structure examples can be combined as appropriate.

### Embodiment 4

In this embodiment, an example of a method for operating a memory device of one embodiment of the present invention will be described. In a memory cell described below as an example, the transistor including the ferroelectric described as example in Embodiment 1 can be used.

### [Hysteresis Properties of Ferroelectric]

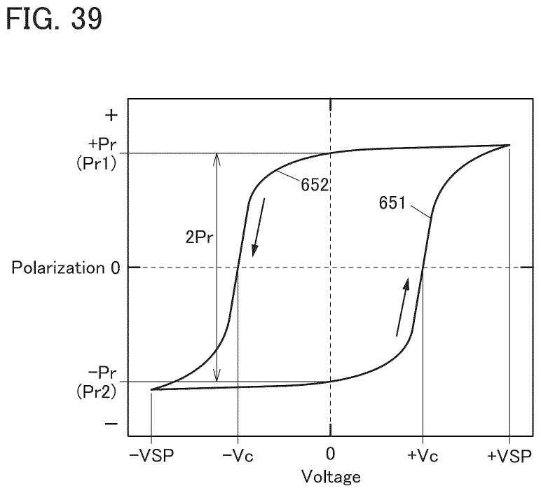

A ferroelectric has hysteresis properties. FIG. 39 is a graph showing an example of hysteresis properties of a ferroelectric. The hysteresis properties can be measured using a capacitor including a ferroelectric (a ferroelectric capacitor). In FIG. 39, the horizontal axis represents voltage (electric field) applied to the ferroelectric. The voltage is a potential difference between one electrode and the other electrode of the ferroelectric capacitor. The electric field strength can be obtained by dividing the potential difference by the thickness of the ferroelectric.

In FIG. 39, the vertical axis represents polarization of the ferroelectric. Positive polarization indicates that positive charge in the ferroelectric is concentrated on the one electrode side of the capacitor and negative charge is concentrated on the other electrode side of the capacitor. By contrast, negative polarization indicates that negative charge in the ferroelectric is concentrated on the one electrode side of the capacitor and positive charge is concentrated on the other electrode side of the capacitor.

Alternatively, the polarization represented by the vertical axis of the graph in FIG. 39 may be regarded as being positive when negative charge is concentrated on the one electrode side of the capacitor and positive charge is concentrated on the other electrode side of the capacitor, and regarded as being negative when positive charge is concentrated on the one electrode side of the capacitor and negative charge is concentrated on the other electrode side of the capacitor.

As shown in FIG. 39, the hysteresis properties of the ferroelectric can be represented by a curve 651 and a curve 652. Voltages at the intersections of the curve 651 and the curve 652 are referred to as a saturated polarization voltage +VSP (also referred to as “+VSP”) and a saturated polarization voltage −VSP (also referred to as “−VSP”). It can be said that +VSP and −VSP have different polarities.

When a voltage lower than or equal to −VSP is applied to the ferroelectric and then the voltage applied to the ferroelectric is increased, the polarization of the ferroelectric is increased along the curve 651. On the other hand, when a voltage higher than or equal to +VSP is applied to the ferroelectric and then the voltage applied to the ferroelectric is decreased, the polarization of the ferroelectric is decreased along the curve 652. Note that +VSP is sometimes referred to as a positive saturated polarization voltage or a first saturated polarization voltage. Moreover, −VSP is sometimes referred to as a negative saturated polarization voltage or a second saturated polarization voltage. The absolute value of the first saturation polarization voltage may be the same as or different from the absolute value of the second saturation polarization voltage.

The voltage at the time when the polarization of the ferroelectric changes along the curve 651 to reach 0 is referred to as a coercive voltage +Vc. The voltage at the time when the polarization of the ferroelectric changes along the curve 652 to reach 0 is referred to as a coercive voltage −Vc. The value of +Vc and the value of −Vc are each a value between +VSP and −VSP. In some cases, +Vc is referred to as a positive coercive voltage or a first coercive voltage, and −Vc is referred to as a negative coercive voltage or a second coercive voltage. The absolute value of the first coercive voltage may be the same as or different from the absolute value of the second coercive voltage.

The maximum value of polarization when voltage is not applied to the ferroelectric (when voltage is 0 V) is referred to as remanent polarization +Pr or remanent polarization Pr1, and the minimum value thereof is referred to as remanent polarization −Pr or remanent polarization Pr2. The absolute value of the difference between the remanent polarization +Pr and the remanent polarization −Pr is referred to as remanent polarization 2Pr. Larger remanent polarization 2Pr increases the range of a change in the capacitance of the ferroelectric capacitor due to polarization reversal. The remanent polarization 2Pr is preferably as large as possible.

### [Relation Between Polarization of Ferroelectric and Id-Vg Characteristics]

Next, a structure where a transistor is provided with a capacitor including a ferroelectric will be described. The relation between polarization of a ferroelectric included in a capacitor 620 and the Id-Vg characteristics of a transistor 610 will be described below.

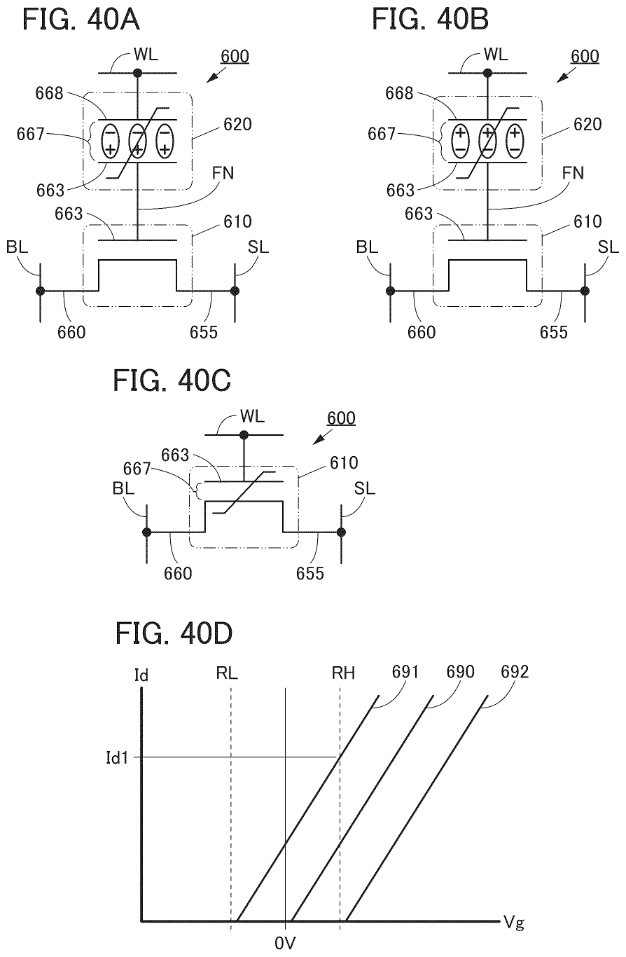

FIGS. 40A and 40B are equivalent circuit diagrams of a semiconductor device 600 including the transistor 610 and the capacitor 620, which is a ferroelectric capacitor. The capacitor 620 includes an electrode 663 serving also as a gate of the transistor 610, an electrode 668 connected to a wiring WL, and an insulating layer 667 between the electrodes 663 and 668. The transistor 610 includes the electrode 663, an electrode 660 connected to a wiring BL, and an electrode 655 connected to a wiring SL. The electrode 660 functions as one of a source electrode and a drain electrode, and the electrode 655 functions as the other of the source electrode and the drain electrode. The insulating layer 667 functions as a ferroelectric layer. FIGS. 40A and 40B schematically illustrate the polarization of the insulating layer 667. The electrode 663 can also be referred to as a node FN.

The semiconductor device 600 corresponds to the semiconductor device including the insulating layer 250 and the conductive layer 252 illustrated in FIG. 7F in Embodiment 1, and the insulating layer 667 of the capacitor 620 corresponds to the insulating layer 250d2 illustrated in FIG. 7F. Although the structure where the capacitor 620, which is a ferroelectric capacitor, is connected to the gate of the transistor 610 is described below, the present invention is not limited to this structure. A structure can be employed where the insulating layer 667, which is a ferroelectric, is provided as a gate insulating layer of the transistor 610 without providing the capacitor 620 in the semiconductor device 600 as illustrated in FIG. 40C (such a structure can be referred to as an FeFET). Here, the electrode 663 of the transistor 610 is connected to the wiring WL. The semiconductor device 600 illustrated in FIG. 40C corresponds to the transistor 200 including the insulating layer 250 illustrated in FIGS. 7A to 7E in Embodiment 1. The operation principles and the operation method described below can also apply to the semiconductor device 600 illustrated in FIG. 40C.

FIG. 40D is a graph showing the Id-Vg characteristics of the transistor 610 at the time when a voltage between the source and the drain (also referred to as a drain voltage or Vd) is constant. In FIG. 40D, the horizontal axis represents a voltage between the source and the gate (also referred to as a gate voltage or Vg), and the vertical axis represents a current flowing between the source and the drain (also referred to as a drain current or Id).

In FIG. 40D, characteristics 690 indicate the Id-Vg characteristics of the transistor 610 at the time when polarization is not caused in the insulating layer 667 included in the capacitor 620.

In FIG. 40D, characteristics 691 indicate the Id-Vg characteristics of the transistor 610 at the time when the polarization of the insulating layer 667 is the remanent polarization Pr1. FIG. 40A schematically illustrates the polarization of the insulating layer 667 included in the capacitor 620 when the transistor 610 has the characteristics 691.

Since the remanent polarization Pr1 is positive polarization, a positive voltage is generated at the node FN. Thus, the Id-Vg characteristics 690 shift in the negative direction of Vg to be the characteristics 691. In other words, the threshold voltage of the transistor 610 shifts in the negative direction of Vg.

In FIG. 40D, characteristics 692 indicate the Id-Vg characteristics of the transistor 610 at the time when the polarization of the insulating layer 667 is the remanent polarization Pr2. FIG. 40B schematically illustrates the polarization of the insulating layer 667 included in the capacitor 620 when the transistor 610 has the characteristics 692.

Since the remanent polarization Pr2 is negative polarization, a negative voltage is generated at the node FN. Thus, the Id-Vg characteristics 690 shift in the positive direction of Vg to be the characteristics 692. In other words, the threshold voltage of the transistor 610 shifts in the positive direction of Vg.

As illustrated in FIGS. 40A to 40C, the Id-Vg characteristics of the transistor 610 can be changed in accordance with the polarization of the insulating layer 667, which is a ferroelectric layer. In other words, the threshold voltage of the transistor 610 can be controlled by controlling the polarization of the insulating layer 667. Thus, the semiconductor device 600 including the transistor 610 and the capacitor 620 can function as a memory cell capable of retaining binary data.

For example, when binary data of data “0” or “1” is written to the semiconductor device 600 functioning as a memory cell, it is preferable that the polarization of the insulating layer 667 be changed to the remanent polarization Pr1 to write the data “1”, and the polarization of the insulating layer 667 be changed to the remanent polarization Pr2 to write the data “0”. The Id-Vg characteristics of the semiconductor device 600 to which the data “1” has been written become the characteristics 691. The Id-Vg characteristics of the semiconductor device 600 to which the data “0” has been written become the characteristics 692.

Next, erasing operation, writing operation, retention operation, and reading operation of the semiconductor device 600 will be described.

### <Erasing Operation>

Before data is written to the semiconductor device 600 functioning as a memory cell, data in the semiconductor device 600 needs to be erased. In this embodiment, operation of writing data “0” to the semiconductor device 600 is performed as the erasing operation. That is, the polarization of the insulating layer 667 is changed to the remanent polarization Pr2.

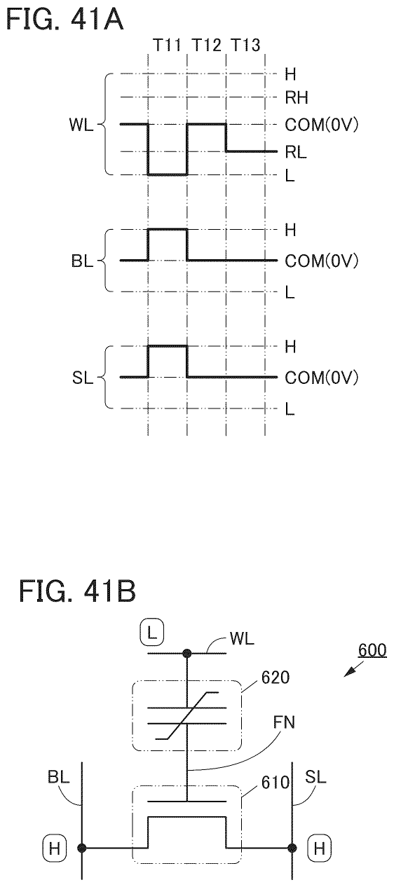

FIG. 41A is a timing chart for describing the erasing operation. FIG. 41B is a circuit diagram illustrating a state of the semiconductor device 600 in Period T11. Note that in a circuit diagram and the like, for easy understanding of a potential of a wiring or the like, a symbol showing the potential of the wiring is sometimes illustrated adjacent to the wiring or the like. Furthermore, an enclosed letter is sometimes written near a wiring or the like whose potential has changed.

In Period T11, a potential L is supplied to the wiring WL, and a potential H is supplied to the wiring BL and the wiring SL.

Note that the gate capacitance of the transistor 610 and the capacitor 620 are connected in series between the wirings WL and BL and between the wirings WL and SL. A voltage applied to the capacitor 620 is determined by the ratio of the gate capacitance of the transistor 610 to the capacitance of the capacitor 620. In this embodiment, the ratio of the gate capacitance of the transistor 610 to the capacitance of the capacitor 620 is 1:1. Accordingly, the difference between the potential H and the potential L is set to twice or more the absolute value of VSP. In order to change the polarization of the insulating layer 667 to the remanent polarization Pr2, the potential H is supplied to the wiring BL and the wiring SL, and the potential L is supplied to the wiring WL. The potential H is higher than the potential L.

For example, in the case where a potential COM is a reference potential (0 V), the potential H is higher than the potential COM and is different from the potential COM by +VSP. Similarly, the potential L is lower than the potential COM and is different from the potential COM by −VSP.

Under the above conditions, the potential L is supplied to the wiring WL and the potential H is supplied to the wiring BL and the wiring SL, whereby-VSP is applied to the capacitor 620. Next, in Period T12, 0 V is supplied to the wiring WL, the wiring BL, and the wiring SL. That is, the wiring WL, the wiring BL, and the wiring SL are made to have the same potential.

In Period T12, the polarization of the insulating layer 667 becomes the remanent polarization Pr2 (see FIG. 39). Since the remanent polarization Pr2 is negative polarization as described above, a negative voltage is generated at the node FN. Thus, the Id-Vg characteristics 690 shift in the positive direction of Vg to be the characteristics 692. That is, the threshold voltage of the transistor 610 shifts in the positive direction of Vg (see FIG. 40D).

In Period T13, a potential RL is supplied to the wiring WL. The potential RL will be described in detail in the description of the retention operation. Note that Period T12 may be omitted and Period T11 may be followed by Period T13. A negative voltage is generated at the node FN through Period T11 even when Period T12 is omitted.

### <Writing Operation>

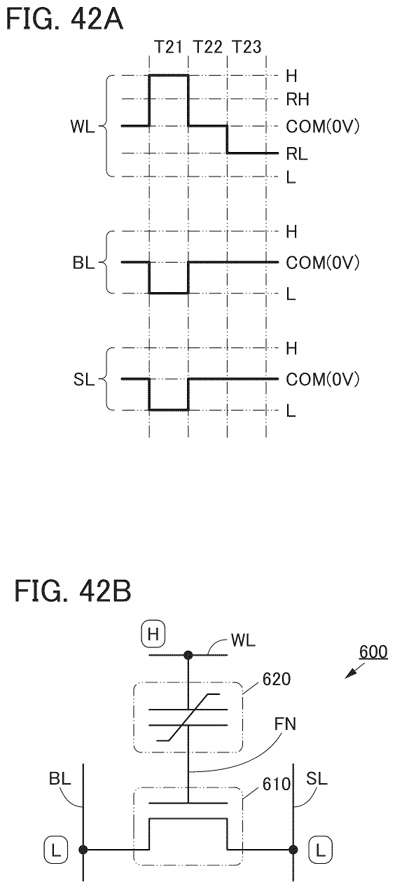

Next, operation of writing data “1” to the semiconductor device 600 functioning as a memory cell will be described. FIG. 42A is a timing chart for describing the writing operation. FIG. 42B is a circuit diagram illustrating a state of the semiconductor device 600 in Period T21.

After the erasing operation is performed in Period T11, the potential H is supplied to the wiring WL and the potential L is supplied to the wiring BL and the wiring SL in Period T21. Thus, +VSP is applied to the capacitor 620, and the polarization of the insulating layer 667 changes along the curve 651 (see FIG. 39). Then, in Period T22, 0 V is supplied to the wiring WL, the wiring BL, and the wiring SL. That is, the wiring WL, the wiring BL, and the wiring SL are made to have the same potential.

In Period T22, the polarization of the insulating layer 667 becomes the remanent polarization Pr1 (see FIG. 39). Since the remanent polarization Pr1 is positive polarization as described above, a positive voltage is generated at the node FN. Thus, the Id-Vg characteristics 690 shift in the negative direction of Vg to be the characteristics 691. That is, the threshold voltage of the transistor 610 shifts in the negative direction of Vg (see FIG. 40D).

In this manner, the data “1” can be written to the semiconductor device 600. Since the capacitor 620 is a ferroelectric capacitor, polarization of the insulating layer 667, which is a ferroelectric, is maintained even when power supply to the semiconductor device 600 stops. Thus, data written to the semiconductor device 600 is maintained even when power supply to the semiconductor device 600 stops. Accordingly, the semiconductor device 600 functions as a nonvolatile memory cell.

The operation of writing data “0” to the semiconductor device 600 is the same as the above-described erasing operation. Accordingly, there is no need to perform the operation of writing data “0” after the erasing operation.

### <Retention Operation>

After data is written to the semiconductor device 600, the potential RL is supplied to the wiring WL in Period T23. The potential RL is a potential at which the transistor 610 is turned off even when the Id-Vg characteristics of the transistor 610 are the characteristics 691 (see FIG. 40D). Thus, the potential RL is preferably set to a potential lower than the threshold voltage of the characteristics 691. Moreover, in order to hardly cause a change in polarization of the insulating layer 667, the potential RL is set to a voltage with which a voltage applied to the capacitor 620 is higher than or equal to the coercive voltage-Vc.

After the writing operation, the potential of the wiring WL is preferably the potential RL until the reading operation is performed. When the potential of the wiring WL remains as the potential RL, the transistor 610 is surely brought into an off state; thus, power consumption of the semiconductor device 600 is reduced. Moreover, in the case where the semiconductor devices 600 are arranged in a matrix to form a memory cell array, interference in the reading operation of another memory cell (semiconductor device 600) can be prevented. Consequently, the memory cell array can have higher reliability.

Note that Period T22 may be omitted and Period T21 may be followed by Period T23.

### <Reading Operation>

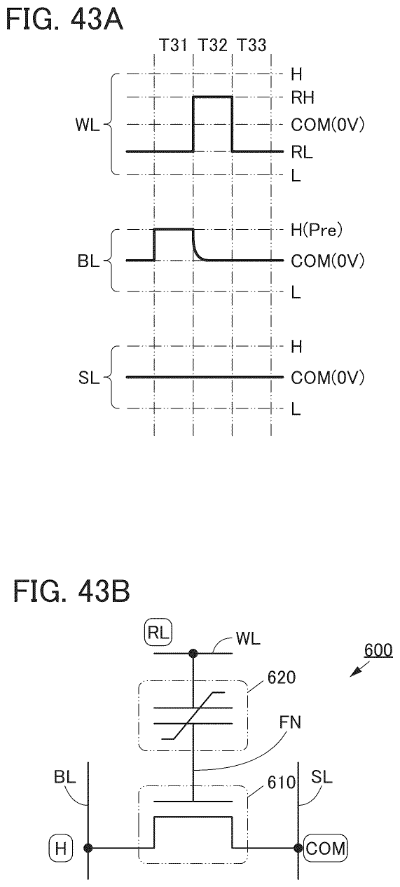

Next, operation of reading data retained in the semiconductor device 600 functioning as a memory cell will be described. FIG. 43A is a timing chart for describing the reading operation. FIG. 43B is a circuit diagram illustrating a state of the semiconductor device 600 in Period T31.

In this embodiment, the reading operation of the semiconductor device 600 that retains data “1” is described.

In Period T31, the wiring BL is precharged with the potential H. That is, after the potential of the wiring BL is set to the potential H, the wiring BL is brought into a floating state (a state where electric power is supplied from nowhere). In addition, the potential COM is supplied to the wiring SL.

Next, in Period T32, a potential RH that is a reading potential is supplied to the wiring WL. The potential RH is a potential higher than or equal to the threshold voltage of the characteristics 691 and lower than the threshold voltage of the characteristics 692. Moreover, in order to hardly cause a change in polarization of the insulating layer 667, the potential RH is set to a voltage with which the voltage applied to the capacitor 620 is lower than or equal to the coercive voltage +Vc.

In the case where the data “1” is retained in the semiconductor device 600, when the potential RH is supplied to the wiring WL, the transistor 610 is turned on, and a current Id1 flows between the source and the drain (see FIG. 40D). Thus, electrical continuity is established between the wiring BL and the wiring SL, and the potential of the wiring BL that is in a floating state changes toward the potential COM.

The case where the potential of the wiring BL changes after the potential RH is supplied to the wiring WL can be determined that the data “1” has been written to the semiconductor device 600. The case where it is judged that the potential of the wiring BL does not change even when the potential RH is supplied to the wiring WL can be determined that the data “O” has been written to the semiconductor device 600.

After the reading operation, the potential RL is supplied to the wiring WL in Period T33. Since the potential RH is set to a voltage with which the voltage applied to the capacitor 620 is lower than or equal to the coercive voltage +Vc, the polarization of the insulating layer 667 included in the capacitor 620 is less likely to change. Thus, non-destructive reading of the semiconductor device 600 can be achieved.

Note that the hysteresis properties of the ferroelectric change depending on the material, the structure, and the formation method. Accordingly, the potential RH is preferably a voltage with which the voltage applied to the capacitor 620 is 0.8 times or less, preferably 0.6 times or less the coercive voltage +Vc. Moreover, the potential RL is preferably a voltage with which the voltage applied to the capacitor 620 is 0.8 times or more, preferably 0.6 times or more the coercive voltage −Vc.

The above is the description of the method for operating the memory device.

At least part of this embodiment can be implemented as appropriate in combination with any of the other embodiments described in this specification.

### Embodiment 5

In this embodiment, the semiconductor device 900 of one embodiment of the present invention will be described. The semiconductor device 900 can function as a memory device.

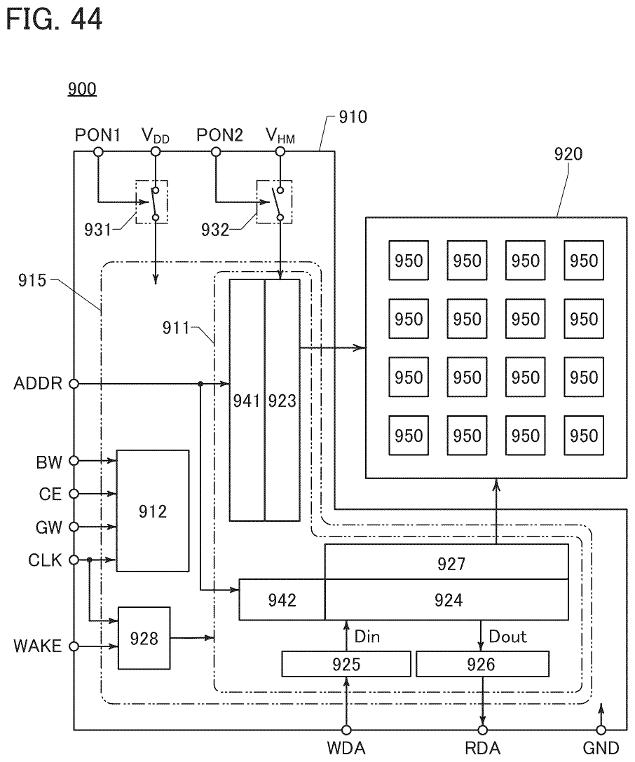

FIG. 44 is a block diagram illustrating a structure example of the semiconductor device 900. The semiconductor device 900 illustrated in FIG. 44 includes a driver circuit 910 and a memory array 920. The memory array 920 includes at least one memory cell 950. FIG. 44 illustrates an example where the memory array 920 includes a plurality of memory cells 950 arranged in a matrix.

The memory device (e.g., the memory device 150) described in Embodiment 3 can be used for the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of VDD to the peripheral circuit 915. The PSW 932 has a function of controlling the supply of VHM to the row driver 923. Here, in the semiconductor device 900, a high power supply potential is VDD and a low power supply potential is a ground potential (GND). In addition, VHM is a high power supply potential used for setting a word line at a high level, and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 44 but can be more than one. In that case, a power switch is provided for each power domain.

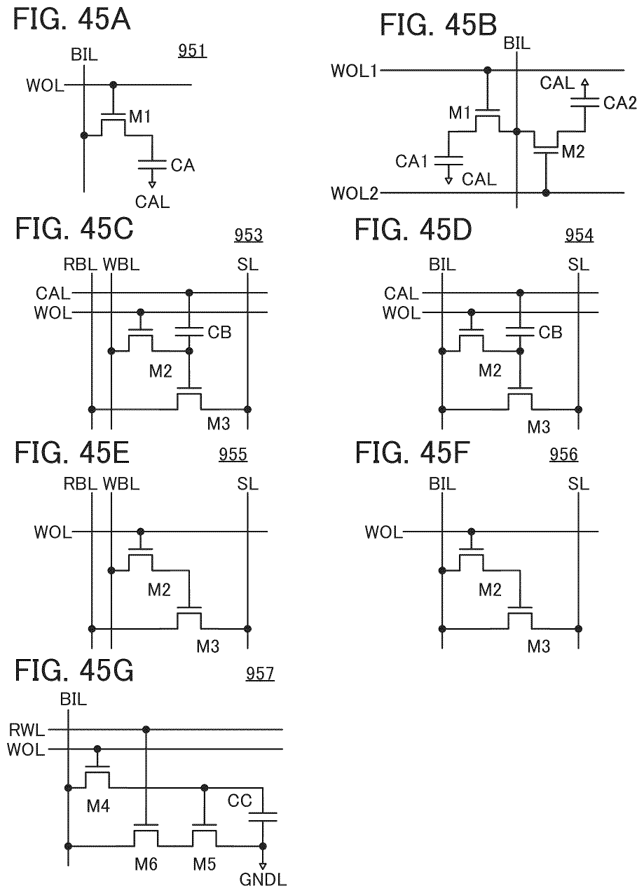

Structure examples of other memory cells each of which can be used as the memory cell 950 are described with reference to FIGS. 45A to 45G.

### [DOSRAM]

FIG. 45A illustrates a circuit structure example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. A gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, the memory cell 951 does not necessarily include the capacitor CA or the wiring CAL, and the first terminal of the transistor M1 may be in a floating state.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cell 951.

As illustrated in FIG. 45B, one wiring BIL can be provided to be shared by two or more memory cells of DRAM.

### [NOSRAM]

FIG. 45C illustrates a circuit structure example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. A gate of the transistor M2 is connected to the wiring WOL. A second terminal of the capacitor CB is connected to the wiring CAL. A first terminal of the transistor M3 is connected to a wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 45D. In a memory cell 954, one wiring BIL is provided instead of the wiring WBL and the wiring RBL in the memory cell 953, and the second terminal of the transistor M2 and the first terminal of the transistor M3 are connected to the wiring BIL. In other words, one wiring BIL operates as the write bit line and the read bit line in the memory cell 954.

A memory cell 955 illustrated in FIG. 45E is an example where the capacitor CB and the wiring CAL in the memory cell 953 are omitted. A memory cell 956 illustrated in FIG. 45F is an example where the capacitor CB and the wiring CAL in the memory cell 954 are omitted. Such structures enable high integration of the memory cell.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When an OS transistor is used as the transistor M3, the memory cell can be configured with only n-channel transistors.

FIG. 45G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than an OS transistor depending on the crystal state of silicon used in a semiconductor layer, for example.

When OS transistors are used as the transistors M5 and M6, the memory cell can be configured with only n-channel transistors.

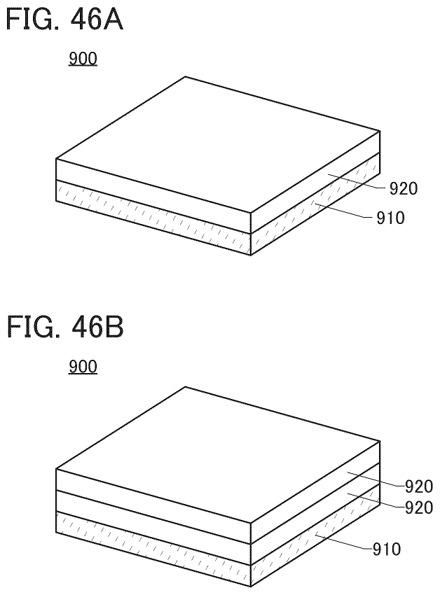

The driver circuit 910 and the memory array 920 included in the semiconductor device 900 may be provided on the same plane. Alternatively, as illustrated in FIG. 46A, the driver circuit 910 and the memory array 920 may be provided to overlap each other. Providing the driver circuit 910 and the memory array 920 to overlap with each other can shorten a signal propagation distance. As illustrated in FIG. 46B, a plurality of memory arrays 920 may be stacked over the driver circuit 910.

Next, description is made on an example of an arithmetic processing device that can include the semiconductor device such as the memory device described above.

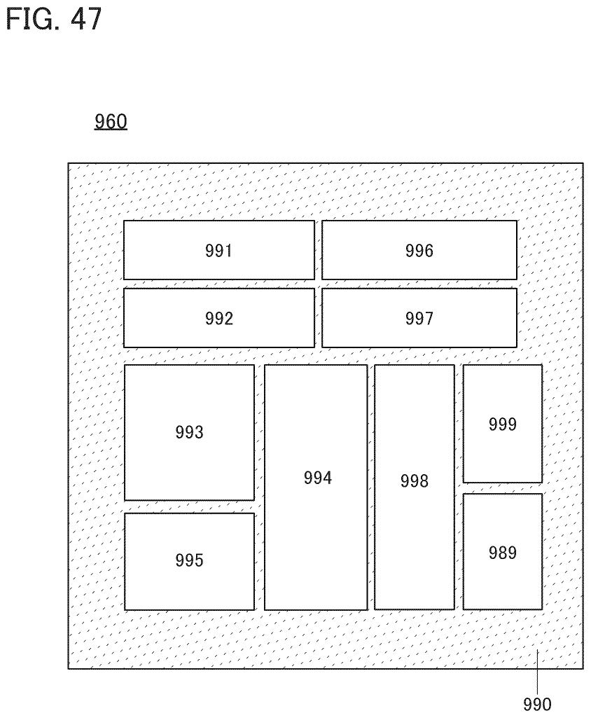

FIG. 47 is a block diagram of an arithmetic device 960. The arithmetic device 960 illustrated in FIG. 47 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 47 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 47 is just an example with a simplified structure, and the actual arithmetic device 960 has a variety of structures depending on the application. For example, what is called a multicore structure is preferably employed where a plurality of cores each including the arithmetic device 960 in FIG. 47 operate in parallel. The larger number of cores can further enhance the arithmetic performance. The number of cores is preferably larger; for example, the number is preferably 2, further preferably 4, still further preferably 8, yet still further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 illustrated in FIG. 47, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

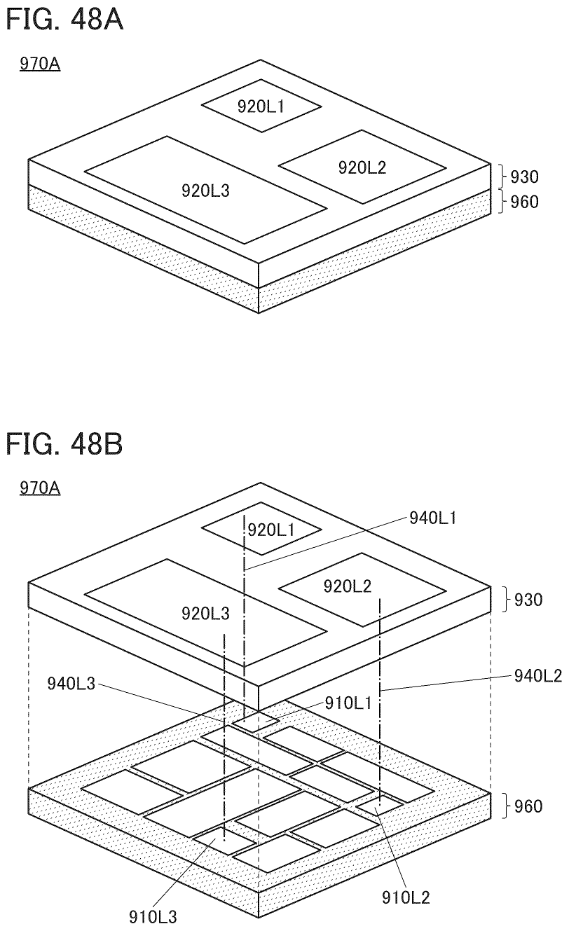

The memory array 920 and the arithmetic device 960 can be provided to overlap with each other. FIGS. 48A and 48B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 48B.

Overlapping the arithmetic device 960 and the layer 930 provided with the memory arrays can shorten the connection distance therebetween. Accordingly, the communication speed therebetween can be increased. Moreover, a short connection distance leads to lower power consumption.

As a method for stacking the arithmetic device 960 and the layer 930 provided with the memory arrays, either of the following methods may be employed: a method in which the layer 930 provided with the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 48B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

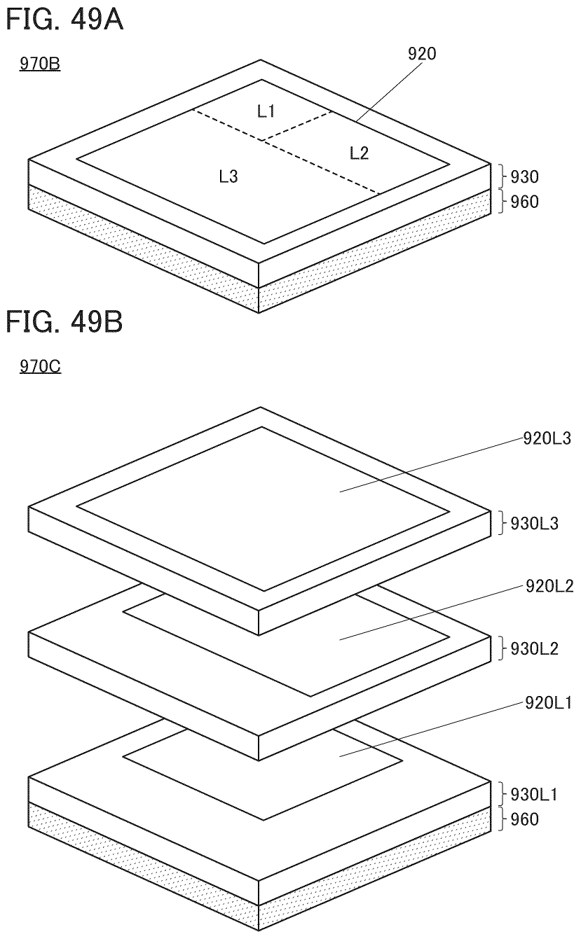

The layer 930 including one memory array 920 may be provided to overlap with the arithmetic device 960. FIG. 49A is a perspective view of a semiconductor device 970B.

In the semiconductor device 970B, one memory array 920 can be divided into a plurality of areas having different functions. FIG. 49A illustrates an example where a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 49B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate. In this specification, in the case where a plurality of structure examples are shown in one embodiment, the structure examples can be combined as appropriate.

### Embodiment 6

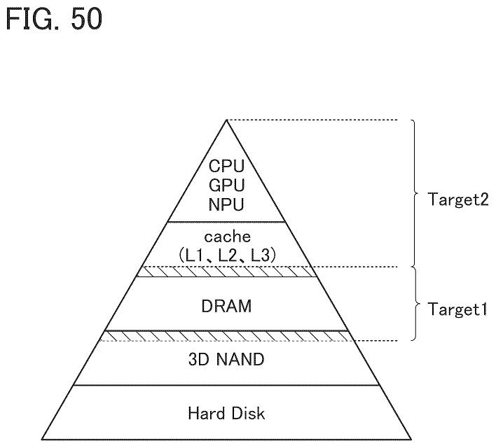

In this embodiment, an example of an application range of a semiconductor device of one embodiment of the present invention is described with reference to FIG. 50.

A variety of memory devices are used in semiconductor devices such as computers in accordance with the intended use. FIG. 50 is a conceptual diagram showing a hierarchy of memory devices used in semiconductor devices. In the conceptual diagram in FIG. 50, the hierarchy of memory devices is shown by a triangle; the memory devices at higher levels in the triangle require higher operation speed, and the memory devices at lower levels in the triangle require higher storage capacity and higher record density.

In FIG. 50, memories included as registers in arithmetic processing devices such as a CPU, a GPU, and an NPU, cache memories (sometimes simply referred to as caches, typically L1, L2, and L3 caches), main memories typified by DRAMs, 3D NANDs, and storage memories typified by hard disks (also referred to as hard disk drives (HDDs)) are shown in this order from the highest level in the triangle.

A memory included as a register in an arithmetic processing device such as a CPU, a GPU, or an NPU is used for temporary storage of arithmetic operation results, for example, and is thus very frequently accessed by the arithmetic processing device. Accordingly, high operation speed is required rather than high storage capacity. The register also has a function of retaining settings of the arithmetic processing device, for example.

The cache memory has a function of duplicating and retaining part of data retained in the DRAM. Duplicating frequently used data and retaining the duplicated data in the cache memory facilitates rapid data access. The cache memory requires lower storage capacity but requires higher operation speed than the DRAM. Data that is rewritten in the cache memory is duplicated, and the duplicated data is supplied to the DRAM. Although only L1 to L3 caches are shown as the cache memories in FIG. 50, one embodiment of the present invention is not limited thereto. For example, a memory device including the oxide semiconductor of one embodiment of the present invention can be suitably used as the last level cache (LLC) or a final level cache (FLC) positioned at the lowest level among the caches.

The DRAM has a function of retaining a program, data, or the like read from the 3D NAND.

The 3D NAND has a function of retaining data that needs to be stored for a long time, a variety of programs used in an arithmetic device (e.g., a model of an artificial neural network), and the like. Therefore, the 3D NAND requires high storage capacity and high record density rather than high operating speed.

The hard disk has high capacity and a nonvolatile function. Instead of the hard disk, a solid state drive (SSD) or the like can be used.

The memory device including the oxide semiconductor (OS memory) of one embodiment of the present invention can retain data for a long time. Thus, the memory device can be suitably used for devices in a region denoted as Target 1 in FIG. 50. Note that as indicated by hatching with oblique lines in FIG. 50, Target 1 also includes part of the caches (L1, L2, and L3) and part of the 3D NAND. In other words, Target 1 includes a boundary region between the DRAM and the 3D NAND and a boundary region between the DRAM and the caches (L1, L2, and L3). The memory device including the oxide semiconductor of one embodiment of the present invention operates at high speed, and thus can achieve excellent writing operation and excellent reading operation. Thus, the memory device can be suitably used for a region denoted as Target 2 in FIG. 50.

For example, the DRAM shown in FIG. 50 is suitably replaced with the memory device including the oxide semiconductor of one embodiment of the present invention. Refresh operation is essential in the DRAM, and the DRAM is a destructive read memory device and thus consumes higher power than other memory devices. Therefore, power consumption can be reduced with a structure not using the DRAM. With this structure, power consumption can be reduced to one-hundredth or less or one-thousandth or less of a structure using the DRAM. Thus, global expansion of information processing devices, such as supercomputers (also referred to as a high performance computers (HPCs)), computers, and servers, having such a structure will greatly contribute to global warming mitigation.

As described above, the memory device including the oxide semiconductor of one embodiment of the present invention can be applied to a wide range of memories covering from a memory included as a register in an arithmetic processing device such as a CPU, a GPU, or an NPU to a memory in the boundary region between a DRAM and a 3D NAND.

Note that this embodiment can be combined with the same embodiment or any of the other embodiments in this specification as appropriate. For example, the configurations, structures, methods, and the like described in this embodiment can be used in an appropriate combination with any of the other configurations, the other structures, the other methods, and the like described in this embodiment. Alternatively, for example, the configurations, structures, methods, and the like described in this embodiment can be used in an appropriate combination with any of the configurations, structures, methods, and the like described in the other embodiments and the like.

### Embodiment 7

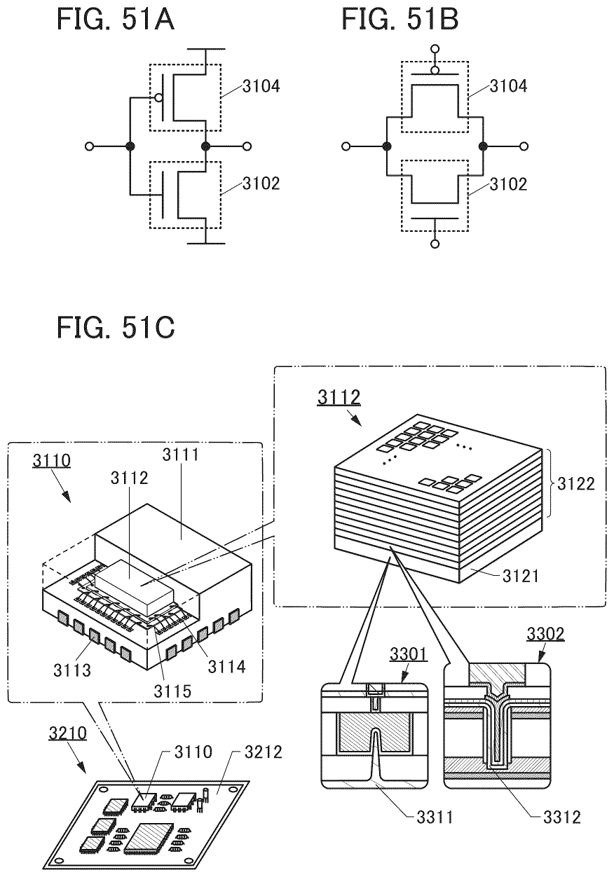

In this embodiment, examples of a circuit structure including the OS transistor of one embodiment of the present invention and examples of electronic components using the semiconductor device of one embodiment of the present invention are described with reference to FIGS. 51A to 51C.

### Circuit Structure Example

FIGS. 51A and 51B each illustrate an example of a circuit structure including the OS transistor of one embodiment of the present invention. The circuit diagram in FIG. 51A illustrates a structure of an inverter circuit formed of what is called a complementary metal oxide semiconductor (CMOS) circuit in which an n-channel transistor 3102 and a p-channel transistor 3104 are connected in series and their gates are connected. The circuit diagram in FIG. 51B illustrates a structure of a circuit that functions as what is called an analog switch, in which sources of the n-channel transistor 3102 and the p-channel transistor 3104 are connected to each other and drains of the n-channel transistor 3102 and the p-channel transistor 3104 are connected to each other.

### <Transistor Structure>

Any of various types of transistors can be used as the n-channel transistor 3102 and the p-channel transistor 3104 illustrated in FIGS. 51A and 51B. Specifically, a planar transistor, a vertical field effect transistor (VFET), a Fin-type transistor, a gate all around (GAA) transistor, or the like can be used as the n-channel transistor 3102 and the p-channel transistor 3104. A complementary field effect transistor (CFET) in which the n-channel transistor 3102 and the p-channel transistor 3104 are combined may be used.

In this specification and the like, a planar transistor has a structure where a source electrode and a drain electrode are positioned at the same or substantially the same height and a current flowing through a semiconductor contains components in the lateral direction. In this specification and the like, a VFET has a structure where a source electrode and a drain electrode are positioned at different heights and a current flowing through a semiconductor contains components in the vertical direction. Since two or more of the source electrode, the semiconductor, and the drain electrode of the VFET can be provided to overlap with each other, the area occupied by the VFET can be much smaller than the area occupied by the planar transistor.

In this specification and the like, a Fin-type transistor has a structure where two or more surfaces of a channel are covered with a gate electrode with a gate insulating film therebetween in a cross-sectional view in the channel width direction. In particular, the channel height (H) is preferably larger than the channel width (W) in the cross-sectional view in the channel width direction, in which case the channel width per unit area can be increased. In this specification and the like, a GAA transistor has a structure where a gate electrode covers four surfaces of a channel with a gate insulating film therebetween in a cross-sectional view in the channel width direction.

### <N-Channel Transistor>

An OS transistor of one embodiment of the present invention can be used as the n-channel transistor 3102 illustrated in FIGS. 51A and 51B. The OS transistor has an extremely low off-state current, and thus the leakage current of the n-channel transistor 3102 can be extremely low. In the n-channel transistor 3102, a single element semiconductor such as silicon or germanium, a compound semiconductor such as gallium arsenide, a layered material functioning as a semiconductor, or the like can be used as a semiconductor material. In particular, a layered material functioning as a semiconductor is preferably used as a semiconductor material.

In this specification and the like, the layered material is a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

In this specification and the like, the above-described layered material is sometimes referred to as a two-dimensional material. Examples of a two-dimensional material that can be used for the n-channel transistor 3102 and the p-channel transistor 3104 in one embodiment of the present invention include graphene, silicene (a substance in which a carbon atom of graphene is replaced with a silicon atom), germanene (a substance in which a carbon atom of graphene is replaced with a germanium atom), transition metal chalcogenides or transition metal dichalcogenides (TMDs), boron nitride (BN), and black phosphorus. Using the above-described two-dimensional material can improve one or more physical properties of electron mobility, mechanical strength, and thermal conductivity, compared with the case of using a single element semiconductor such as silicon or germanium. The above-described two-dimensional material has excellent physical properties compared with a single element semiconductor such as silicon; thus, the two-dimensional material may be referred to as a new material channel (NMC).

Examples of the layered material include chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As a material that can be used for the n-channel transistor 3102, a transition metal chalcogenide functioning as a semiconductor is preferably used, for example. Specific examples of the transition metal chalcogenide include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <P-Channel Transistor>

In the p-channel transistor 3104 illustrated in FIGS. 51A and 51B, a single element semiconductor such as silicon or germanium, a compound semiconductor such as gallium arsenide, a layered material functioning as a semiconductor, or the like can be used as a semiconductor material. In particular, a layered material functioning as a semiconductor is preferably used as a semiconductor material.

As a material that can be used for the p-channel transistor 3104, a transition metal chalcogenide functioning as a semiconductor is preferably used, for example. Specific examples of the transition metal chalcogenide include molybdenum sulfide (typically MoS₂), molybdenum selenide (typically MoSe₂), tungsten sulfide (typically WS₂), and tungsten selenide (typically WSe₂).

As the material that can be used for the p-channel transistor 3104, other than the above-described two-dimensional material, a Group III-V compound semiconductor (typically, a gallium-arsenic compound semiconductor, an indium-phosphorus compound semiconductor, an indium-gallium-arsenic compound semiconductor, an indium-arsenic compound semiconductor, or the like), a carbon nanotube (CNT), tin sulfide (typically, SnS), tin selenide (typically, SnSe), or the like can be used. Note that a Group III-V compound semiconductor may be used for the n-channel transistor 3102.

### Electronic Component Example

FIG. 51C illustrates an example of an electronic component including the semiconductor device of one embodiment of the present invention. An electronic component including the semiconductor device or the memory device of one embodiment of the present invention is effective in reducing power consumption and improving performance.

FIG. 51C is a perspective view of a substrate (a circuit board 3210) provided with an electronic component 3110. The electronic component 3110 illustrated in FIG. 51C includes a memory device 3112 in a mold 3111. FIG. 51C omits some components to show the inside of the electronic component 3110. The electronic component 3110 includes a land 3113 outside the mold 3111. The land 3113 is connected to an electrode pad 3114, and the electrode pad 3114 is connected to the memory device 3112 through a wire 3115. The electronic component 3110 is mounted on a printed wiring board 3212, for example. A plurality of such electronic components are combined and electrically connected to each other on the printed circuit board 3212, which forms the circuit board 3210.

The memory device 3112 includes a layer 3121 including an arithmetic core and a layer 3122 including a memory. For example, the above-described n-channel transistor and p-channel transistor can be used for both the layer 3121 and the layer 3122. It is particularly preferable that a p-channel transistor be used for the layer 3121 and an n-channel transistor be used for the layer 3122 to form a CMOS circuit. However, one embodiment of the present invention is not limited thereto, and both an n-channel transistor and a p-channel transistor may be included in the layer 3121 and an n-channel transistor may be used in the layer 3122.

Specifically, it is preferable that the layer 3121 include a p-channel transistor 3301 and the layer 3122 include an n-channel transistor 3302. In FIG. 51C, when a semiconductor layer 3311 included in the transistor 3301 is p-channel silicon and a semiconductor layer 3312 included in the transistor 3302 is an n-channel oxide semiconductor, a stacked-layer structure of a Si transistor and an OS transistor can be obtained.

Alternatively, in FIG. 51C, when the semiconductor layer 3311 included in the transistor 3301 is a p-channel two-dimensional material (e.g., WS₂) and the semiconductor layer 3312 included in the transistor 3302 is an n-channel oxide semiconductor, a stacked-layer structure of a WS₂ transistor and an OS transistor can be obtained. With such a stacked-layer structure, a memory device with low power consumption and high performance can be provided.

Stacking the two kinds of transistors reduces the area occupied by the circuit, allowing a plurality of circuits to be highly integrated. Although FIG. 51C illustrates a structure example where the transistor 3301 is a Fin-type transistor and the transistor 3302 is a VFET, one embodiment of the present invention is not limited thereto; a Fin-type transistor may be used as the transistor 3301 and a Fin-type transistor may be used as the transistor 3302. When the transistor 3301 and the transistor 3302 have different structures, characteristics according to the respective transistor structures can be obtained, which is excellent. The structures of the transistor 3301 and the transistor 3302 are preferably the same, in which case some manufacturing apparatuses can be used in common.

The layer 3122 including the memory has a structure where a plurality of memory cell arrays are stacked. The layer 3121 including the arithmetic core and the layer 3122 including the memory can be stacked monolithically. In the monolithic stacked-layer structure, layers can be connected to each other without using a through electrode technique such as a through silicon via (TSV) technique and a bonding technique such as Cu—Cu direct bonding. The monolithic stacked-layer structure of the layer 3121 including the arithmetic core and the layer 3122 including the memory enables, for example, what is called an on-chip memory structure where a memory is directly formed on a processor. The on-chip memory structure allows an interface portion between the processor and the memory to operate at high speed. Note that part of the function (part of the arithmetic function) of the layer 3121 including the arithmetic core may be provided in part of the layer 3122 including the memory.

With the on-chip memory structure, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the layer 3122 including the memory be formed with OS transistors and be monolithically stacked. The monolithic stacked-layer structure of memory cell arrays can improve the bandwidth of the memory and/or the access latency of the memory. Note that the bandwidth refers to the data transfer volume per unit time, and the access latency refers to a period of time from data access to the start of data transmission. Note that in the case where the layer 3122 including the memory is formed with Si transistors, the monolithic stacked-layer structure is difficult to form as compared with the case where the layer 3122 including the memory is formed with OS transistors. Therefore, an OS transistor is superior to a Si transistor in the monolithic stacked-layer structure.

This embodiment can be combined with any of the other embodiments as appropriate. In this specification, in the case where a plurality of structure examples are shown in one embodiment, the structure examples can be combined as appropriate.

### Embodiment 8

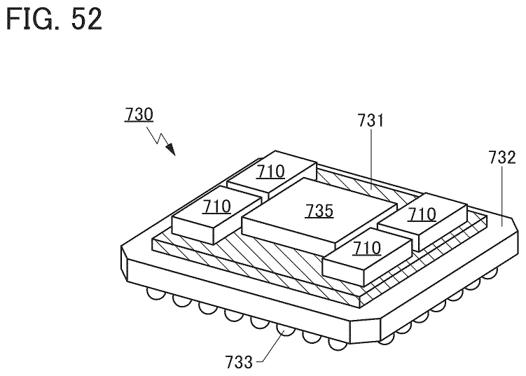

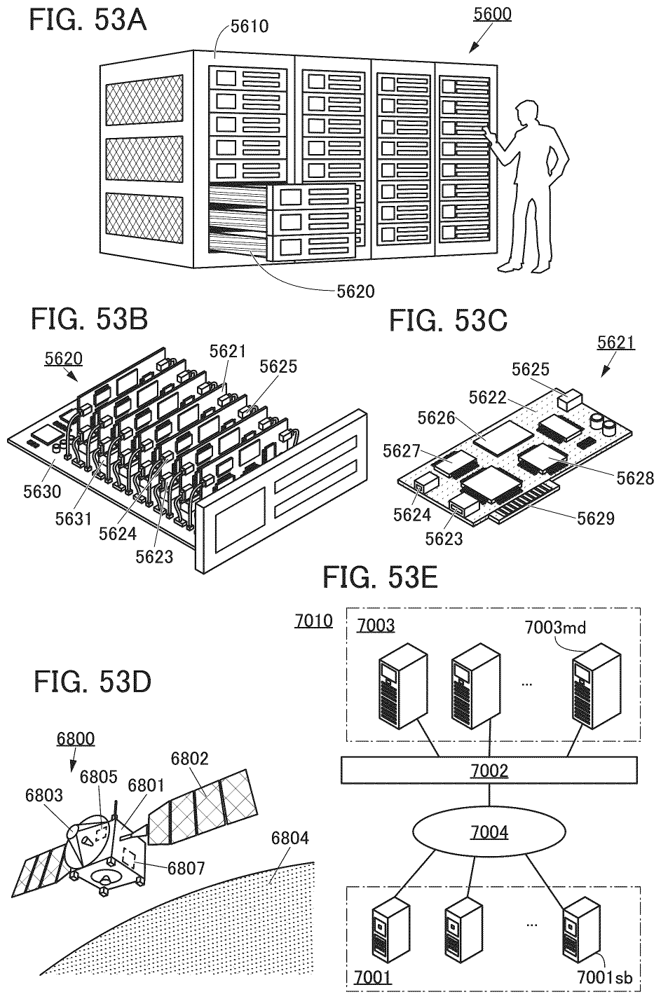

In this embodiment, application examples of the semiconductor device or the memory device of one embodiment of the present invention are described with reference to FIG. 52, FIGS. 53A to 53E, FIGS. 54A to 54F, FIGS. 55A to 55G, and FIGS. 56A to 56F.

The semiconductor device or the memory device of one embodiment of the present invention can be used for an electronic component, a large computer, a device for space, a data center (also referred to as DC), and a variety of electronic devices, for example. With the use of the semiconductor device or the memory device of one embodiment of the present invention, an electronic component, a large computer, a device for space, a data center, and a variety of electronic devices can have lower power consumption and higher performance.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

Examples of such an electronic device include watch-type and bracelet-type information terminal devices (wearable devices) and wearable devices that can be worn on a head, such as a VR device like a head-mounted display, a glasses-type AR device, and an MR device.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 52 is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The memory device 3112 described in Embodiment 7 can be used for the semiconductor device 710.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure using OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 52 illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

### [Large Computer]

FIG. 53A is a perspective view of a large computer 5600. In the large computer 5600 illustrated in FIG. 53A, a plurality of rack mount computers 5620 are stored in a rack 5610. Note that the large computer 5600 may be referred to as a supercomputer.

The computer 5620 can have a structure illustrated in a perspective view in FIG. 53B, for example. In FIG. 53B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 53C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 53C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device or the like. As the semiconductor device 5628, the electronic component 3110 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device or the memory device of one embodiment of the present invention can be suitably used as a device for space.

The semiconductor device or the memory device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of thermosphere, mesosphere, and stratosphere.

FIG. 53D illustrates an artificial satellite 6800 as an example of a device for space. The artificial satellite 6800 includes a body 6801, a solar panel 6802, an antenna 6803, a secondary battery 6805, and a control device 6807. In FIG. 53D, a planet 6804 in outer space is illustrated as an example.

Although not illustrated in FIG. 53D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device or the memory device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device or the memory device of one embodiment of the present invention can be suitably used for a device for space such as a spacecraft, a space capsule, or a space probe, for example.

As described above, the OS transistor has advantageous effects over the Si transistor, such as a wide memory bandwidth and high radiation resistance.

### [Data Center]

The semiconductor device or the memory device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device or the memory device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device or the memory device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device or the memory device of one embodiment of the present invention can achieve a data center that operates stably even in a high temperature environment. Thus, the reliability of the data center can be increased.

FIG. 53E illustrates a storage system that can be used in a data center. A storage system 7010 illustrated in FIG. 53E includes a plurality of servers 7001sb as a host 7001. The storage system 7010 includes a plurality of memory devices 7003md as a storage 7003. In the illustrated example, the host 7001 and the storage 7003 are connected to each other via a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still much longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure where an OS transistor is used as a transistor for storing data in the cache memory to retain a potential based on data, the frequency of refreshing can be decreased, so that power consumption can be reduced. Furthermore, downscaling is possible by stacking memory cell arrays.

### [Electronic Device]

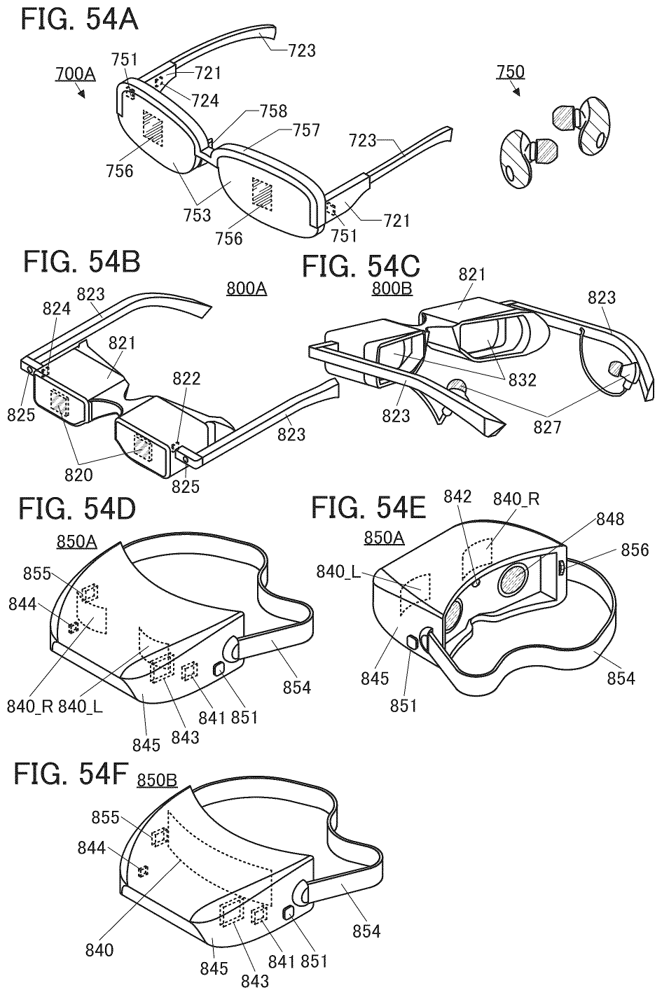

Examples of a wearable device that can be worn on a head are described with reference to FIGS. 54A to 54F. The wearable device has at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 54A includes a pair of display panels 751, a pair of housings 721, a communication portion (not illustrated), a pair of wearing portions 723, a control portion 724, an image capturing portion (not illustrated), a pair of optical members 753, a frame 757, and a pair of nose pads 758.

The semiconductor device or the memory device of one embodiment of the present invention can be used for the control portion 724. In that case, power consumption of the electronic device can be reduced.

The electronic device 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A is an electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic device 800A illustrated in FIG. 54B and an electronic device 800B illustrated in FIG. 54C each include a pair of display portions 820, a housing 821, a communication portion 822, a pair of wearing portions 823, a control portion 824, a pair of image capturing portions 825, and a pair of lenses 832.

The semiconductor device or the memory device of one embodiment of the present invention can be used for the control portion 824. In that case, power consumption of the electronic device can be reduced.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user wearing the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 54B and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 54A has a function of transmitting information to the earphones 750 with the wireless communication function.

The electronic device may include an earphone portion. The electronic device 800B in FIG. 54C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 54D and 54E are perspective views of a goggles-type electronic device 850A for VR. FIGS. 54D and 54E illustrate an example where a housing 845 includes a pair of curved display devices 840 (a display device 840_R and a display device 840_L). The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-resolution image to be displayed even when three-dimensional display using parallax or the like is performed. In addition, the display device 840 is curved around an arc with an approximate center at the user's eye. This keeps a certain distance between the user's eye and the display surface of the display device 840, enabling the user to see a more natural image. Even when having what is called viewing angle dependence where the luminance or chromaticity of light changes depending on a viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic video.

As illustrated in FIG. 54E, the lenses 848 are positioned between the display devices 840 and the user's eyes. FIG. 54E illustrates an example where the dial 856 for changing the positions of the lenses for visibility adjustment is provided. Note that in the case where the electronic device 850A has an autofocus function, the dial 856 for visibility adjustment is not necessarily provided.

FIG. 54F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image which can be seen with both eyes may be displayed on the entire display device 840. Thus, a panorama image can be displayed from end to end of the field of view, which can provide a higher sense of reality.

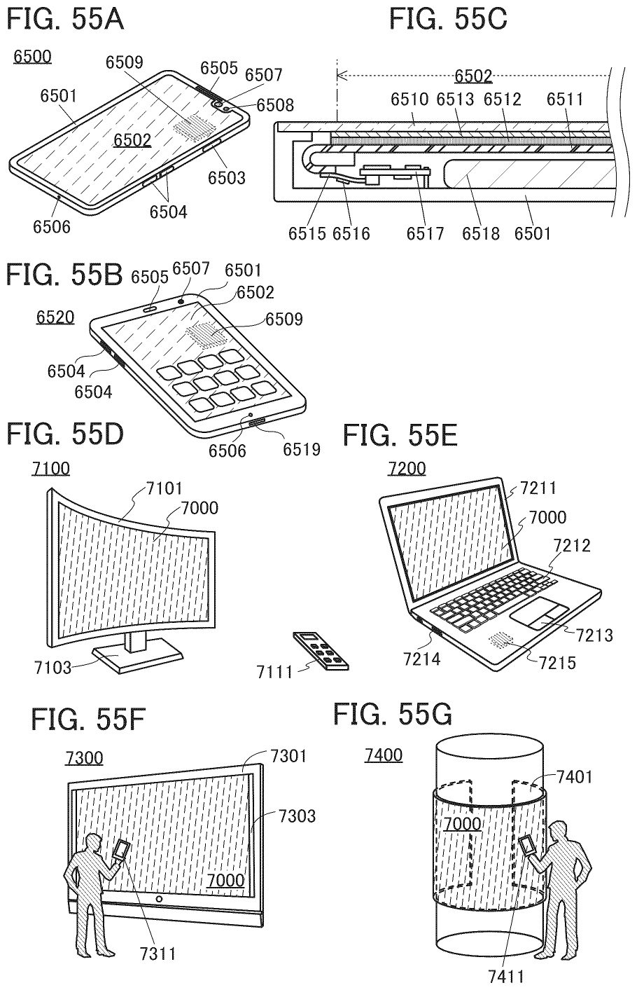

An electronic device 6500 illustrated in FIG. 55A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 illustrated in FIG. 55B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. Note that the control device 6509 includes, for example, one or more selected from a CPU, a GPU, and a memory device. The semiconductor device or the memory device of one embodiment of the present invention can be used for the control device 6509.

FIG. 55C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

FIG. 55D illustrates an example of a television device. In a television device 7100, a display portion 7000 is incorporated in a housing 7101. Here, the housing 7101 is supported by a stand 7103.

Operation of the television device 7100 illustrated in FIG. 55D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 55E illustrates an example of a laptop personal computer. The laptop personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device or the memory device of one embodiment of the present invention can be used for the control device 7215.

FIGS. 55F and 55G illustrate examples of digital signage.

Digital signage 7300 illustrated in FIG. 55F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 55G is digital signage 7400 attached to a cylindrical pillar 7401. The digital signage 7400 includes the display portion 7000 provided along a curved surface of the pillar 7401.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 55F and 55G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device or the memory device of one embodiment of the present invention can be used around a driver's seat in a car, which is a vehicle.

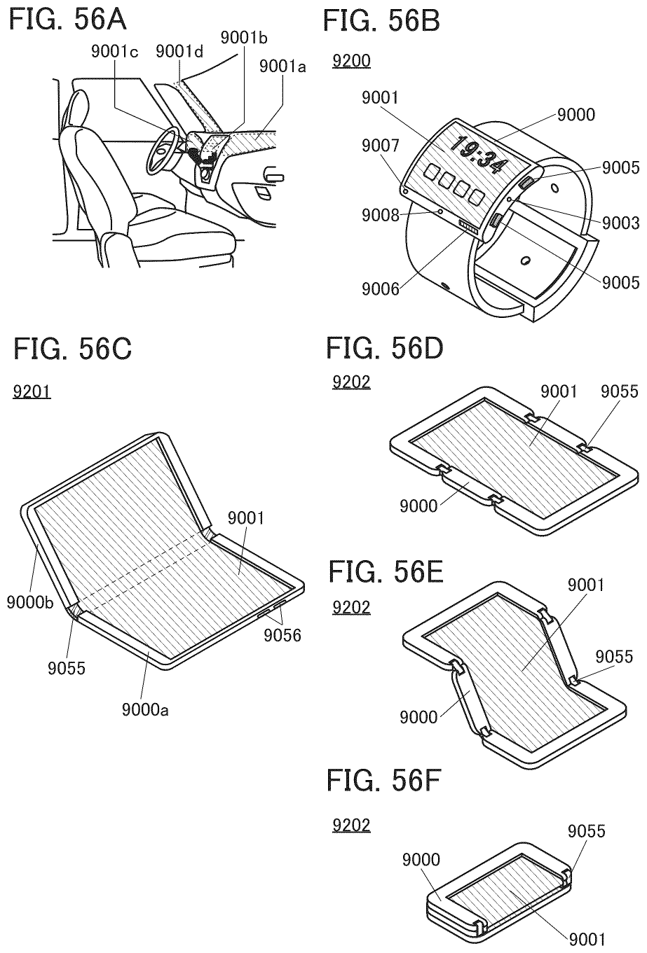

FIG. 56A illustrates the vicinity of a windshield inside a car. FIG. 56A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying an image taken by an imaging unit provided for the car body. That is, displaying an image taken by the imaging unit provided on the outside of the car body leads to elimination of blind areas and enhancement of safety. Moreover, showing an image to compensate for the area that a driver cannot see makes it possible for the driver to confirm safety more easily and comfortably. The display panel 9001d can also be used as a lighting device.

FIG. 56B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 56B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like. FIG. 56C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together with the hinge 9055.

FIGS. 56D to 56F are perspective views illustrating a foldable portable information terminal 9202. FIG. 56D is a perspective view of an opened state of the portable information terminal 9202, FIG. 56F is a perspective view of a folded state thereof, and FIG. 56E is a perspective view of a state in the middle of change from one of FIG. 56D and FIG. 56F to the other. In this manner, the portable information terminal 9202 can be folded in three.

The display portion 9001 of the portable information terminal 9202 is supported by three housings 9000 joined together with the hinges 9055.

The portable information terminals 9201 and 9202 are highly portable when folded. When the portable information terminals 9201 and 9202 are opened, a seamless large display region is highly browsable.

The use of the semiconductor device or the memory device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device or the memory device of one embodiment of the present invention. Furthermore, the semiconductor device or the memory device of one embodiment of the present invention has low power consumption and is thus effective as a global warming countermeasure.

This embodiment can be combined with any of the other embodiments as appropriate. In this specification, in the case where a plurality of structure examples are shown in one embodiment, the structure examples can be combined as appropriate.

This application is based on Japanese Patent Application Serial No. 2024-013335 filed with Japan Patent Office on Jan. 31, 2024, Japanese Patent Application Serial No. 2024-013338 filed with Japan Patent Office on Jan. 31, 2024, and Japanese Patent Application Serial No. 2024-022002 filed with Japan Patent Office on Feb. 16, 2024, the entire contents of which are hereby incorporated by reference.

What is claimed is:

1. A semiconductor device comprising:
an oxide semiconductor layer;
a first insulating layer;
a second insulating layer;
a third insulating layer;
a first conductive layer;
a second conductive layer; and
a third conductive layer,
wherein the first conductive layer and the second conductive layer are over the first insulating layer and apart from each other,
wherein the first insulating layer comprises a groove portion between the first conductive layer and the second conductive layer,
wherein the oxide semiconductor layer comprises a region in contact with part of a top surface of the first conductive layer and a side surface of the first conductive layer on a side of the groove portion, a region in contact with part of a top surface of the second conductive layer and a side surface of the second conductive layer on a side of the groove portion, and a region in contact with a side surface of the groove portion,
wherein the second insulating layer is over the oxide semiconductor layer,
wherein the third conductive layer is over the second insulating layer,
wherein side surfaces of the third conductive layer, the second insulating layer, and the oxide semiconductor layer are aligned or substantially aligned with each other,
wherein the third insulating layer comprises, outside the groove portion, a region in contact with another part of the top surface of the first conductive layer, another part of the top surface of the second conductive layer, the side surface of the oxide semiconductor layer, the side surface of the second insulating layer, and the side surface of the third conductive layer, and
wherein the third insulating layer comprises, inside the groove portion, a region in contact with a side surface of the oxide semiconductor layer, a side surface of the second insulating layer, and a side surface of the third conductive layer.

2. The semiconductor device according to claim 1, further comprising a fourth conductive layer,
wherein the fourth conductive layer is in contact with a top surface of the third conductive layer, and
wherein an extending direction of the fourth conductive layer intersects with an extending direction of the groove portion.

3. The semiconductor device according to claim 1, further comprising a fifth conductive layer,
wherein the fifth conductive layer comprises regions overlapping with the first conductive layer and the second conductive layer with the first insulating layer therebetween,
wherein the fifth conductive layer comprises a depressed portion in a region overlapping with the groove portion, and
wherein the oxide semiconductor layer comprises a region in contact with a side surface and a bottom portion of the depressed portion.

4. The semiconductor device according to claim 3, wherein the depressed portion comprises a curved portion.

5. A memory device comprising:
a capacitor;
a transistor over the capacitor;
a first insulating layer; and
a second insulating layer,
wherein the transistor comprises an oxide semiconductor layer, a third insulating layer, a first conductive layer, a second conductive layer, a third conductive layer, and a fourth conductive layer,
wherein the first insulating layer covers the first conductive layer,
wherein the second conductive layer and the third conductive layer are over the first insulating layer and apart from each other,
wherein the first insulating layer comprises a groove portion between the second conductive layer and the third conductive layer,
wherein the first conductive layer comprises a depressed portion in a region overlapping with the groove portion,
wherein the oxide semiconductor layer comprises a region in contact with part of a top surface of the second conductive layer and a side surface of the second conductive layer on a side of the groove portion, a region in contact with part of a top surface of the third conductive layer and a side surface of the third conductive layer on a side of the groove portion, a region in contact with a side surface of the groove portion, and a region in contact with a side surface and a bottom portion of the depressed portion,
wherein the third insulating layer is over the oxide semiconductor layer,
wherein the fourth conductive layer is over the third insulating layer,
wherein side surfaces of the fourth conductive layer, the third insulating layer, and the oxide semiconductor layer are aligned or substantially aligned with each other,
wherein the second insulating layer comprises, outside the groove portion, a region in contact with another part of the top surface of the second conductive layer, another part of the top surface of the third conductive layer, the side surface of the oxide semiconductor layer, the side surface of the third insulating layer, and the side surface of the fourth conductive layer, and
wherein the second insulating layer comprises, inside the groove portion, a region in contact with a side surface of the oxide semiconductor layer, a side surface of the third insulating layer, and a side surface of the fourth conductive layer.

6. The memory device according to claim 5, further comprising a fifth conductive layer,
wherein the fifth conductive layer is in contact with a top surface of the fourth conductive layer, and
wherein an extending direction of the fifth conductive layer intersects with an extending direction of the groove portion.

7. The memory device according to claim 5, wherein the depressed portion comprises a curved portion.

8. The memory device according to claim 5, wherein the capacitor comprises a sixth conductive layer, a fourth insulating layer over the sixth conductive layer, and the first conductive layer over the fourth insulating layer.

9. The memory device according to claim 5,
wherein the third insulating layer comprises a first layer, and
wherein the first layer comprises an oxide comprising hafnium.

10. The memory device according to claim 9, wherein the first layer comprises hafnium zirconium oxide.

11. The memory device according to claim 10,
wherein the third insulating layer comprises a second layer over the first layer, and
wherein the second layer comprises silicon nitride.

12. A semiconductor device comprising:
a first insulating layer;
a second insulating layer;
a first transistor; and
a second transistor,
wherein the first insulating layer comprises a groove portion,
wherein the first transistor comprises a first oxide semiconductor layer comprising a channel formation region,
wherein the second transistor comprises a second oxide semiconductor layer comprising a channel formation region,
wherein at least part of the first oxide semiconductor layer and at least part of the second oxide semiconductor layer are in the groove portion, and
wherein in a plan view, the first oxide semiconductor layer and the second oxide semiconductor layer face each other with the second insulating layer therebetween, in a direction perpendicular to an extending direction of the groove portion.

13. The semiconductor device according to claim 12,
wherein the first transistor comprises a first conductive layer, a second conductive layer, and a third conductive layer,
wherein the second conductive layer is over the first insulating layer,
wherein the first conductive layer comprises a region overlapping with the second conductive layer with the first insulating layer therebetween,
wherein the first conductive layer comprises a depressed portion in a region overlapping with the groove portion,
wherein the first oxide semiconductor layer comprises a region in contact with a side surface and a bottom portion of the depressed portion in the first conductive layer and a region in contact with a top surface and a side surface of the second conductive layer, and
wherein the third conductive layer is above the first oxide semiconductor layer.

14. The semiconductor device according to claim 13, wherein inside the groove portion, the second insulating layer comprises regions in contact with a side surface of the first oxide semiconductor layer and a side surface of the second oxide semiconductor layer.

15. The semiconductor device according to claim 13, further comprising a fourth conductive layer,
wherein the fourth conductive layer is connected to a gate of the first transistor and a gate of the second transistor, and
wherein an extending direction of the fourth conductive layer intersects with an extending direction of the groove portion.

16. A memory device comprising:
the semiconductor device according to claim 13; and
a capacitor,
wherein the capacitor is below the first transistor, and
wherein the first conductive layer comprises a region serving as one of a pair of electrodes of the capacitor.
